(19) United States
(12) Patent Application Publication
(10) Pub. No.: US 2026/0323954 A1
(43) Pub. Date: Oct. 15, 2026

(54) SEMICONDUCTOR DEVICE AND METHOD FOR FABRICATING SEMICONDUCTOR DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Fumito ISAKA, Zama, Kanagawa-ken (JP); Yuji EGI, Atsugi, Kanagawa (JP); Shiyuu NUMATA, Atsugi, Kanagawa (JP); Ryo TOKUMARU, Isehara, Kanagawa (JP); Jun ISHIKAWA, Isehara, Kanagawa (JP); Sachiaki TEZUKA, Atsugi, Kanagawa (JP)

(21) Appl. No.: 19/485,721

(22) PCT Filed: Jun. 3, 2024
(86) PCT No.: PCT/IB2024/055384

§ 371 Date: Nov. 19, 2025

(30) Foreign Application Priority Data
Jun. 9, 2023 (JP) 2023-095844

(51) Int. Cl. H10B 53/20; H10B 12/00; H10B 53/10; H10B 53/30; H10D 1/00; H10D 1/68; H10D 30/67

(52) U.S. Cl. CPC H10B 53/20; H10B 12/33; H10B 53/10; H10B 53/30; H10D 1/042; H10D 1/692; H10D 1/714; H10D 1/716; H10D 30/6728; H10D 1/696

(57) ABSTRACT

A novel semiconductor device is provided. The semiconductor device includes a first conductive layer, a ferroelectric layer over the first conductive layer, and a second conductive layer over the ferroelectric layer. The first conductive layer includes a first depressed portion. The ferroelectric layer includes a region formed along the first depressed portion. The ferroelectric layer includes a second depressed portion in a region overlapping with the first depressed portion. The second conductive layer is provided to fill the second depressed portion. The ferroelectric layer includes hafnium, zirconium, and oxygen. The ferroelectric layer, in an X-ray diffraction analysis, has a peak at 2θ of around 30.4°. In the ferroelectric layer, in the X-ray diffraction analysis, an intensity at 2θ of 28.5° is less than or equal to 0.1 times a peak intensity of the peak and an intensity at 2θ of 31.6° is less than or equal to 0.1 times a peak intensity of the peak.

### TECHNICAL FIELD

One embodiment of the present invention relates to a semiconductor device and a method for fabricating the semiconductor device.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

Thus, examples of the technical field of one embodiment of the present invention include a semiconductor device, a display device, a liquid crystal display device, a light-emitting device, a power storage device, an imaging device, a storage device, a signal processing device, a processor, an electronic device, a system, a driving method thereof, a manufacturing method thereof, a testing method thereof, and a usage method thereof.

### BACKGROUND ART

In recent years, semiconductor devices such as an LSI (Large Scale Integration), a CPU (Central Processing Unit), and a memory (a storage device) have been developed. These semiconductor devices have been used in various electronic devices such as computers and portable information terminals. In addition, memories under development employ various storage systems for intended uses such as temporary storage at the time of executing arithmetic processing and long-term storage of data. Examples of memories with typical storage systems include a DRAM (Dynamic Random Access Memory), an SRAM, and a flash memory.

Memories using ferroelectrics have been actively researched and developed as disclosed in Non-Patent Document 1. For the next-generation ferroelectric memories, researches on hafnium oxide, such as research on ferroelectric HfO₂-based materials (Non-Patent Document 2); research on ferroelectricity of a hafnium oxide thin film (Non-Patent Document 3); research on hafnium oxide-based ferroelectrics (Non-Patent Document 4); and demonstration of integration of an FeRAM (Ferroelectric Random Access Memory) using a ferroelectric Hf_{0.5}Zr_{0.5}O₂ and a CMOS (Non-Patent Document 5) have been actively carried out.

### REFERENCES

### Non-Patent Documents

[Non-Patent Document 1]T. S. Boescke, et al., “Ferroelectricity in hafnium oxide thin films”, APL99, 2011
[Non-Patent Document 2] Zhen Fan, et al., “Ferroelectric HfO₂-based materials for next-generation ferroelectric memories”, JOURNAL OF ADVANCED DIELECTRICS, Vol. 6, No. 2, 2016
[Non-Patent Document 3] Jun Okuno, et al., “SoC compatible 1T1C FeRAM memory array based on ferroelectric Hf_{0.5}Zr_{0.5}O₂”, VLSI 2020
[Non-Patent Document 4] Hiroshi Funakubo, Takanori Mimura, Takao Shimizu, and Takanori Kiguchi, “Understanding of the basic properties of HfO₂-based ferroelectrics using epitaxial films”, Applied Physics, Vol. 87, No. 12, pp. 921-925, (2018)
[Non-Patent Document 5]T. Francois, et al., “Demonstration of BEOL-compatible ferroelectric Hf_{0.5}Zr_{0.5}O₂ scaled FeRAM co-integrated with 130 nm CMOS for embedded NVM applications”, IEDM 2019

### SUMMARY OF THE INVENTION

### Problems to be Solved by the Invention

As described in Non-Patent Document 1 to Non-Patent Document 5, various researches and developments on ferroelectrics have been carried out. For example, Non-Patent Document 4 has reported crystal structures that HfO₂ can have and polarization-electric field characteristics of the crystal structures, as shown in FIG. 8.

Although research and development of ferroelectrics have been variously conducted as described above, ferroelectric characteristics still have a room for improvement, and improvements in characteristics such as reliability is being demanded.

An object of one embodiment of the present invention is to provide a novel semiconductor device. Another object of one embodiment of the present invention is to provide a semiconductor device that occupies a small area. Another object of one embodiment of the present invention is to provide a highly reliable semiconductor device. Another object of one embodiment of the present invention is to provide a semiconductor device with low power consumption. Another object of one embodiment of the present invention is to provide a semiconductor device with high storage capacity.

Note that the objects of one embodiment of the present invention are not limited to the objects listed above. The objects listed above do not preclude the existence of other objects. The other objects are objects that are not described in this section and will be described below. The objects that are not described in this section will be derived from the description of the specification, the drawings, and the like and can be extracted as appropriate from the description by those skilled in the art. One embodiment of the present invention does not have to achieve all of the objects listed above and the other objects. One embodiment of the present invention achieves at least one of the objects listed above and the other objects.

### Means for Solving the Problems

One embodiment of the present invention is a semiconductor device including a first conductive layer, a ferroelectric layer over the first conductive layer, and a second conductive layer over the ferroelectric layer. The first conductive layer includes a first depressed portion. The ferroelectric layer includes a region formed along the first depressed portion. The ferroelectric layer includes a second depressed portion in a region overlapping with the first depressed portion. The second conductive layer is provided to fill the second depressed portion. The ferroelectric layer includes hafnium, zirconium, and oxygen. The ferroelectric layer, in an X-ray diffraction analysis, has a peak at 2θ of around 30.4°. In the ferroelectric layer, in the X-ray diffraction analysis, an intensity at 2θ of 28.5° is less than or equal to 0.1 times a peak intensity of the peak and an intensity at 2θ of 31.6° is less than or equal to 0.1 times a peak intensity of the peak.

In the semiconductor device, one or both of the first conductive layer and the second conductive layer preferably include titanium and nitrogen.

In the semiconductor device, one or both of the first conductive layer and the second conductive layer preferably include tungsten.

One embodiment of the present invention is a semiconductor device including a capacitor and a transistor over the capacitor. The capacitor includes a first conductive layer, a ferroelectric layer over the first conductive layer, and a second conductive layer over the ferroelectric layer. The ferroelectric layer includes hafnium, zirconium, and oxygen. A top surface of the second conductive layer includes a region in contact with at least part of a bottom surface of an oxide semiconductor layer included in the transistor.

In the semiconductor device, it is preferable that the ferroelectric layer, in an X-ray diffraction analysis, have a peak at 2θ of around 30.4°, and in the ferroelectric layer, in the X-ray diffraction analysis, an intensity at 2θ of 28.5° be less than or equal to 0.1 times a peak intensity of the peak and an intensity at 2θ of 31.6° be less than or equal to 0.1 times a peak intensity of the peak.

In the semiconductor device, one or both of the first conductive layer and the second conductive layer preferably include titanium and nitrogen.

In the semiconductor device, one or both of the first conductive layer and the second conductive layer preferably include tungsten.

In the semiconductor device, it is preferable that the first conductive layer include a first depressed portion, the ferroelectric layer include a region formed along the first depressed portion, the ferroelectric layer include a second depressed portion in a region overlapping with the first depressed portion, and the second conductive layer be provided to fill the second depressed portion.

In the semiconductor device, a channel of the transistor is preferably formed along a side surface of an opening portion of an insulating layer.

In the semiconductor device, the oxide semiconductor layer preferably includes one or both of indium and zinc.

One embodiment of the present invention is a method for fabricating a semiconductor device including forming a first conductive layer over a substrate, forming a ferroelectric layer over the first conductive layer, and forming a second conductive layer over the ferroelectric layer. The first conductive layer is formed by a metal CVD method in which a temperature of the substrate is a first temperature. The ferroelectric layer is formed by an ALD method using a precursor including hafnium, a precursor including zirconium, and an oxidizer. The second conductive layer is formed by a metal CVD method in which a temperature of the substrate is a second temperature. The second temperature is higher than or equal to 250° C. and lower than or equal to 325° C. The first temperature is higher than the second temperature.

In the method for fabricating a semiconductor device, one or both of the first conductive layer and the second conductive layer are preferably formed using titanium chloride and ammonia.

In the method for fabricating a semiconductor device, one or both of the first conductive layer and the second conductive layer are preferably formed using tungsten hexafluoride.

In the method for fabricating a semiconductor device, after an insulating film to be the ferroelectric layer is formed, heat treatment at higher than or equal to 400° C. and lower than or equal to 600° C. is preferably performed by an RTA method using a lamp.

In the method for fabricating a semiconductor device, it is preferable that the first conductive layer include a first depressed portion, the ferroelectric layer be formed along the first depressed portion, the ferroelectric layer include a second depressed portion in a region overlapping with the first depressed portion, and the second conductive layer be formed to fill the second depressed portion.

In the method for fabricating a semiconductor device, it is preferable that the ferroelectric layer, in an X-ray diffraction analysis after the second conductive layer is formed, have a peak at of around 30.4°, and in the ferroelectric layer, in the X-ray diffraction analysis after the second conductive layer is formed, an intensity at 2θ of 28.5° be less than or equal to 0.1 times a peak intensity of the peak and an intensity at 2θ of 31.6° be less than or equal to 0.1 times a peak intensity of the peak.

### Effect of the Invention

One embodiment of the present invention can provide a novel semiconductor device. Another embodiment of the present invention can provide a semiconductor device that occupies a small area. Another embodiment of the present invention can provide a highly reliable semiconductor device. Another embodiment of the present invention can provide a semiconductor device with low power consumption. Another embodiment of the present invention can provide a semiconductor device with high storage capacity.

Note that the effects of one embodiment of the present invention are not limited to the effects listed above. The effects listed above do not preclude the existence of other effects. Accordingly, one embodiment of the present invention does not have the effects listed above in some cases. Note that the other effects are effects that are not described in this section and will be described below. The other effects are derived from the description of the specification, the drawings, and the like and can be extracted as appropriate from the description by those skilled in the art. One embodiment of the present invention has at least one of the effects listed above and the other effects.

### BRIEF DESCRIPTION OF THE DRAWINGS

FIG. 1A is a plan view illustrating a structure example of a semiconductor device. FIG. 1B and

FIG. 1C are cross-sectional views illustrating the structure example of the semiconductor device.

FIG. 2A to FIG. 2F are cross-sectional views illustrating structure examples of semiconductor devices.

FIG. 3A to FIG. 3D are cross-sectional views illustrating structure examples of semiconductor devices.

FIG. 4A is a plan view illustrating a structure example of a semiconductor device. FIG. 4B and FIG. 4C are cross-sectional views illustrating the structure example of the semiconductor device.

FIG. 5A is a plan view illustrating a structure example of a semiconductor device. FIG. 5B and FIG. 5C are cross-sectional views illustrating the structure example of the semiconductor device.

FIG. 6A to FIG. 6H are cross-sectional views illustrating an example of a method for fabricating a semiconductor device.

FIG. 7A to FIG. 7D are cross-sectional views illustrating an example of a method for fabricating a semiconductor device.

FIG. 8 is a diagram showing crystal structures that HfO₂ can have and polarization-electric field characteristics of the crystal structures, which are disclosed in Non-Patent Document 4.

FIG. 9A is a plan view illustrating a structure example of a semiconductor device. FIG. 9B and FIG. 9C are cross-sectional views illustrating the structure example of the semiconductor device.

FIG. 10A is a plan view illustrating a structure example of a semiconductor device. FIG. 10B is a cross-sectional view illustrating the structure example of the semiconductor device.

FIG. 11 is a cross-sectional view illustrating a structure example of a semiconductor device.

FIG. 12 is a cross-sectional view illustrating a structure example of a semiconductor device.

FIG. 13A is a diagram illustrating an example of a circuit structure of a memory cell. FIG. 13B is a graph showing an example of hysteresis characteristics. FIG. 13C is a timing chart showing an example of a method for driving the memory cell.

FIG. 14A to FIG. 14C are diagrams illustrating structure examples of a storage device.

FIG. 15A is a diagram illustrating a structure example of a storage device. FIG. 15B is a schematic diagram of a memory string included in the storage device.

FIG. 16A is a diagram illustrating a structure example of a storage device. FIG. 16B is a schematic diagram of a memory string included in the storage device.

FIG. 17A and FIG. 17B are diagrams illustrating examples of a semiconductor device.

FIG. 18A and FIG. 18B are perspective views illustrating examples of electronic components.

FIG. 19A to FIG. 19J are diagrams illustrating examples of electronic devices.

FIG. 20A to FIG. 20E are diagrams illustrating examples of electronic devices.

FIG. 21A to FIG. 21C are diagrams illustrating examples of electronic devices.

FIG. 22 is a diagram illustrating an example of a device for space.

FIG. 23 is a schematic cross-sectional view illustrating samples fabricated in Example.

FIG. 24A to FIG. 24E are diagrams showing GIXRD measurement results.

### MODE FOR CARRYING OUT THE INVENTION

Embodiments and the like below will be described in detail with reference to the drawings. Note that the present invention is not limited to the following description, and it is readily understood by those skilled in the art that modes and details can be changed in various ways without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and repeated description thereof is omitted in some cases.

In this specification and the like, a semiconductor device refers to a device that utilizes semiconductor characteristics, and means a circuit including a semiconductor element (a transistor, a diode, a photodiode, and the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a storage device, a display device, a light-emitting device, a lighting device, an electronic device, and the like themselves might be semiconductor devices, or might include semiconductor devices.

The position, size, range, and the like of each component illustrated in drawings and the like do not represent the actual position, size, range, and the like in some cases for easy understanding of the invention. Therefore, the disclosed invention is not necessarily limited to the position, size, range, and the like disclosed in the drawings and the like. For example, in the actual manufacturing process, a layer, a resist mask, and the like might be unintentionally reduced in size by treatment such as etching, which is not illustrated in some cases for easy understanding of the invention.

In this specification and the like, in the case where an etching step (a removal step) is performed after a resist mask is formed by a lithography method (e.g., a photolithography method, an X-ray lithography method, an electron beam lithography method, a multiphoton lithography method, an interference lithography method, or a nanoimprinting method), the resist mask is removed after the etching step, unless otherwise specified.

Especially in a plan view (also referred to as a “top view”), a perspective view, and the like, the illustration of some components might be omitted for easy understanding of the invention. The illustration of some hidden lines and the like might also be omitted.

Note that in the structures of the invention in the embodiments, the same reference numerals are used in common for the same portions or portions having similar functions in different drawings, and repeated description thereof is omitted in some cases. Furthermore, the same hatch pattern is used for the portions having similar functions, and the portions are not especially denoted by reference numerals in some cases. Moreover, some components are omitted in a perspective view, a top view, and the like for easy understanding of the drawings in some cases.

Ordinal numbers such as “first” and “second” in this specification and the like are used in order to avoid confusion among components and do not denote any priority or order such as the order of steps or the stacking order. A term without an ordinal number in this specification and the like may be provided with an ordinal number in the scope of claims in order to avoid confusion among components. An ordinal number provided in this specification and the like and an ordinal number provided in the scope of claims might be different from each other. Even when a term is provided with an ordinal number in this specification and the like, the ordinal number might be omitted in the scope of claims and the like.

In this specification and the like, terms such as “electrode”, “wiring”, and “terminal” do not limit the functions of such components. For example, an “electrode” is used as part of a “wiring” in some cases, and vice versa. Furthermore, terms such as “electrode” and “wiring” also include the case where a plurality of “electrodes” and “wirings” are provided in an integrated manner, for example. As another example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, terms such as “electrode”, “wiring”, and “terminal” can sometimes be replaced with a term such as “region” depending on the case.

In this specification and the like, supply of a signal refers to supply of a predetermined potential to a wiring or the like. Thus, the term “signal” can be replaced with a term such as “potential” in some cases. A term such as “potential” can be replaced with the term “signal” in some cases. The “signal” may be a variable potential or a fixed potential. For example, it may be a power supply potential.

Note that the term “film” and the term “layer” can be used interchangeably depending on the case or the circumstances. For example, the term “conductive layer” can be changed to the term “conductive film” in some cases. As another example, the term “insulating film” can be changed to the term “insulating layer” in some cases.

In this specification and the like, a “capacitor element” can be, for example, a circuit element having an electrostatic capacitance value greater than 0 F, a region of a wiring having an electrostatic capacitance value greater than 0 F, parasitic capacitance, or gate capacitance of a transistor. The term “capacitor element”, “parasitic capacitance”, or “gate capacitance” can be replaced with the term “capacitor” in some cases. Conversely, the term “capacitor” can be replaced with the term “capacitor element”, “parasitic capacitance”, or “gate capacitance” in some cases. In addition, a “capacitor” (including a “capacitor” with three or more terminals) includes an insulating layer and a pair of conductive layers between which the insulating layer is interposed. Thus, the term “pair of conductive layers” of “capacitor” can be replaced with “pair of electrodes”, “pair of conductive regions”, “pair of regions”, or “pair of terminals”. The term “one of a pair of terminals” is referred to as “one terminal” or “first terminal” in some cases. The term “the other of the pair of terminals” is referred to as “the other terminal” or “second terminal” in some cases. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

Functions of a “source” and a “drain” of a transistor are sometimes interchanged with each other when a transistor of the opposite conductivity type is used or when the direction of current flow is changed in circuit operation, for example. Therefore, the terms “source” and “drain” can be used interchangeably in this specification and the like.

In this specification and the like, a “gate” refers to part or the whole of a gate electrode and a gate wiring. A gate wiring refers to a wiring for electrically connecting at least one gate electrode of a transistor to another electrode or another wiring.

In this specification and the like, a “source” refers to part or the whole of a source region, a source electrode, and a source wiring. A source region refers to a region in a semiconductor layer, where the resistivity is lower than or equal to a given value. A source electrode refers to a conductive layer including a part connected to a source region. A source wiring refers to a wiring for electrically connecting at least one source electrode of a transistor to another electrode or another wiring.

In this specification and the like, a “drain” refers to part or the whole of a drain region, a drain electrode, and a drain wiring. A drain region refers to a region in a semiconductor layer, where the resistivity is lower than or equal to a given value. A drain electrode refers to a conductive layer including a part connected to a drain region. A drain wiring refers to a wiring for electrically connecting at least one drain electrode of a transistor to another electrode or another wiring.

Unless otherwise specified, a transistor described in this specification and the like is an enhancement-mode (a normally-off mode) field-effect transistor. In the case where a transistor in this specification and the like is an n-channel transistor and unless otherwise specified, the threshold voltage (also referred to as “Vₜₕ”) of the transistor is higher than 0 V. In the case where the transistor in this specification and the like is a p-channel transistor and unless otherwise specified, Vₜₕ of the transistor is lower than or equal to 0 V. Unless otherwise specified, a plurality of transistors having the same conductivity type all have the same Vₜₕ.

Unless otherwise specified, off-state current in this specification and the like refers to a current flowing between a source and a drain of a transistor (also referred to as a “drain current” or “I_{d}”) when the transistor is in an off state (also referred to as a “non-conduction state” or a “cutoff” state). Unless otherwise specified, the off state of an n-channel transistor refers to a state where a potential difference (also referred to as a “gate voltage” or “V_{g}”) between its gate and source when the potential of the source is regarded as a reference potential is lower than the threshold voltage, and the off state of a p-channel transistor refers to a state where V_{g} is higher than the threshold voltage. For example, the off-state current of an n-channel transistor sometimes refers to drain current that flows when V_{g} is lower than Vₜₕ.

In this specification and the like, leakage current sometimes expresses the same meaning as off-state current. Furthermore, in this specification and the like, the off-state current sometimes refers to current that flows between a source and a drain of a transistor in an off state, for example.

Unless otherwise specified, an on-state current in this specification and the like refers to an I_{d} of a transistor in an on state (also referred to as a “conduction state”). Unless otherwise specified, the on state of an n-channel transistor refers to a state where V_{g} is higher than or equal to Vₜₕ, and the on state of a p-channel transistor refers to a state where V_{g} is lower than or equal to Vₜₕ. For example, the on-state current of an n-channel transistor sometimes refers to a drain current that flows when V_{g} is higher than or equal to Vₜₕ.

In this specification and the like, a high power supply potential VDD (hereinafter also simply referred to as “VDD” or a “potential H”) is a power supply potential higher than a low power supply potential VSS. The low power supply potential VSS (hereinafter also simply referred to as “VSS” or a “potential L”) is a power supply potential lower than the high power supply potential VDD. In addition, a ground potential GND (hereinafter also simply referred to as “GND”) can be used as VDD or VSS. For example, VSS is a potential lower than GND when VDD is GND, and VDD is a potential higher than GND when VSS is GND. Note that in this specification and the like, VSS is a reference potential unless otherwise specified.

A “voltage” usually refers to a potential difference between a given potential and a reference potential (e.g., aground potential or a source potential). A “potential” is a relative value, and a potential supplied to a wiring or the like changes depending on the reference potential in some cases. Therefore, the terms “voltage” and “potential” can be replaced with each other in some cases.

In this specification and the like, terms for describing arrangement, such as “over”, “under”, “above”, and “below”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulating layer positioned over a conductive layer” can be replaced with the expression “an insulating layer positioned under a conductive layer” when the direction of a drawing illustrating these components is rotated by 180°. For example, the expression “an insulating layer positioned over an opening” includes “an insulating layer positioned on a side surface of an opening” in some cases.

Furthermore, the term “over” or “under” does not necessarily mean that a component is placed directly over or directly under and in direct contact with another component. For example, the expression “an electrode B over an insulating layer A” does not necessarily mean that the electrode B is formed on and in direct contact with the insulating layer A, and does not exclude the case where another component is provided between the insulating layer A and the electrode B.

The term “overlap”, for example, in this specification and the like does not limit a state such as the stacking order of components. For example, the expression “the electrode B overlapping with the insulating layer A” does not necessarily mean the state where the electrode B is formed over the insulating layer A, and does not exclude the state where the electrode B is formed under the insulating layer A and the state where the electrode B is formed on the right side (or the left side) of the insulating layer A.

Each of the terms “adjacent” and “proximity” in this specification and the like does not necessarily mean that a component is directly in contact with another component. For example, the expression “the electrode B adjacent to the insulating layer A” does not necessarily mean that the electrode B is formed in direct contact with the insulating layer A and does not exclude the case where another component is provided between the insulating layer A and the electrode B.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 800 and less than or equal to 100°. Thus, the case where the angle is greater than or equal to 850 and less than or equal to 950 is also included. Furthermore, “approximately perpendicular” or “substantially perpendicular” indicates a state where two straight lines are placed at an angle greater than or equal to 600 and less than or equal to 120°.

In the drawings and the like in this specification, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

In this specification and the like, when a plurality of components are denoted by the same reference numerals, and in particular need to be distinguished from each other, an identification sign such as “A”, “b”, “_1”, “[n]”, or “[m, n]” is sometimes added to the reference numerals. For example, a conductive layer 120 is divided and shown as a conductive layer 120a and a conductive layer 120b in some cases.

### Embodiment 1

In this embodiment, a semiconductor device of one embodiment of the present invention will be described.

### <Structure Example of Semiconductor Device>

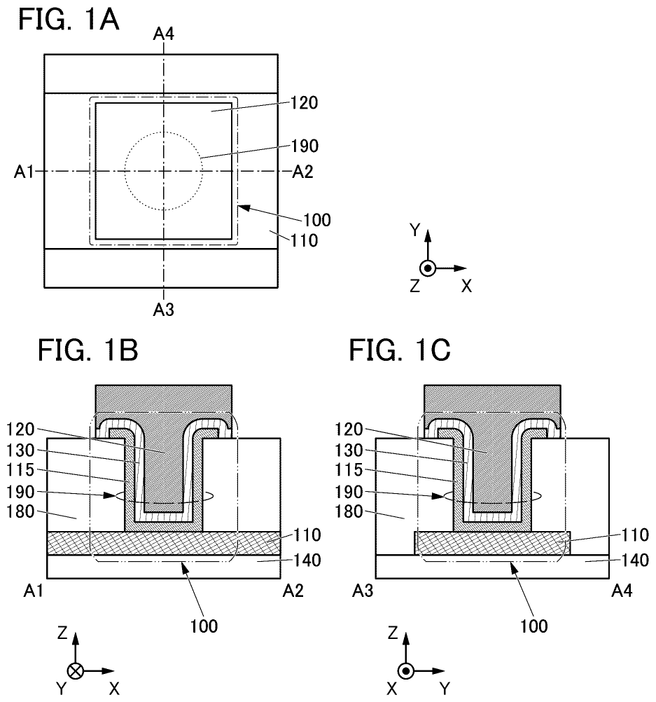

Structure examples of the semiconductor device of one embodiment of the present invention will be described below with reference to FIG. 1A to FIG. 4C.

FIG. 1A to FIG. 1C are a plan view and cross-sectional views illustrating a structure example of the semiconductor device of one embodiment of the present invention. FIG. 1A is a plan view of the semiconductor device. FIG. 1B is a cross-sectional view of a portion indicated by the dashed-dotted line A1-A2 in FIG. 1A, which is seen from the Y direction. FIG. 1C is a cross-sectional view of a portion indicated by the dashed-dotted line A3-A4 in FIG. 1A, which is seen from the X direction. Note that for clarity of the drawing, some components are omitted in the plan view of FIG. 1A.

The semiconductor device of one embodiment of the present invention includes an insulating layer 140 over a substrate (not illustrated), a conductive layer 110 over the insulating layer 140, a capacitor 100 over the conductive layer 110, and an insulating layer 180. The insulating layer 140 and the insulating layer 180 function as interlayer films, and the conductive layer 110 functions as a wiring.

The capacitor 100 includes a conductive layer 115 over the conductive layer 110, an insulating layer 130 over the conductive layer 115, and the conductive layer 120 over the insulating layer 130. In the capacitor 100, the conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 forms a MIM (Metal-Insulator-Metal) capacitor. In this embodiment, a material that can have ferroelectricity is used for the insulating layer 130. In this case, the insulating layer 130 has ferroelectricity. Thus, the capacitor 100 functions as a ferroelectric capacitor.

As illustrated in FIG. 1B and FIG. 1C, an opening portion 190 reaching the conductive layer 110 is provided in the insulating layer 180. At least part of the conductive layer 115 is placed in the opening portion 190. The conductive layer 115 includes a region in contact with the top surface of the conductive layer 110 in the opening portion 190 and a region in contact with the side surface of the insulating layer 180 in the opening portion 190. The conductive layer 115 includes a depressed portion in a region overlapping with the opening portion 190. Note that in the structures illustrated in FIG. 1B and FIG. 1C, the conductive layer 115 includes a region in contact with at least part of the top surface of the insulating layer 180.

The insulating layer 130 is placed so as to be at least partly positioned in the opening portion 190. The insulating layer 130 includes a region in contact with the top surface of the conductive layer 115 in the opening portion 190. That is, the insulating layer 130 includes a region formed along the depressed portion of the conductive layer 115. The insulating layer 130 has a depressed portion in a region overlapping with the depressed portion of the conductive layer 115. Note that in the structures illustrated in FIG. 1B and FIG. 1C, the insulating layer 130 includes a region in contact with at least part of the top surface of the insulating layer 180.

The conductive layer 120 is placed so as to be at least partly positioned in the opening portion 190. The conductive layer 120 includes a region in contact with the top surface of the insulating layer 130 in the opening portion 190. The conductive layer 120 is provided to fill the depressed portion of the insulating layer 130. That is, the conductive layer 120 is provided to fill the opening portion 190.

The capacitor 100 has a structure in which the upper electrode and the lower electrode face each other with the dielectric therebetween on the side surface of the opening portion 190 as well as on the bottom surface of the opening portion 190; thus, the electrostatic capacitance per unit area can be larger than that of a parallel plate capacitor. Thus, the deeper the opening portion 190 is, the higher the electrostatic capacitance of the capacitor 100 can be.

The sidewall of the opening portion 190 is preferably perpendicular to the top surface of the conductive layer 110. In that case, the opening portion 190 has a cylindrical shape. This structure enables miniaturization or high integration of the semiconductor device.

The sidewall of the opening portion 190 can have a tapered shape with respect to the top surface of the conductive layer 110. When the sidewall of the opening portion 190 has a tapered shape with respect to the top surface of the conductive layer 110, coverage with the conductive layer 115 and the like is improved, so that defects such as voids can be reduced.

In this specification and the like, a tapered shape refers to such a shape that at least part of a side surface of a component is inclined with respect to a substrate surface or a formation surface. For example, a tapered shape includes a region where the angle between the inclined side surface and the substrate surface or the formation surface (such an angle is also referred to as a taper angle) is greater than 0 degrees and less than 90 degrees. Note that the side surface of the component, the substrate surface, and the formation surface are not necessarily completely flat, and may have a substantially planar shape with a small curvature or a substantially planar shape with slight unevenness.

The conductive layer 115 and the insulating layer 130 are stacked along the sidewall of the opening portion 190 and the top surface of the conductive layer 110. The conductive layer 120 is provided over the insulating layer 130 to fill the opening portion 190. The capacitor 100 having such a structure may be referred to as a trench-type capacitor or a trench capacitor.

Although this embodiment describes the example where the opening portion 190 is circular in the plan view, the present invention is not limited thereto. The opening portion 190 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than 180°) or a convex polygonal shape (a polygonal shape all the interior angles of which are less than or equal to 180°). As illustrated in FIG. 1A, the opening portion 190 in the plan view preferably has a circular shape. When the opening portions have a circular shape, processing accuracy in forming the opening portions can be high, whereby the opening portions can be formed to have minute sizes. In this specification and the like, a circular shape is not necessarily a perfect circular shape.

### <Component Materials for Semiconductor Device>

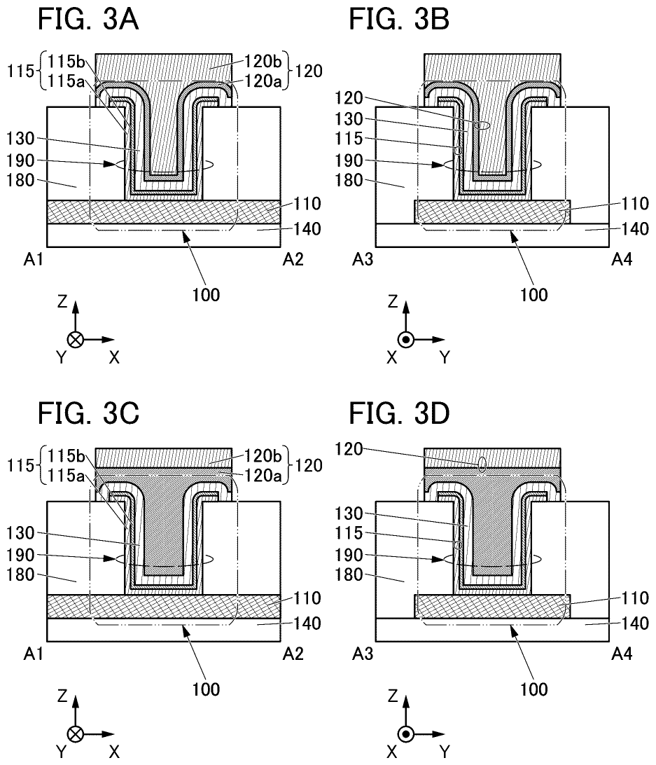

Materials that can be used for the semiconductor device of this embodiment will be described below. Note that each layer included in the semiconductor device of this embodiment may have a single-layer structure or a stacked-layer structure. FIG. 1B and FIG. 1C illustrate an example in which the conductive layer 115 and the conductive layer 120 each have a single-layer structure. FIG. 3A and FIG. 3B illustrate an example in which the conductive layer 115 and the conductive layer 120 each have a stacked-layer structure.

### [Insulating Layer 130]

As described above, a material that can have ferroelectricity is used for the insulating layer 130.

Here, a material that can have ferroelectricity is described. In this specification and the like, a material that can have ferroelectricity refers to a material that can have hysteresis characteristics in the relation between the intensity of an electric field applied to the material (electric field intensity) and the polarization magnitude, or a material in which spontaneous polarization occurs even with no external electric field (electric field applied to the material from the outside). Thus, the material that can have ferroelectricity includes a material having one or more of ferroelectricity, anti-ferroelectricity, and ferrielectricity.

In this specification and the like, the material that can have ferroelectricity processed into a layered shape is sometimes referred to as a ferroelectric layer. Thus, the insulating layer 130 can sometimes be rephrased as a ferroelectric layer. A device that includes such a ferroelectric layer is sometimes referred to as a ferroelectric device in this specification and the like.

As the material that can have ferroelectricity, an oxide containing one or both of hafnium and zirconium is given. As the metal oxide containing one or both of hafnium and zirconium, hafnium oxide, zirconium oxide, and hafnium zirconium oxide are given. Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X} (X is a real number greater than 0)), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the atomic ratio of the element M1 to the element M2 to the element M3 can be set as appropriate.

Examples of the material that can have ferroelectricity also include a perovskite-type oxynitride such as SrTaO₂N or BaTaO₂N, GaFeO₃ with a κ-alumina-type structure, and the like.

In the above description, metal oxides and metal nitrides are presented as non-limiting examples. For example, a metal oxynitride in which nitrogen is added to any of the above metal oxides, a metal nitride oxide in which oxygen is added to any of the above metal nitrides, or the like may be used.

The material that can have ferroelectricity can be, for example, a mixture or a compound formed of a plurality of materials selected from the above-listed materials. Alternatively, the insulating layer can have a stacked-layer structure of a plurality of materials selected from the above-listed materials. Note that the crystal structures (properties) of the above-listed materials and the like can be changed depending on the processes as well as the formation conditions; thus, a material that exhibits ferroelectricity is referred to not only as a ferroelectric but also as a material that can have ferroelectricity in this specification and the like.

For the insulating layer 130, an oxide containing one or both of hafnium and zirconium is preferably used, and hafnium zirconium oxide is further preferably used. In the case where hafnium zirconium oxide is used for the insulating layer 130, the insulating layer 130 includes hafnium, zirconium, and oxygen.

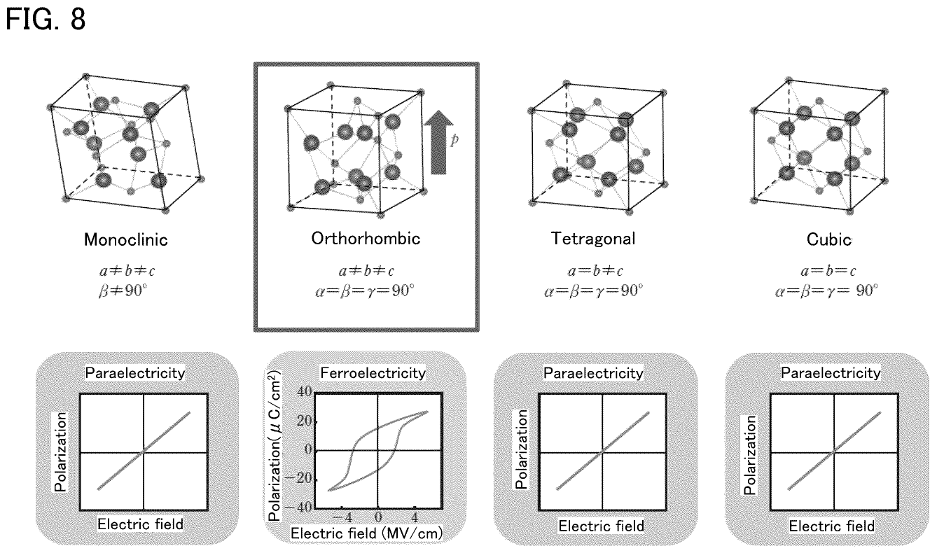

Crystal structures of hafnium oxide, which is a material that can be used for the insulating layer 130, are described here. As reported also in Non-Patent Document 4, hafnium oxide is known to take on various crystal structures. For example, hafnium oxide can take on crystal structures such as monoclinic (space group: P2₁/c), orthorhombic (space group: Pbca or Pca2₁), tetragonal (space group: P4₂/nmc), and cubic (space group: Fm-3m) crystal structures (see FIG. 8). Phase transition can occur between the above-described crystal structures. Note that the same applies to hafnium zirconium oxide.

In hafnium zirconium oxide, monoclinic, tetragonal, and cubic crystal structures each have an inverted center. Thus, hafnium oxide including a crystal having such a crystal structure is a paraelectric that does not have remanent polarization. On the other hand, the orthorhombic crystal structure belonging to the space group Pca2₁ does not have central symmetry. Accordingly, oxygen is displaced by an external electric field in the orthorhombic crystal structure belonging to the space group Pca2₁, and thus ferroelectricity is exhibited in hafnium oxide including a crystal having an orthorhombic crystal structure belonging to the space group Pca2₁.

Accordingly, ferroelectricity is presumably exhibited depending on a crystal structure of a crystal included in a ferroelectric layer. Thus, in order that the insulating layer 130 can exhibit ferroelectricity, the insulating layer 130 needs to include a crystal. It is particularly preferable that the insulating layer 130 include a crystal having an orthorhombic crystal structure belonging to the space group Pca2₁ to exhibit ferroelectricity. In addition, when the proportion of the crystal having an orthorhombic structure in the insulating layer 130 is increased, the amount of remanent polarization can be increased.

Note that in hafnium zirconium oxide, a crystal having a monoclinic, a tetragonal, or a cubic crystal structure is stable under normal pressure, and a crystal having an orthorhombic crystal structure is metastable under normal pressure. Thus, it is presumed that a crystal having a monoclinic, a tetragonal, or a cubic crystal structure is less likely to undergo a phase transition to an orthorhombic crystal structure even when heat treatment or the like is performed. Hereinafter, a crystal that is stable under normal pressure is referred to as a stable phase, and a crystal that is metastable under normal pressure is referred to as a metastable phase in some cases.

Accordingly, the content percentage of the metastable phase in the insulating layer 130 is preferably high. Furthermore, the content percentage of the stable phase in the insulating layer 130 is preferably low. That is, the insulating layer 130 preferably has a high content percentage of a crystal having an orthorhombic crystal structure and a low content percentage of a crystal having a monoclinic, a tetragonal, or a cubic crystal structure. For example, the sum of the content percentage of a crystal having a monoclinic crystal structure, the content percentage of a crystal having a tetragonal crystal structure, and the content percentage of a crystal having a cubic crystal structure is preferably low. For another example, each of the content percentage of a crystal having a monoclinic crystal structure, the content percentage of a crystal having a tetragonal crystal structure, and the content percentage of a crystal having a cubic crystal structure is preferably low. A crystal structure of a crystal included in the insulating layer 130 can be evaluated with X-ray diffraction (XRD), for example. Specifically, evaluation is possible using an XRD spectrum that is obtained by grazing-incidence XRD (GIXRD) measurement. Note that a GIXRD method is also referred to as a thin film method or a Seemann-Bohlin method. Hereinafter, an XRD spectrum obtained from GIXRD measurement is simply referred to as an XRD spectrum in some cases.

In this specification and the like, a peak in XRD analysis refers to a convex shape appearing in an XRD spectrum. Note that one peak is sometimes formed by an overlap of a plurality of peaks. A peak intensity refers to a local maximum value of a convex shape (peak) appearing in an XRD spectrum. A peak position refers to the value of the X-ray diffraction angle (2θ) at a local maximum value of a convex shape (peak) appearing in an XRD spectrum.

For example, in the case where hafnium zirconium oxide includes a crystal having an orthorhombic, a tetragonal, or a cubic crystal structure, a peak derived from an orthorhombic, a tetragonal, or a cubic crystal structure is detected at 2θ of around 30.4° in the X-ray diffraction analysis of the hafnium zirconium oxide. In the case where hafnium zirconium oxide includes a crystal having a monoclinic crystal structure, a peak derived from the (−111) plane of the monoclinic crystal structure is detected at 2θ of around 28.5° and a peak derived from the (111) plane of the monoclinic crystal structure is detected at 2θ of around 31.6° in the X-ray diffraction analysis of the hafnium zirconium oxide. Hereinafter, a peak detected at 2θ of around 30.4° is referred to as a first peak, a peak detected at 2θ of around 28.5° is referred to as a second peak, and a peak detected at 2θ of around 31.6° is referred to as a third peak. Note that in this specification and the like, “around a certain angle A” in an XRD spectrum means plus or minus 0.5° inclusive of A.

To increase the ferroelectricity of the insulating layer 130, it is preferable that the first peak be detected and neither the second peak nor the third peak be detected in the X-ray diffraction analysis of the insulating layer 130. In the X-ray diffraction analysis of the insulating layer 130, the intensity at 2θ of 28.5° and the intensity at 2θ of 31.6° are each preferably less than or equal to 0.1 times the peak intensity of the first peak, further preferably less than or equal to 0.02 times the peak intensity of the first peak, still further preferably less than or equal to 0.01 times the peak intensity of the first peak. In that case, the content percentage of a crystal having a monoclinic crystal structure included in the insulating layer 130 is reduced, so that the ferroelectricity of the insulating layer 130 can be increased.

Note that the first peak and the second peak overlap with each other in some cases. Furthermore, the first peak and the third peak overlap with each other in some cases. For example, in the case where the first peak and the third peak overlap with each other, the XRD spectrum can be subjected to waveform separation to calculate each of the peak intensities of the first peak and the third peak. For example, when a peak set for each crystal structure is fitted using a synthetic spectrum with respect to an actually measured XRD spectrum, the peak intensity can be calculated.

Note that in the X-ray diffraction analysis, it is difficult to distinguish whether a peak detected at 2θ of around 30.4° is derived from an orthorhombic crystal structure, a tetragonal crystal structure, or a cubic crystal structure. Thus, the content percentage of a crystal included the insulating layer 130 can be evaluated by electron diffraction (ED) mapping using a high-resolution transmission electron microscope (TEM), for example.

The higher the oxygen vacancy (Vo) concentration in an oxide containing one or both of hafnium and zirconium is, the more likely it is to generate a crystal having an orthorhombic crystal structure. Thus, an element that increases the oxygen vacancy concentration in the oxide containing one or both of hafnium and zirconium is preferably added to the oxide. Examples of the element include Group 3 elements (also referred to as Group IIIa elements) in the periodic table. The Group 3 element in the periodic table that is added to the oxide is further preferably one or more selected from scandium, lanthanum, and yttrium, still further preferably one or both of lanthanum and yttrium. Note that in this specification and the like, the Group 3 elements in the periodic table may be simply referred to as Group 3 elements.

In the oxide containing one or both of hafnium and zirconium, hafnium and zirconium are likely to have a valence of +4. Meanwhile, in an oxide containing a Group 3 element, the Group 3 element is likely to have a valence of +3. Thus, when an element having a valence different from that of hafnium and that of zirconium is added to the oxide containing one or both of hafnium and zirconium, the oxygen vacancy concentration in the oxide can be increased.

When at least one of the Group 3 elements is added to the oxide containing one or both of hafnium and zirconium, the grain size of a crystal included in the oxide can be reduced in some cases. By reducing the grain size of the crystals included in the oxide and reducing the grain size variation, the breakdown voltage of the oxide can be increased, enabling high withstand voltage. Furthermore, the amount of leakage current can be reduced.

When at least one of the Group 3 elements is added to the oxide containing one or both of hafnium and zirconium, a crystal having an orthorhombic crystal structure is sometimes more likely to be generated in the oxide than a crystal having a monoclinic crystal structure. This is probably because an element having a larger ion radius than hafnium and zirconium is added. In view of this, lanthanum and yttrium are particularly preferable as the Group 3 element added to the oxide.

Note that addition of excess Group 3 element to the oxide containing one or both of hafnium and zirconium might decrease the crystallinity of the oxide and adversely affect the generation of ferroelectricity. Thus, the content percentage of the Group 3 element added to the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the total number of metal element atoms contained in the ferroelectric layer. When the Group 3 element is added to the oxide within the above range, the remanent polarization can be improved, high withstand voltage can be achieved, and the amount of leakage current can be reduced, for example.

Accordingly, the insulating layer 130 preferably contains one or both of hafnium and zirconium, at least one of the Group 3 elements, and oxygen, further preferably contains hafnium, zirconium, at least one of the Group 3 elements, and oxygen, still further preferably contains hafnium, zirconium, one or both of lanthanum and yttrium, and oxygen. In other words, for the insulating layer 130, an oxide containing one or both of hafnium and zirconium to which at least one of the Group 3 elements is added is preferably used, hafnium zirconium oxide to which at least one of the Group 3 elements is added is further preferably used, and hafnium zirconium oxide to which one or both of lanthanum and yttrium are added is still further preferably used.

The content percentage of at least one of the Group 3 elements in the insulating layer 130 is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. For example, in the case where the insulating layer 130 contains lanthanum as at least one of the Group 3 elements, the content percentage of lanthanum in the insulating layer 130 preferably falls within the above range. In addition, for example, in the case where the insulating layer 130 contains lanthanum and yttrium as at least one of the Group 3 elements, the sum of the content percentage of lanthanum and the content percentage of yttrium in the insulating layer 130 preferably falls within the above range.

Note that by forming an oxide containing one or both of hafnium and zirconium, forming an oxide containing at least one of the Group 3 elements, and then performing heat treatment, an oxide containing one or both of hafnium and zirconium and at least one of the Group 3 elements may be formed.

Alternatively, by forming an oxide containing at least one of the Group 3 elements, forming an oxide containing one or both of hafnium and zirconium, and then performing heat treatment, an oxide containing one or both of hafnium and zirconium and at least one of the Group 3 elements may be formed.

Alternatively, by forming an oxide containing one or both of hafnium and zirconium and performing treatment adding the Group 3 element, an oxide containing one or both of hafnium and zirconium and at least one of the Group 3 elements may be formed. In that case, in the treatment adding the Group 3 element, oxygen vacancies are sometimes formed in the oxide containing one or both of hafnium and zirconium. That is, the addition of the Group 3 element can promote an increase in the oxygen vacancy concentration in the oxide. The treatment adding the Group 3 element can be performed by, for example, an ion doping method, an ion implantation method, or the like.

Note that as the insulating layer 130, a single layer or stacked layers of any of the insulating materials described later in [Insulating layer] may be used.

### [Insulating Layer]

An inorganic insulating film is preferably used for each of the insulating layers (the insulating layer 140, the insulating layer 180, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

Examples of the material with high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic resin. Other examples of the inorganic insulating material with low relative permittivity include silicon oxide to which fluorine is added, silicon oxide to which carbon is added, and silicon oxide to which carbon and nitrogen are added. Another example is porous silicon oxide. These silicon oxides can contain nitrogen.

A material that can have ferroelectricity can be used for the above-described insulating layer included in the semiconductor device. For the insulating layer included in the semiconductor device, an insulating material described in [Insulating layer] in Embodiment 2 below can be used.

The insulating layer 140 and the insulating layer 180 function as interlayer films and thus preferably have low relative permittivity. When a material with low relative permittivity is used for an interlayer film, parasitic capacitance generated between wirings can be reduced. Silicon oxide and silicon oxynitride are thermally stable, and thus are suitable for the insulating layer 140 and the insulating layer 180.

### [Conductive Layer]

For each of the conductive layers included in the semiconductor device (e.g., the conductive layer 110, the conductive layer 115, and the conductive layer 120), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As the alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Alternatively, a semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include an indium oxide containing tungsten oxide, an indium oxide containing titanium oxide, an indium tin oxide (also referred to as ITO), an indium tin oxide containing titanium oxide, an indium tin oxide containing silicon (also referred to as ITSO), an indium zinc oxide (also referred to as IZO (a registered trademark)), and an indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may also be employed. A stacked-layer structure combining a material containing the above metal element, a conductive material containing oxygen, and a conductive material containing nitrogen may also be employed.

For the conductive layer included in the semiconductor device, a conductive material described in [Conductive layer] in Embodiment 2 below can be used.

In addition, a conductive material that is less likely to be oxidized, a conductive material having a function of inhibiting diffusion of oxygen, or the like is preferably used for the conductive layer 115. For example, titanium nitride, tantalum nitride, or the like can be used. In the case where titanium nitride is used for the conductive layer 115, the conductive layer 115 contains titanium and nitrogen.

For the conductive layer 115, a conductive material having a function of absorbing oxygen is preferably used. Since the conductive layer 115 is in contact with the insulating layer 130, the use of a conductive material having a function of absorbing oxygen for the conductive layer 115 enables oxygen to be absorbed from the insulating layer 130, so that the oxygen vacancy concentration in the insulating layer 130 can be increased. Accordingly, the remanent polarization can be increased. Examples of the conductive material having a function of absorbing oxygen include a metal element, an alloy containing a metal element as its component, and an alloy containing a combination of metal elements. As the alloy containing a metal element as its component, an oxide of the alloy may be used. Specific examples include tungsten, molybdenum, ruthenium, titanium, and tantalum. These conductive materials are also conductive materials that do not contain nitrogen. Note that in this specification and the like, a conductive material that does not contain nitrogen refers to a conductive material whose nitrogen concentration is lower than or equal to 1 atomic %.

For example, tungsten is a conductive material with high conductivity and thus can be suitably used for the conductive layer 115. Furthermore, since an oxide of ruthenium also has high conductivity, ruthenium can be suitably used for the conductive layer 115, for example. Thus, tungsten or ruthenium is preferably used for the conductive layer 115. In the case where tungsten is used for the conductive layer 115, the conductive layer 115 contains tungsten.

In the case where a conductive material having a function of absorbing oxygen is used for the conductive layer 115, oxygen in the insulating layer 130 is diffused into the conductive layer 115. Thus, the oxygen vacancy concentration in the insulating layer 130 has a gradient in the direction from the conductive layer 115 toward the sidewall or the bottom surface of the opening portion 190. In other words, the direction in which oxygen vacancies are generated is the same as the direction from the conductive layer 115 toward the sidewall or the bottom surface of the opening portion 190. In the case where an oxide containing one or both of hafnium and zirconium is formed and treatment adding a Group 3 element is performed as described above, the Group 3 element is preferably added in the direction in which oxygen vacancies are generated. Forming the insulating layer 130 in such a manner can further increase the oxygen vacancy concentration in the oxide.

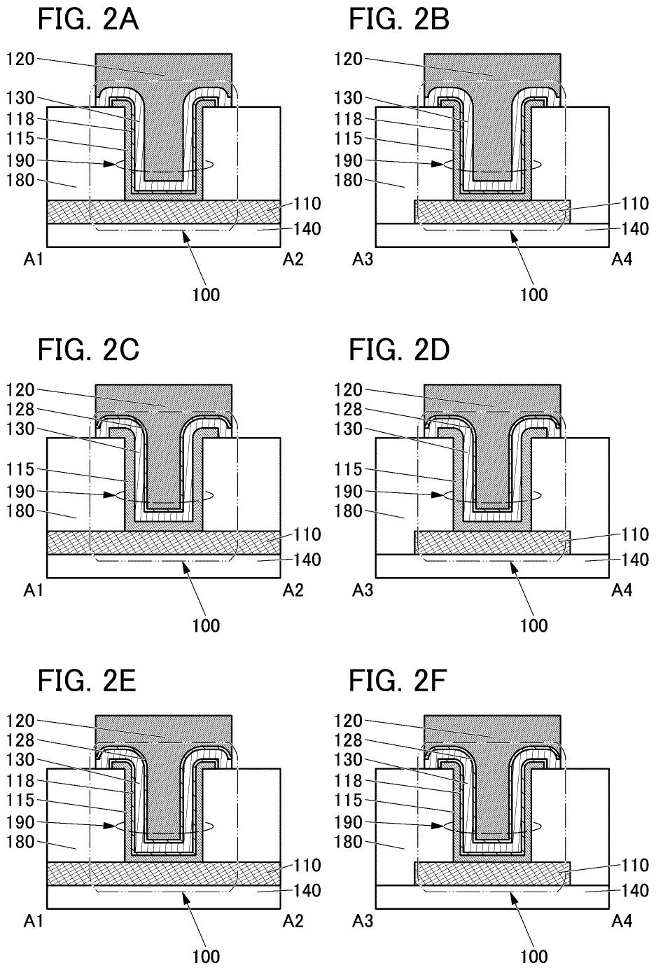

Note that in the case where a conductive material having a function of absorbing oxygen is used for the conductive layer 115, a layer 118 is sometimes formed between the conductive layer 115 and the insulating layer 130, as illustrated in FIG. 2A and FIG. 2B. Here, when a metal contained in the conductive layer 115 is a metal MX, the layer 118 contains the metal MX and oxygen. In the case where an oxide containing the metal MX is used for the conductive layer 115, the oxygen concentration in the layer 118 is higher than that in the conductive layer 115. The concentration of the metal MX in the layer 118 is lower than that of the metal MX in the conductive layer 115.

In the case where the layer 118 is formed between the conductive layer 115 and the insulating layer 130, the capacitor 100 includes the conductive layer 115, the layer 118 over the conductive layer 115, the insulating layer 130 over the layer 118, and the conductive layer 120 over the insulating layer 130.

The layer 118 may have conductivity or an insulating property. In the case where the layer 118 has conductivity, the layer 118 includes a region functioning as the other of the pair of electrodes of the capacitor 100. In the case where the layer 118 has an insulating property, the physical distance between the conductive layer 115 and the conductive layer 120 can be increased, so that the parasitic capacitance generated between the conductive layer 115 and the conductive layer 120 can be reduced.

FIG. 3A and FIG. 3B each illustrate an example in which the conductive layer 115 has a two-layer structure of a conductive layer 115a and a conductive layer 115b over the conductive layer 115a.

For example, tungsten can be used for the conductive layer 115a, and titanium nitride or tantalum nitride can be used for the conductive layer 115b. In this case, titanium nitride or tantalum nitride is in contact with the insulating layer 130. With such a structure, when an oxide insulator is used as the insulating layer 130, oxidation of the conductive layer 115 due to the insulating layer 130 can be inhibited.

For another example, titanium nitride or tantalum nitride can be used for the conductive layer 115a, and tungsten can be used for the conductive layer 115b. With such a structure, when an oxide insulator is used as the insulating layer 180, oxidation of the conductive layer 115 due to the insulating layer 180 can be inhibited. Furthermore, when oxygen is absorbed from the insulating layer 130 and the oxygen vacancy concentration in the insulating layer 130 is increased, remanent polarization can be increased.

One or both of the conductive layer 115a and the conductive layer 115b may have a stacked-layer structure. For example, in the case where the conductive layer 115a has a two-layer structure of a first conductive layer and a second conductive layer over the first conductive layer, titanium nitride or tantalum nitride can be used for each of the first conductive layer of the conductive layer 115a and the conductive layer 115b, and tungsten can be used for the second conductive layer of the conductive layer 115a. With such a structure, when an oxide insulator is used as the insulating layer 130, oxidation of the conductive layer 115 due to the insulating layer 130 can be inhibited. Furthermore, when an oxide insulator is used as the insulating layer 180, oxidation of the conductive layer 115 due to the insulating layer 180 can be inhibited.

A conductive material that is not easily oxidized, a conductive material having a function of inhibiting diffusion of oxygen, or the like is preferably used for the conductive layer 120. For example, titanium nitride, tantalum nitride, or the like can be used. In the case where titanium nitride is used for the conductive layer 120, the conductive layer 120 contains titanium and nitrogen.

For the conductive layer 120, a conductive material having a function of absorbing oxygen is preferably used. Since the conductive layer 120 is in contact with the insulating layer 130, the use of a conductive material having a function of absorbing oxygen for the conductive layer 120 enables oxygen to be absorbed from the insulating layer 130, so that the oxygen vacancy concentration in the insulating layer 130 can be increased. Accordingly, the remanent polarization can be increased. For example, the conductive layer 120 is preferably formed using the above-described conductive material that does not contain nitrogen and is further preferably formed using tungsten.

In the case where a conductive material having a function of absorbing oxygen is used for the conductive layer 120, oxygen in the insulating layer 130 is diffused into the conductive layer 120. Thus, the oxygen vacancy concentration in the insulating layer 130 has a gradient in the direction from the bottom surface of the conductive layer 120 toward the top surface of the conductive layer 120. In other words, the direction in which oxygen vacancies are generated is the same as the direction from the bottom surface of the conductive layer 120 toward the top surface of the conductive layer 120. In the case where an oxide containing one or both of hafnium and zirconium is formed and treatment adding a Group 3 element is performed as described above, the Group 3 element is preferably added in the direction in which oxygen vacancies are generated. Forming the insulating layer 130 in such a manner can further increase the oxygen vacancy concentration in the oxide.

Note that in the case where a conductive material having a function of absorbing oxygen is used for the conductive layer 120, a layer 128 is sometimes formed between the insulating layer 130 and the conductive layer 120, as illustrated in FIG. 2C and FIG. 2D. Here, when a metal contained in the conductive layer 120 is a metal MY, the layer 128 contains the metal MY and oxygen. In the case where an oxide containing the metal MY is used for the conductive layer 120, the oxygen concentration in the layer 128 is higher than that in the conductive layer 120. The concentration of the metal MY in the layer 128 is lower than that of the metal MY in the conductive layer 120.

In the case where the layer 128 is formed between the insulating layer 130 and the conductive layer 120, the capacitor 100 includes the conductive layer 115, the insulating layer 130 over the conductive layer 115, the layer 128 over the insulating layer 130, and the conductive layer 120 over the layer 128.

The layer 128 may have conductivity or an insulating property. In the case where the layer 128 has conductivity, the layer 128 includes a region functioning as one of the pair of electrodes of the capacitor 100. In the case where the layer 128 has an insulating property, the physical distance between the conductive layer 115 and the conductive layer 120 can be increased, so that the parasitic capacitance generated between the conductive layer 115 and the conductive layer 120 can be reduced.

FIG. 3A and FIG. 3B each illustrate an example where the conductive layer 120 has a two-layer structure of the conductive layer 120a and the conductive layer 120b over the conductive layer 120a. Note that in the case where the conductive layer 120a is provided to fill the depressed portion of the insulating layer 130, the conductive layer 120b is provided such that its bottom surface is positioned above the top surface of the insulating layer 180 or the top surface of the insulating layer 130, as illustrated in FIG. 3C and FIG. 3D.

For example, titanium nitride or tantalum nitride can be used for the conductive layer 120a, and tungsten can be used for the conductive layer 120b. In this case, titanium nitride or tantalum nitride is in contact with the insulating layer 130. With such a structure, when an oxide insulator is used as the insulating layer 130, oxidation of the conductive layer 120 due to the insulating layer 130 can be inhibited.

For another example, tungsten can be used for the conductive layer 120a, and titanium nitride or tantalum nitride can be used for the conductive layer 120b. With such a structure, when oxygen is absorbed from the insulating layer 130 and the oxygen vacancy concentration in the insulating layer 130 is increased, remanent polarization can be increased.

One or both of the conductive layer 120a and the conductive layer 120b may have a stacked-layer structure. For example, in the case where the conductive layer 120a has a two-layer structure of the first conductive layer and the second conductive layer over the first conductive layer, a conductive material that is less likely to be oxidized or a conductive material having a function of inhibiting diffusion of oxygen can be used for the first conductive layer of the conductive layer 120a, a material with high conductivity can be used for the second conductive layer of the conductive layer 120a, and a conductive material that contains oxygen can be used for the conductive layer 120b. Specifically, it is possible to use titanium nitride or tantalum nitride for the first conductive layer of the conductive layer 120a, tungsten for the second conductive layer of the conductive layer 120a, and ITSO for the conductive layer 120b. With such a structure, when an oxide insulator is used as the insulating layer 130, oxidation of the conductive layer 120 due to the insulating layer 130 can be inhibited.

Note that in the case where a conductive material having a function of absorbing oxygen is used for each of the conductive layer 115 and the conductive layer 120, the layer 118 is sometimes formed between the conductive layer 115 and the insulating layer 130 and the layer 128 is sometimes formed between the insulating layer 130 and the conductive layer 120, as illustrated in FIG. 2E and FIG. 2F. In this case, the capacitor 100 includes the conductive layer 115, the layer 118 over the conductive layer 115, the insulating layer 130 over the layer 118, the layer 128 over the insulating layer 130, and the conductive layer 120 over the layer 128.

A conductive material with high conductivity such as tungsten can be used for the conductive layer 110. With use of a conductive material with high conductivity for the conductive layer 110, the conductive layer 110 can have improved conductivity and can work well as a wiring.

A single layer or stacked-layer including a conductive material that is not easily oxidized, a conductive material having a function of inhibiting diffusion of oxygen, or the like is preferably used for the conductive layer 110. For example, titanium nitride, ITSO, or the like may be used. Alternatively, for example, a structure in which titanium nitride is stacked over tungsten may be used. Alternatively, for example, a structure in which tungsten is stacked over a first titanium nitride and a second titanium nitride is stacked over the tungsten may be used. With such a structure, when an oxide insulator is used for the insulating layer 180, the conductive layer 110 can be inhibited from being oxidized by the insulating layer 180.

### [Substrate]

As a substrate where the semiconductor of one embodiment of the present invention is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is the above-described semiconductor substrate in which an insulator region is included, e.g., an SOI (Silicon On Insulator) substrate or the like. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor element, a resistor element, a switching element, a light-emitting element, and a storage element.

### <Modification Example of Semiconductor Device>

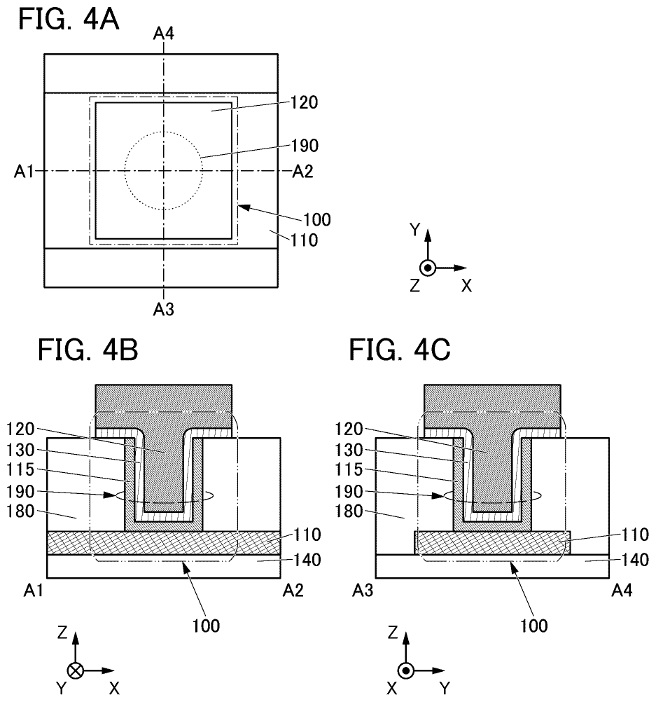

A modification example of the semiconductor device illustrated in FIG. 1A to FIG. 1C is described with reference to FIG. 4A to FIG. 4C. FIG. 4A is a plan view of the semiconductor device. FIG. 4B is a cross-sectional view of a portion indicated by the dashed-dotted line A1-A2 in FIG. 4A, which is seen from the Y direction. FIG. 4C is a cross-sectional view of a portion indicated by the dashed-dotted line A3-A4 in FIG. 4A, which is seen from the X direction. For simplification of the drawing, some components are omitted in the plan view of FIG. 4A.

The shape of the conductive layer 115 included in the semiconductor device illustrated in FIG. 4A to FIG. 4C is different from the shape of the conductive layer 115 included in the semiconductor device illustrated in FIG. 1A to FIG. 1C. Differences from the description with reference to FIG. 1A to FIG. 1C are mainly described below; the description is referred to for the same portions and the description of the same portion is omitted in some cases.

As illustrated in FIG. 4B and FIG. 4C, the conductive layer 115 is not in contact with the top surface of the insulating layer 180. In other words, the top surface of the conductive layer 115 is level with the top surface of the insulating layer 180. With such a structure, a step at the end portion of the conductive layer 115 can be reduced. Consequently, coverage with the insulating layer 130 and the like that are formed later can be improved. In addition, a short circuit between the conductive layer 115 and the conductive layer 120 can be prevented.

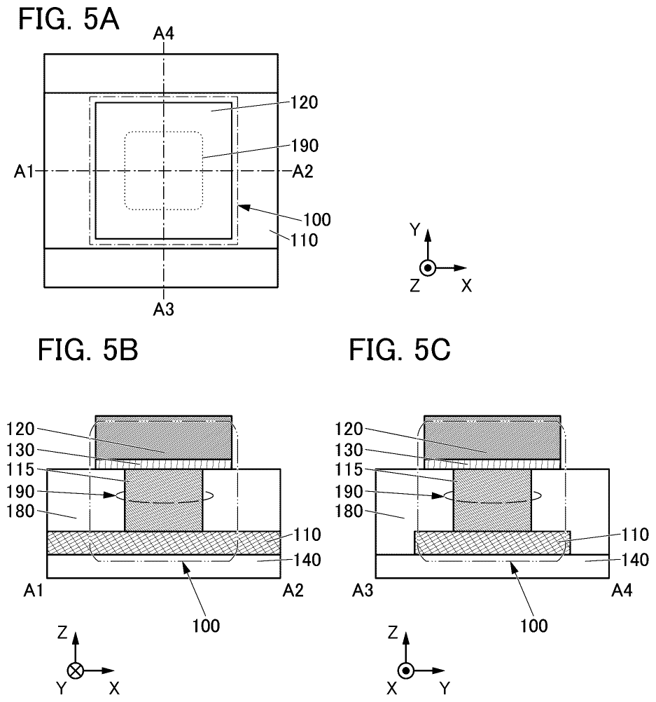

Note that the present invention is not limited thereto as long as the electrostatic capacitance necessary for the capacitor 100 is ensured. For example, as illustrated in FIG. 5B and FIG. 5C, the conductive layer 115 may be provided to fill the opening portion 190. Also in this case, the top surface of the conductive layer 115 is level with the top surface of the insulating layer 180. With such a structure, the insulating layer 130 and the conductive layer 120 can be formed over a formed component having a flat top surface. Therefore, formation of the insulating layer 130 and the conductive layer 120 is not limited to a film formation method providing good coverage. For example, when one or both of an insulating film to be the insulating layer 130 and a conductive film to be the conductive layer 120 are formed by a sputtering method with a high film formation rate, the semiconductor device can be fabricated with high productivity.

When the insulating layer 130 is formed over the formed component having a flat top surface, the insulating layer 130 can be formed to be flat. In addition, a structure in which the insulating layer 130 does not cover the corner portion of the top surface of the conductive layer 115 can be employed. Thus, the concentration of electric field on the insulating layer 130 can be inhibited. Accordingly, dielectric breakdown of the insulating layer 130 is inhibited, and thus a highly reliable semiconductor device can be provided.

FIG. 5B and FIG. 5C are cross-sectional views of the semiconductor device, and FIG. 5A is a plan view of the semiconductor device. In the plan view in FIG. 5A, the opening portion 190 has a quadrangular shape with rounded corners. When the opening portion 190 has a quadrangular shape with rounded corners in the plan view, as compared with the case where the opening portion 190 has a circular shape in the plan view, the electrostatic capacitance of the capacitor 100 can be increased. Note that the opening portion 190 in the plan view may have a substantially circular shape or a polygonal shape.

### <Example of Method for Fabricating Semiconductor Device>

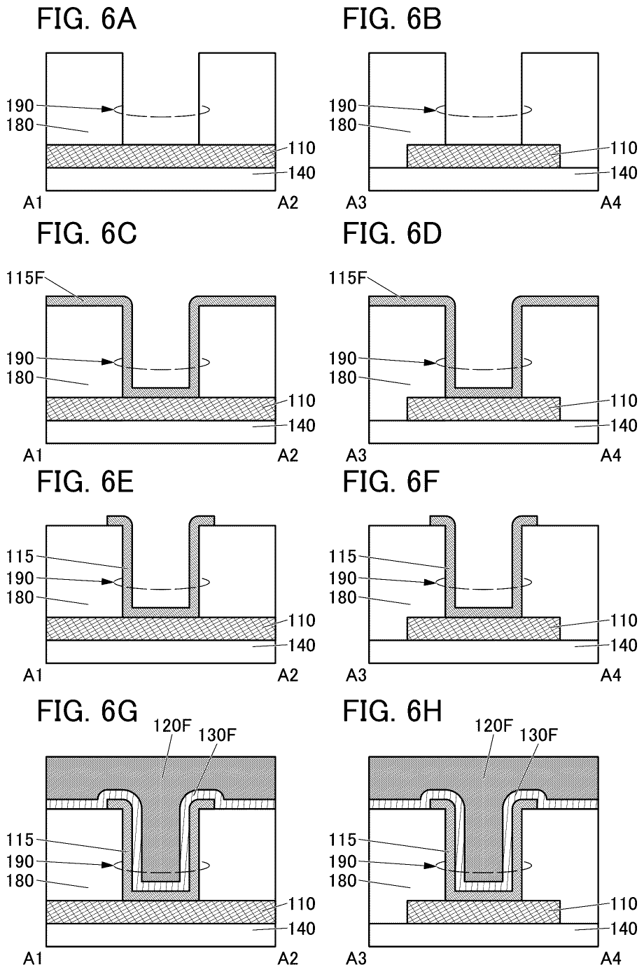

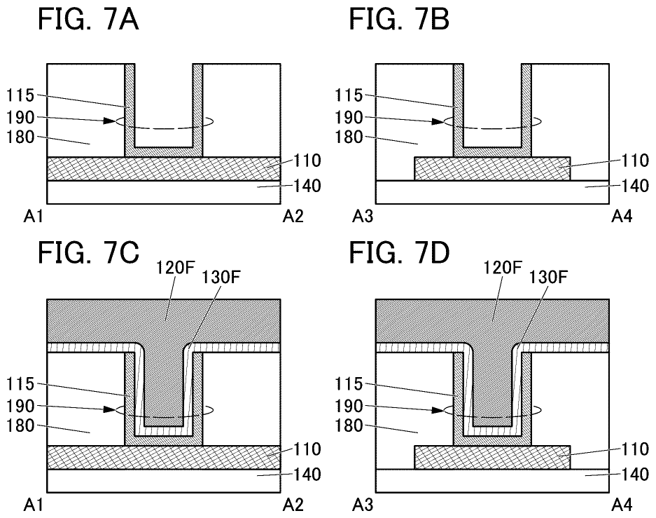

A method for fabricating the semiconductor device of one embodiment of the present invention will be described with reference to FIG. 6A to FIG. 7D. FIG. 6A, FIG. 6C, FIG. 6E, FIG. 7A, and FIG. 7C are cross-sectional views of the semiconductor device seen from the X direction, and FIG. 6B, FIG. 6D, FIG. 6F, FIG. 7B, and FIG. 7D are cross-sectional views of the semiconductor device seen from the Y direction. Note that as for a material and a formation method of each component, portions similar to the portions described above are not described in some cases.

Thin films included in the semiconductor device (e.g., insulating films, semiconductor films, and conductive films) can be formed by a sputtering method, a chemical vapor deposition (CVD) method, a vacuum evaporation method, a molecular beam epitaxy (MBE) method, a pulsed laser deposition (PLD) method, an atomic layer deposition (ALD) method, or the like.

Examples of a sputtering method include an RF sputtering method in which a high-frequency power source is used as a sputtering power source, a DC sputtering method in which a DC power source is used, and a pulsed DC sputtering method in which voltage applied to an electrode is changed in a pulsed manner. An RF sputtering method is mainly used in the case where an insulating film is formed, and a DC sputtering method is mainly used in the case where a metal conductive film is formed. The pulsed DC sputtering method is mainly used in the case where a compound such as an oxide, a nitride, or a carbide is formed by a reactive sputtering method.

Furthermore, CVD methods can be classified into a plasma CVD (PECVD) method using plasma, a thermal CVD (TCVD) method using heat, a photo CVD method using light, and the like. Moreover, the CVD method can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving electric charge from plasma. In that case, accumulated electric charge may break the wiring, the electrode, the element, or the like included in the semiconductor device. By contrast, a thermal CVD method, which does not use plasma, does not cause such plasma damage, and thus can increase the yield of the semiconductor device. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, and the like can be used.

A CVD method and an ALD method are different from a sputtering method in which particles ejected from a target or the like are deposited. Thus, an ALD method is a film formation method that enables good step coverage almost regardless of the shape of an object. In particular, an ALD method enables excellent step coverage and excellent thickness uniformity and thus is suitable for covering a surface of an opening with a high aspect ratio, for example. On the other hand, the ALD method has a relatively low film formation rate, and thus is preferably used in combination with another film formation method with a high film formation rate, such as the CVD method, in some cases.

By a CVD method, a film with a certain composition can be formed depending on the flow rate ratio of the source gases. For example, by the CVD method, a film whose composition is continuously changed can be formed by changing the flow rate ratio of the source gases during formation. In the case where a film is formed while the flow rate ratio of the source gas is changed, the time taken for transfer or pressure adjustment is saved, and thus, the time taken for the film formation can be shortened as compared to the case where a film is formed using a plurality of film formation chambers. Thus, the productivity of the semiconductor device can be increased in some cases.

An ALD method, with which different kinds of precursors are introduced at a time, enables formation of a film with a certain composition. In the case where different kinds of precursors are introduced, a film with a certain composition can be formed by controlling the number of cycles for each of the precursors.

Alternatively, thin films included in the semiconductor device (e.g., insulating films, semiconductor films, and conductive films) can be formed by a wet film formation method such as a spin coating method, a dip coating method, a spray coating method, an ink-jet method, dispensing, screen printing, offset printing, a doctor knife method, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Island-shaped thin films may be directly formed by a film formation method using a blocking mask such as a metal mask.

There are the following two typical examples of a photolithography method. In one of the methods, a resist mask is formed over a thin film that is to be processed, the thin film is processed by etching or the like, and the resist mask is removed. The other method is that a photosensitive thin film is formed and then light exposure and development are performed, so that the thin film is processed into a desired shape.

As light for light exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed, for example. Alternatively, ultraviolet light, KrF laser light, ArF laser light, or the like can be used. In addition, light exposure may be performed by liquid immersion exposure technique. As the light for light exposure, extreme ultraviolet (EUV) light or X-rays may also be used. Instead of the light used for light exposure, an electron beam can be used. It is preferable to use extreme ultraviolet light, X-rays, or an electron beam because extremely minute processing can be performed. Note that in the case of performing light exposure by scanning of a beam such as an electron beam, a photomask is not needed.

For etching of the thin films, a dry etching method, a wet etching method, a sandblast method, or the like can be used.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which high-frequency voltages with the same frequency are applied to the parallel plate electrodes. Alternatively, a structure may be employed in which different high-frequency voltages are applied to the parallel plate electrodes. Such a CCP etching apparatus is referred to as a dual frequency capacitively coupled plasma (DF-CCP) etching apparatus. In the DF-CCP etching apparatus, a structure may be employed in which high-frequency voltages with different frequencies are applied to the parallel plate electrodes. Alternatively, a structure may be employed in which different high-frequency voltages are applied to one of the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched. Note that in the above dry etching apparatus, high-frequency voltage is applied to the electrode on the substrate side to generate a self-bias potential, whereby reactive ion etching can be performed. In reactive ion etching, ion species in plasma are accelerated to collide with an object to be processed, whereby highly anisotropic etching can be performed.

First, a method for fabricating the semiconductor device illustrated in FIG. 1A to FIG. 1C is described.

First, a substrate (not illustrated) is prepared, and the insulating layer 140 is formed over the substrate (see FIG. 6A and FIG. 6B). The insulating layer 140 may be formed by a sputtering method, a CVD method, an MBE method, a PLD method, an ALD method, or the like as appropriate.

Next, the conductive layer 110 is formed over the insulating layer 140 (see FIG. 6A and FIG. 6B). The conductive layer 110 can be formed in the following manner: a conductive film is formed over the insulating layer 140 and the conductive film is patterned by a lithography method. The conductive film may be formed by a sputtering method, a CVD method, an MBE method, a PLD method, an ALD method, or the like as appropriate.

Then, the insulating layer 180 is formed over the insulating layer 140 and the conductive layer 110. The insulating layer 180 may be formed by a sputtering method, a CVD method, an MBE method, a PLD method, an ALD method, or the like as appropriate. The top surface of the formed insulating layer 180 is preferably planarized by CMP treatment. The planarization treatment on the insulating layer 180 makes it possible to favorably form the conductive layer 115.

Note that the CMP treatment may be skipped in some cases. In that case, the top surface of the insulating layer 180 has an upward-convex curved top surface shape. When planarization treatment is not performed, the manufacturing cost can be reduced and the production yield can be increased.

Then, part of the insulating layer 180 is processed to form the opening portion 190 reaching the conductive layer 110 (see FIG. 6A and FIG. 6B). The opening portion 190 may be formed by a lithography method. A dry etching method or a wet etching method can be used for forming the opening portion 190. A dry etching method enables anisotropic etching and thus is suitable for forming the opening portion 190 with a high aspect ratio. Note that the opening portion 190 can also be formed by a dry etching method and a wet etching method as appropriate.

Next, a conductive film 115F is formed in contact with parts of the top surface of the conductive layer 110, the side surface of the insulating layer 180, and the top surface of the insulating layer 180 (see FIG. 6C and FIG. 6D). The conductive film 115F is a film to be the conductive layer 115 in a later step. The conductive film 115F may be formed by a sputtering method, a CVD method, an MBE method, a PLD method, an ALD method, or the like as appropriate.

At least part of the conductive film 115F is formed in the opening portion 190 having a high aspect ratio. Thus, the conductive film 115F is preferably formed by a film formation method providing good coverage. For example, the conductive film 115F is preferably formed by an ALD method, a CVD method, or the like, and further preferably formed by a metal CVD method.

Next, the conductive film 115F is processed by a lithography method to form the conductive layer 115 (see FIG. 6E and FIG. 6F). For the processing of the conductive film 115F, a dry etching method or a wet etching method can be employed. Processing by a dry etching method is suitable for microfabrication. By the processing, the conductive layer 115 is formed to be in contact with the sidewall and the bottom surface of the opening portion 190 and to have a depressed portion in a region overlapping with the opening portion 190. Note that part of the insulating layer 180 may be processed in processing the conductive film 115F, and the thickness of the insulating layer 180 in a region not overlapping with the conductive layer 115 may be reduced.

Next, an insulating film 130F is formed over the insulating layer 180 and the conductive layer 115 (see FIG. 6G and FIG. 6G). The insulating film 130F is a film to be the insulating layer 130 in a later step. The insulating film 130F may be formed by a sputtering method, a CVD method, an MBE method, a PLD method, an ALD method, or the like as appropriate.

The insulating film 130F is preferably formed by an ALD method. It is preferable to form the insulating film 130F to have a small thickness, and a variation in the thickness needs to be reduced. By contrast, since an ALD method is a film formation method in which a precursor and a reactant (e.g., an oxidizer) are alternately introduced and the thickness can be adjusted with the number of repetition times of the cycle, accurate control of the thickness is possible. In an ALD method, an atomic layer can be deposited one by one on the opening portion or the bottom portion and the side surface of the depressed portion, whereby the insulating film 130F can be deposited on the depressed portion of the conductive layer 115 with good coverage. By an ALD method, a film with a certain composition can be formed by concurrently introducing different kinds of precursors. In the case where different kinds of precursors are introduced, a film with a certain composition can be formed by controlling the number of cycles for each of the precursors. Thus, an oxide whose content percentage of at least one of the Group 3 elements falls within the above range can be formed.

In the case where a film of hafnium zirconium oxide is formed as the insulating film 130F by an ALD method, a precursor containing hafnium, a precursor containing zirconium, and an oxidizer can be used. As the precursor containing hafnium, tetrakis(ethylmethylamide)hafnium (TEMAHf), HfCl₄, or the like can be used. As the precursor containing zirconium, tetrakis(ethylmethylamide)zirconium (TEMAZr), ZrCl₄, or the like can be used. As the oxidizer, any one or more selected from O₂, O₃, N₂O, NO₂, H₂O, and H₂O₂ can be used.

Note that a precursor used in an ALD method sometimes contains impurities such as carbon. For that reason, a film provided by an ALD method may contain an impurity such as carbon in a larger quantity than a film provided by another film formation method. Note that impurities can be quantified by X-ray photoelectron spectroscopy (XPS). Accordingly, the insulating film 130F does not have crystallinity immediately after the formation of the insulating film 130F in some cases.

Note that in the case where the insulating film 130F is formed by an ALD method using an oxidizer, the surface of the conductive layer 115 is oxidized by the oxidizer, so that the layer 118 illustrated in FIG. 2A and the like is formed in some cases.

The insulating film 130F is formed along the depressed portion of the conductive layer 115. The insulating film 130F has a depressed portion in a region overlapping with the depressed portion of the conductive layer 115.

Heat treatment is preferably performed after the formation of the insulating film 130F. For the heat treatment, an RTA (Rapid Thermal Anneal) apparatus, a resistance heating furnace, or a microwave heating apparatus can be used, for example. It is particularly preferable to use the RTA apparatus, in which case the ferroelectricity of the insulating film 130F to be the insulating layer 130 can sometimes be improved. As the RTA apparatus, an LRTA (Lamp Rapid Thermal Anneal) apparatus, a GRTA (Gas Rapid Thermal Anneal) apparatus, or the like can be used. An LRTA apparatus is an apparatus for heating an object by radiation of light (an electromagnetic wave) emitted from a lamp such as a halogen lamp, a metal halide lamp, a xenon arc lamp, a carbon arc lamp, a high-pressure sodium lamp, or a high-pressure mercury lamp. A GRTA apparatus is an apparatus for performing heat treatment using a high-temperature gas. As the gas, an inert gas that does not react with an object by heat treatment, for example, nitrogen or a noble gas such as argon is used. Note that a method for performing heat treatment with the LRTA apparatus is referred to as an RTA method using a lamp or an LRTA method in some cases.

In the case where an RTA method is used for the heat treatment, the treatment temperature is preferably higher than or equal to 300° C. and lower than or equal to 700° C., further preferably higher than or equal to 400° C. and lower than or equal to 600° C., still further preferably higher than or equal to 400° C. and lower than or equal to 500° C. Furthermore, the treatment time is preferably longer than or equal to 5 seconds and shorter than or equal to 1 hour, further preferably longer than or equal to 5 seconds and shorter than or equal to 5 minutes, still further preferably longer than or equal to 1 minute and shorter than or equal to 5 minutes.

In this embodiment, as the heat treatment, treatment is performed at 450° C. in a nitrogen atmosphere for 1 minute with the LRTA apparatus.

Note that the heat treatment is performed after the formation of the insulating film 130F and is not necessarily performed immediately after the formation of the insulating film 130F. For example, the heat treatment can also be performed at timings such as after the formation of a conductive film 120F, after the formation of the conductive layer 120, and after the formation of the insulating layer 130, which are described later. In addition, the heat treatment may be performed one or more times. The atmosphere in the LRTA, other than a nitrogen atmosphere, may be an atmosphere of an inert gas such as Ar or He. For the heat treatment, instead of the LRTA, an annealing furnace may be used.

Note that the surface of the conductive layer 115 is oxidized by the heat treatment to form the layer 118 illustrated in FIG. 2A and the like in some cases. In the case where the heat treatment is performed after the formation of the conductive film 120F, the bottom surface of the conductive film 120F is oxidized to form a film to be the layer 128 illustrated in FIG. 2C and the like in some cases.

Next, the conductive film 120F is formed over the insulating film 130F (see FIG. 6G and FIG. 6H). The conductive film 120F is formed to fill the depressed portion of the insulating film 130F. The conductive film 120F is a film to be the conductive layer 120 in a later step. The conductive film 120F may be formed by a sputtering method, a CVD method, an MBE method, a PLD method, an ALD method, or the like as appropriate.

At least part of the conductive film 120F is formed in the depressed portion of the insulating layer 130. Since the depressed portion has a high aspect ratio, the conductive film 120F is preferably formed by a film formation method providing good coverage. For example, the conductive film 120F is preferably formed by an ALD method, a CVD method, or the like, and further preferably formed by a metal CVD method.

Note that in the case where the substrate temperature at the time of forming the conductive film 120F is high, a stable phase might be formed in the insulating film 130F due to heat, which might lead to the insulating layer 130 to be formed later not exhibiting ferroelectricity. Thus, the substrate temperature at the time of forming the conductive film 120F is preferably low. Meanwhile, when the substrate temperature is too low, an adsorption reaction of a source gas does not occur, and thus the film is not formed. In view of this, the temperature at the time of forming the conductive film 120F is preferably higher than or equal to room temperature and lower than or equal to 325° C., further preferably higher than or equal to 250° C. and lower than or equal to 325° C., for example. When the conductive film 120F is formed at a low substrate temperature in this manner, formation of a stable phase in the insulating film 130F can be inhibited.

Since the conductive film 115F is formed before the formation of the insulating film 130F, the insulating film 130F is not affected by heat at the time of forming the conductive film 115F. Thus, the substrate temperature at the time of forming the conductive film 115F can be high. For example, the substrate temperature at the time of forming the conductive film 115F can be higher than the substrate temperature at the time of forming the conductive film 120F. Increasing the substrate temperature at the time of forming the conductive film 115F can reduce the resistivity of the conductive film 115F. This can also reduce the hydrogen concentration in the conductive film 115F. For example, the temperature at the time of forming the conductive film 115F is preferably higher than 325° C. and lower than or equal to 700° C., further preferably higher than or equal to 350° C. and lower than or equal to 500° C., still further preferably higher than or equal to 400° C. and lower than or equal to 450° C.

Then, the conductive film 120F and the insulating film 130F are processed by a lithography method to form the conductive layer 120 and the insulating layer 130 (see FIG. 1B and FIG. 1C). For the processing of the conductive film 120F and the insulating film 130F, a dry etching method or a wet etching method can be employed. Processing by a dry etching method is suitable for microfabrication. The conductive film 120F and the insulating film 130F may be processed under different conditions. Note that part of the insulating layer 180 may be processed in processing the conductive film 120F and the insulating film 130F, and the thickness of the insulating layer 180 in a region overlapping with neither the conductive layer 120 nor the insulating layer 130 may be reduced.

Through the above steps, the semiconductor device illustrated in FIG. 1A to FIG. 1C can be fabricated.

Next, a method for fabricating the semiconductor device illustrated in FIG. 4A to FIG. 4C is described.

The description with reference to FIG. 6A to FIG. 6D can be referred to for the fabrication method preceding and including the formation of the conductive film 115F; thus, the detailed description thereof is omitted.

Next, a sacrificial layer is formed to fill the opening portion 190. A material to be removed in a later step can be used for the sacrificial layer. Note that a conductive material, a semiconductor material, or an insulating material may be used for the sacrificial layer.

Next, planarization treatment is performed to expose the top surface of the insulating layer 180, so that the top surfaces of the sacrificial layer, the conductive layer 115, and the insulating layer 180 are planarized. Thus, the top surface of the conductive layer 115 is level with the top surface of the insulating layer 180. As the planarization treatment, CMP treatment is suitable. At least parts of the sacrificial layer and the conductive layer 115 are removed by the planarization treatment. Note that part of the insulating layer 180 may be removed by the planarization treatment.

Next, the sacrificial layer is removed, so that the depressed portion of the conductive layer 115 is exposed (see FIG. 7A and FIG. 7B). A dry etching method or a wet etching method can be employed for the removal of the sacrificial layer. In removing the sacrificial layer, an etching condition with high selectivity between the sacrificial layer and the conductive layer 115 is preferably employed so that the conductive layer 115 is not removed.

Next, the insulating film 130F is formed over the insulating layer 180 and the conductive layer 115, and the conductive film 120F is formed over the insulating film 130F (see FIG. 7C and FIG. 7D). Note that the description with reference to FIG. 6G to FIG. 6H can be referred to for the film formation method of the insulating film 130F and the conductive film 120F.

Then, the conductive film 120F and the insulating film 130F are processed by a lithography method to form the conductive layer 120 and the insulating layer 130 (see FIG. 4B and FIG. 4C). The above description can be referred to for the method for processing the conductive film 120F and the insulating film 130F.

Through the above steps, the semiconductor device illustrated in FIG. 4A to FIG. 4C can be fabricated.

This embodiment can be combined with any of the other embodiments as appropriate. In this specification, in the case where a plurality of structure examples are described in one embodiment, the structure examples can be combined as appropriate.

### Embodiment 2

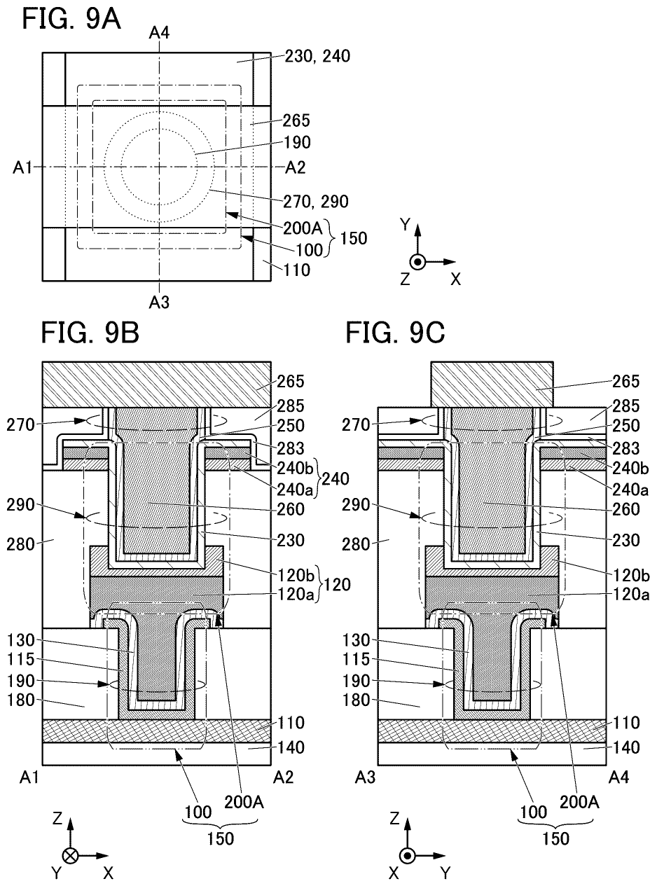

In this embodiment, the semiconductor device of one embodiment of the present invention will be described with reference to FIG. 9A to FIG. 12. The semiconductor device of one embodiment of the present invention includes a memory cell. The memory cell includes a transistor and a capacitor.

### <Structure Example of Memory Cell>

A structure of the semiconductor device including a transistor and a capacitor is described with reference to FIG. 9A to FIG. 9C. FIG. 9A is a plan view of the semiconductor device including a transistor 200A and the capacitor 100. FIG. 9B is a cross-sectional view along the dashed-dotted line A1-A2 in FIG. 9A. FIG. 9C is a cross-sectional view along the dashed-dotted line A3-A4 in FIG. 9A.

The semiconductor device illustrated in FIG. 9A to FIG. 9C includes the insulating layer 140 over a substrate (not illustrated), the conductive layer 110 over the insulating layer 140, a memory cell 150 over the conductive layer 110, the insulating layer 180 over the conductive layer 110, an insulating layer 280, an insulating layer 283, an insulating layer 285, and a conductive layer 265 over the insulating layer 285. The insulating layer 140, the insulating layer 180, the insulating layer 280, the insulating layer 283, and the insulating layer 285 each function as an interlayer film. The conductive layer 110 and the conductive layer 265 function as wirings.

The memory cell 150 includes the capacitor 100 over the conductive layer 110 and the transistor 200A over the capacitor 100.

The description in Embodiment 1 can be referred to for the capacitor 100; thus, the detailed description thereof is omitted.

The insulating layer 280 is provided over the capacitor 100, and the transistor 200A is provided over the insulating layer 280. The insulating layer 280 includes a portion positioned over the insulating layer 180 and a portion positioned over the conductive layer 120b.

The transistor 200A includes the conductive layer 120, a conductive layer 240 over the insulating layer 280, an oxide semiconductor layer 230, an insulating layer 250 over the oxide semiconductor layer 230, and a conductive layer 260 over the insulating layer 250. The conductive layer 120 includes the conductive layer 120a and the conductive layer 120b over the conductive layer 120a. The conductive layer 240 includes a conductive layer 240a and a conductive layer 240b over the conductive layer 240a.

In the transistor 200A, the oxide semiconductor layer 230 functions as a semiconductor layer, the conductive layer 260 functions as a gate electrode, the insulating layer 250 functions as a gate insulating layer, the conductive layer 120 functions as one of a source electrode and a drain electrode, and the conductive layer 240 functions as the other of the source electrode and the drain electrode. The conductive layer 265 functions as a gate wiring.

At least part of a region of the oxide semiconductor layer 230 that is in contact with the insulating layer 280 functions as a channel formation region of the transistor 200A. One of a region of the oxide semiconductor layer 230 that is in contact with the conductive layer 120 and a region of the oxide semiconductor layer 230 that is in contact with the conductive layer 240 functions as a source region, and the other thereof functions as a drain region. That is, the channel formation region is interposed between the source region and the drain region.

In the transistor 200A, the source electrode and the drain electrode are positioned at different levels, and current flowing in the semiconductor layer flows in the height direction. In other words, the channel length direction includes a component of the height direction (vertical direction); accordingly, the transistor 200A can also be referred to as a VFET (Vertical Field Effect Transistor), a vertical transistor, a vertical-channel transistor, a vertical-channel-type transistor, or the like.

A vertical transistor is suitable for the memory cell 150. In the vertical transistor, the source electrode, the semiconductor layer, and the drain electrode can be provided to overlap with each other; thus, the area occupied by the transistor can be significantly smaller than the area occupied by what is called a planar transistor in which a semiconductor layer is provided in a planar shape.

As illustrated in FIG. 9A to FIG. 9C, the transistor 200A is provided to overlap with the capacitor 100. An opening portion 290 and an opening portion 270 where part of the structure of the transistor 200A is provided include a region overlapping with the opening portion 190 where part of the structure of the capacitor 100 is provided. In particular, since the conductive layer 120 has a function of one of the source electrode and the drain electrode of the transistor 200A and a function of the upper electrode of the capacitor 100, the transistor 200A and the capacitor 100 partly share the structure. With such a structure, the transistor 200A and the capacitor 100 can be provided without a great increase in the area occupied thereby in the plan view. Thus, the occupation area of the memory cell 150 can be reduced, so that the memory cells 150 can be arranged densely and the storage capacity of the storage device can be increased. In other words, the storage device can be highly integrated. FIG. 9B and FIG. 9C illustrate an example where the width of the opening portion 190 is smaller than the width of the opening portion 290 and the width of the opening portion 270. There is no particular limitation on the magnitude relation between the width of the opening portion 190 and the width of the opening portion 290 or the width of the opening portion 270. In view of miniaturization, the width of the opening portion 190 is preferably smaller than or equal to the width of the opening portion 290. Similarly, the width of the opening portion 190 is preferably smaller than or equal to the width of the opening portion 270.

When the transistor 200A is provided above the capacitor 100, the transistor 200A is not affected by heat treatment in fabricating the capacitor 100. Thus, in the transistor 200A, degradation of the electrical characteristics such as variation in threshold voltage or an increase in parasitic resistance, and an increase in variation in electrical characteristics due to the degradation of the electrical characteristics can be inhibited.

As described in Embodiment 1, the deeper the opening portion 190 is, the higher the electrostatic capacitance of the capacitor 100 can be. Increasing the electrostatic capacitance per unit area of the capacitor 100 in this manner enables a stable reading operation of the storage device. This also allows further miniaturization or high integration of the storage device.

Next, details of the transistor 200A will be described.

As illustrated in FIG. 9B and FIG. 9C, the opening portion 290 reaching the conductive layer 120b is provided in the insulating layer 280 and the conductive layer 240. The opening portion 290 includes an opening portion included in the insulating layer 280 and an opening portion included in the conductive layer 240. In other words, the opening portion included in the insulating layer 280 in a region overlapping with the conductive layer 120b is part of the opening portion 290, and the opening portion included in the conductive layer 240 in a region overlapping with the conductive layer 120b is another part of the opening portion 290. The sidewall of the opening portion 290 includes the side surface of the insulating layer 280 and the side surface of the conductive layer 240. The shape and the size of the opening portion 290 in the plan view may differ from layer to layer. When the opening portion 290 has a circular top-view shape, the opening portions of the layers may be, but not necessarily, concentrically arranged.

The conductive layer 120b is provided with a depressed portion. The opening portion 290 included in the conductive layer 240 and the insulating layer 280 overlaps with the depressed portion of the conductive layer 120b. Here, the opening portion 290 can be regarded as an opening portion reaching the bottom surface of the depressed portion of the conductive layer 120b.

At least parts of the components of the transistor 200A are placed in the opening portion 290. Specifically, at least part of each of the oxide semiconductor layer 230, the insulating layer 250, and the conductive layer 260 is positioned in the opening portion 290. The oxide semiconductor layer 230 is in contact with the top surface and the side surface of the conductive layer 120b (also referred to as the bottom surface and the side surface of the depressed portion) through the opening portion 290, and is in contact with the side surface of the insulating layer 280, the side surface of the conductive layer 240a, and the top surface and the side surface of the conductive layer 240b in the opening portion 290. In other words, the top surface of the conductive layer 120b includes a region in contact with at least part of the bottom surface of the oxide semiconductor layer 230. The insulating layer 250 is positioned inward from the oxide semiconductor layer 230 in the opening portion 290, and the conductive layer 260 is positioned inward from the insulating layer 250 in the opening portion 290.

Portions of the oxide semiconductor layer 230 and the insulating layer 250 that are placed in the opening portion 290 reflect the shape of the opening portion 290. Specifically, the oxide semiconductor layer 230 is provided to cover the bottom portion and the sidewall of the opening portion 290, and the insulating layer 250 is provided to cover the oxide semiconductor layer 230. Then, the conductive layer 260 is provided to fill at least part of a depressed portion that is defined by the insulating layer 250 and reflects the shape of the opening portion 290.

When the conductive layer 120b includes the depressed portion in a position overlapping with the opening portion 290, unlike in the case where the depressed portion is not provided, the levels of the bottom surfaces of the insulating layer 250 and the conductive layer 260 in the opening portion 290 can be lower than the level of the top surface of the conductive layer 120b which is in contact with the insulating layer 280, with the top surface of the insulating layer 140 used as a reference. The levels of the surfaces can be determined using the formation surface of the memory cell or the transistor as a reference. Here, the top surface of the insulating layer 140 is used as the reference. A surface used as the reference is not particularly limited, and the top surface of the substrate where the transistor or the semiconductor device is provided may be used as the reference, for example.

Accordingly, the contact area between the side surface of the conductive layer 120b and the oxide semiconductor layer 230 can be increased, so that the contact resistance between the conductive layer 120b and the oxide semiconductor layer 230 can be reduced. This can inhibit a decrease in on-state current of the transistor 200A due to the contact resistance between the conductive layer 120b and the oxide semiconductor layer 230.

In addition, a gate electric field is easily applied to the channel formation region of the oxide semiconductor layer 230, so that the electrical characteristics of the transistor 200A can be improved. Furthermore, a gate electric field is easily applied to a region of the oxide semiconductor layer 230 which is in contact with the conductive layer 120b, so that the on-state current of the transistor 200A can be increased. The electrical characteristics of the transistor 200A can be improved when either the conductive layer 120 or the conductive layer 240 is used as the drain electrode.

A conductive material containing oxygen is preferably used for the conductive layer 120b. Accordingly, the contact resistance between the oxide semiconductor layer 230 and the conductive layer 120b can be reduced. Similarly, a conductive material containing oxygen is preferably used for the conductive layer 240a. Accordingly, the contact resistance between the oxide semiconductor layer 230 and the conductive layer 240a can be reduced. In the case where the conductive layer 120 and the conductive layer 240 each have a stacked-layer structure, the use of a conductive material containing oxygen for the layer closest to the channel formation region in the stacked-layer structure can reduce the contact resistance with the oxide semiconductor layer 230, which allows a short current path between the source and the drain and thus can increase the on-state current of the transistor. As a conductive material containing oxygen, a metal oxide having conductivity (also referred to as an oxide conductor) is preferably used.

As illustrated in FIG. 9B and FIG. 9C, the insulating layer 283 is provided to cover the side surface of the conductive layer 240 and the top surface and the side surface of the oxide semiconductor layer 230. The opening portion 270 reaching the oxide semiconductor layer 230 is provided in the insulating layer 283 in a position overlapping with the opening portion 290. At least parts of the components of the transistor 200A are placed in the opening portion 270. Specifically, the insulating layer 250 and the conductive layer 260 are placed in the opening portion 270 at least partly. The insulating layer 250 is in contact with the oxide semiconductor layer 230 and the insulating layer 283 in the opening portion 270.

A portion of the insulating layer 250 that is placed in the opening portion 270 reflects the shape of the opening portion 270. Specifically, the insulating layer 250 is provided to cover the sidewall of the opening portion 270 (the side surface of the insulating layer 283). Then, the conductive layer 260 is provided to fill at least part of a depressed portion that is defined by the insulating layer 250 and reflects the shape of the opening portion 270.

Since the conductive layer 260 does not overlap with the top surface of the conductive layer 240 in the transistor 200A, parasitic capacitance generated between the conductive layer 240 and the conductive layer 260 can be reduced. As illustrated in FIG. 9B and FIG. 9C, the maximum width of the conductive layer 260 is smaller than the width of the opening portion 290 in the cross-sectional view. As described above, the maximum width of the conductive layer 260 is preferably smaller than the width of the opening portion 290, in which case the parasitic capacitance generated between the conductive layer 260 and the conductive layer 240 can be reduced. Note that for example, as illustrated in FIG. 9B or FIG. 9C, the relation between the two widths in the semiconductor device of one embodiment of the present invention can be found in one cross section parallel to the Z direction.

The width of the opening portion 290 sometimes varies in the depth direction. Here, the shortest distance between two side surfaces of the conductive layer 240 on the opening portion 290 side in a cross-sectional view is particularly used as the width of the opening portion 290. In other words, the minimum width of the opening portion 290 in the conductive layer 240 is used as the width of the opening portion 290.

FIG. 9B and FIG. 9C illustrate an example where the width of the opening portion 270 corresponds to that of the opening portion 290. It is preferable that the width of the opening portion 270 do not exceed the sum of the width of the opening portion 290 and twice the thickness of the oxide semiconductor layer 230. In this case, the insulating layer 283 and the insulating layer 285 can be prevented from being positioned inside the opening portion 290. In the case where the insulating layer 250 is provided inside the opening portion 270, it is preferable that the width of the opening portion 270 do not exceed the sum of the width of the opening portion 290 and twice the thickness of the insulating layer 250. The width of the opening portion 270 is further preferably smaller than or equal to that of the opening portion 290. This is preferable because the conductive layer 260 does not overlap with the top surface of the conductive layer 240 and accordingly the parasitic capacitance generated between the conductive layer 260 and the conductive layer 240 can be reduced. Although this embodiment mainly describes the example where the conductive layer 260 does not overlap with the top surface of the conductive layer 240, the conductive layer 260 may include a portion overlapping with the top surface of the conductive layer 240. The overlapping portion is preferably as small as possible because parasitic capacitance generated between the conductive layer 260 and the conductive layer 240 can be reduced.

Note that the width of the opening portion 270 changes in the depth direction in some cases. Here, the maximum width of the opening portion 270 provided in the insulating layer 283 in a cross-sectional view is particularly used as the width of the opening portion 270.

The top surface of the conductive layer 260 is preferably level with or substantially level with the top surface of the insulating layer 285. The conductive layer 265 is provided over the insulating layer 285, the insulating layer 283, and the conductive layer 260, and is in contact with the top surface of the conductive layer 260. It can be said that the conductive layer 260 and the conductive layer 265 are electrically connected to each other. The insulating layer 283 and the insulating layer 285 are positioned between the conductive layer 265 and the conductive layer 240. This can increase the physical distance between the conductive layer 265 and the conductive layer 240, and thus can reduce the parasitic capacitance generated between the conductive layer 265 and the conductive layer 240.

That is, the transistor 200A has a structure where the parasitic capacitance generated between the other of the source electrode and the drain electrode and the gate electrode and the parasitic capacitance generated between the other of the source electrode and the drain electrode and the gate wiring are reduced. Thus, the frequency characteristics of the circuit can be improved.

FIG. 9B illustrates a structure where the end portion of the conductive layer 240a, the end portion of the conductive layer 240b, and the end portion of the oxide semiconductor layer 230 are aligned with each other outside the opening portion 290. The conductive layer 240a, the conductive layer 240b, and the oxide semiconductor layer 230 can be formed by processing with the use of the same mask. This is preferable because the number of masks required for fabricating the semiconductor device can be reduced. Note that the present invention is not limited thereto. For example, in the X direction or the Y direction, any one of the end portion of the oxide semiconductor layer 230, the end portion of the conductive layer 240a, and the end portion of the conductive layer 240b may be positioned inward or outward from the others.

The conductive layer 240 includes the opening portion 290 in a region overlapping with the conductive layer 120. The conductive layer 240 is preferably not provided inside the opening portion 290 included in the insulating layer 280. That is, the conductive layer 240 preferably does not include a region in contact with the side surface of the insulating layer 280 in the opening portion 290. With such a structure, the opening portion 290 can be formed in the conductive layer 240 and the insulating layer 280 at a time. When the side surface of the conductive layer 240 in the opening portion 290 and the side surface of the insulating layer 280 in the opening portion 290 are aligned with each other, the thickness distribution of the oxide semiconductor layer 230 provided inside the opening portion 290 can be uniform. In addition, the oxide semiconductor layer 230 can be inhibited from being divided by a step difference between the conductive layer 240 and the insulating layer 280.

Although FIG. 9B and FIG. 9C illustrate the structure where the side surface of the conductive layer 240 in the opening portion 290 and the side surface of the insulating layer 280 in the opening portion 290 are aligned or substantially aligned with each other, the present invention is not limited thereto. For example, the side surface of the conductive layer 240 in the opening portion 290 and the side surface of the insulating layer 280 in the opening portion 290 may be discontinuous. The inclination of the side surface of the conductive layer 240 in the opening portion 290 and the inclination of the side surface of the insulating layer 280 in the opening portion 290 may be different from each other. At this time, for example, the taper angle of the side surface of the conductive layer 240 in the opening portion 290 is preferably smaller than that of the side surface of the insulating layer 280 in the opening portion 290. With such a structure, the coverage of the side surface of the conductive layer 240 with the oxide semiconductor layer 230 in the opening portion 290 is improved, so that defects such as voids can be reduced. In the case where the insulating layer 280 has a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

In the transistor 200A, the oxide semiconductor layer 230 including a channel formation region contains a metal oxide (also referred to as an oxide semiconductor) functioning as a semiconductor. In this case, the transistor 200A can be regarded as an OS transistor.

An OS transistor is likely to have its electrical characteristics changed by oxygen vacancies (Vo) and impurities in a channel formation region in an oxide semiconductor, which might degrade the reliability. In some cases, a defect that is an oxygen vacancy into which hydrogen enters (hereinafter sometimes referred to as VoH) generates an electron serving as a carrier. Therefore, when the channel formation region in the oxide semiconductor includes oxygen vacancies, the OS transistor is likely to have normally-on characteristics. Therefore, oxygen vacancies and impurities are preferably reduced as much as possible in the channel formation region in the oxide semiconductor. In other words, the oxide semiconductor preferably includes an i-type (intrinsic) or substantially i-type channel formation region with a low carrier concentration.

Meanwhile, it is preferable that the source region and the drain region of the OS transistor include more oxygen vacancies, include more VoH, or have a higher concentration of an impurity such as hydrogen, nitrogen, or a metal element than the channel formation region, and thus be low-resistance regions with high carrier concentrations. In other words, the source region and the drain region of the OS transistor are preferably n-type regions with higher carrier concentrations and lower resistance than the channel formation region.

As described above, the oxide semiconductor layer 230 is provided inside the opening portion 290 included in the insulating layer 280. The transistor 200A has a structure in which a current flows in the vertical direction since one of the source electrode and the drain electrode (here, the conductive layer 120) is positioned on the lower side and the other of the source electrode and the drain electrode (here, the conductive layer 240) is positioned on the upper side. That is, a channel is formed along the side surface of the opening portion 290 included in the insulating layer 280.

The insulating layer 280 is in contact with the entire outer circumference of the oxide semiconductor layer 230. Thus, the channel formation region of the transistor 200A can be formed in the entire outer circumference of the oxide semiconductor layer 230 (the entire region in contact with the insulating layer 280) in the opening portion 290.

The channel length of the transistor 200A is a distance between the source region and the drain region. That is, it can be said that the channel length of the transistor 200A is determined by the thickness of the insulating layer 280 over the conductive layer 120. It can also be said that the channel length corresponds to the length of the side surface of the insulating layer 280 on the opening portion 290 side.

The channel length of a planar transistor is limited by the light exposure limit of photolithography, and further miniaturization is difficult. By contrast, in one embodiment of the present invention, the channel length can be determined by the thickness of the insulating layer 280. Thus, the transistor 200A can have an extremely small channel length below the light exposure limit of photolithography (e.g., smaller than or equal to 60 nm, smaller than or equal to 50 nm, smaller than or equal to 40 nm, smaller than or equal to 30 nm, smaller than or equal to 20 nm, or smaller than or equal to 10 nm, and larger than or equal to 0.1 nm, larger than or equal to 1 nm, or larger than or equal to 5 nm). Accordingly, the transistor 200A can have higher on-state current and improved frequency characteristics.

In addition, as described above, the channel formation region, the source region, and the drain region can be formed in the opening portion 290. Thus, the occupation area of the transistor 200A can be reduced as compared with a planar transistor in which a channel formation region, a source region, and a drain region are provided separately on the XY plane. Thus, high integration of the semiconductor device can be achieved. In the case where the semiconductor device of one embodiment of the present invention is used for a storage device, the storage capacity per unit area can be increased.

The oxide semiconductor layer 230, the insulating layer 250, and the conductive layer 260 are provided concentrically. Thus, the side surface of the conductive layer 260 provided at the center faces the side surface of the oxide semiconductor layer 230 with the insulating layer 250 therebetween. That is, in a plan view, the entire circumference of the oxide semiconductor layer 230 serves as the channel formation region. In that case, for example, the channel width of the transistor 200A is determined by the length of the outer circumference of the oxide semiconductor layer 230. In other words, the channel width of the transistor 200A is determined by the width of the opening portion 290 (the diameter in the case where the opening portion 290 has a circular shape in the plan view). By increasing the width of the opening portion 290, the channel width per unit area can be increased and the on-state current can be increased.

In the case where the opening portion 290 is formed by a photolithography method, the width of the opening portion 290 is determined by the light exposure limit of photolithography. In addition, the width of the opening portion 290 is determined by the thicknesses of the oxide semiconductor layer 230, the insulating layer 250, and the conductive layer 260 provided in the opening portion 290. The width of the opening portion 290 is preferably, for example, larger than or equal to 5 nm, larger than or equal to 10 nm, or larger than or equal to 20 nm and smaller than or equal to 100 nm, smaller than or equal to 60 nm, smaller than or equal to 50 nm, smaller than or equal to 40 nm, or smaller than or equal to 30 nm. In the case where the opening portion 290 is circular in a plan view, a width D of the opening portion 290 corresponds to the diameter of the opening portion 290, and the channel width can be calculated to be “D×π”.

The channel length of the transistor 200A is preferably smaller than at least the channel width of the transistor 200A. The channel length of the transistor 200A is preferably greater than or equal to 0.1 times and less than or equal to 0.99 times, further preferably greater than or equal to 0.5 times and less than or equal to 0.8 times the channel width of the transistor 200A. This structure enables a transistor with favorable electrical characteristics and high reliability.

In the case where the opening portion 290 is formed to be circular in a plan view, the oxide semiconductor layer 230, the insulating layer 250, and the conductive layer 260 are formed concentrically. This makes the distance between the conductive layer 260 and the oxide semiconductor layer 230 substantially uniform, so that a gate electric field can be substantially uniformly applied to the oxide semiconductor layer 230.

Although this embodiment describes the example where the opening portion 290 and the opening portion 270 have a circular shape in the plan view, the present invention is not limited thereto. The opening portion 290 and the opening portion 270 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than 180°) or a convex polygonal shape (a polygonal shape all the interior angles of which are less than or equal to 180°). As illustrated in FIG. 9A and the like, the opening portion 290 and the opening portion 270 in the plan view preferably have a circular shape. When the opening portions have a circular shape, processing accuracy in forming the opening portions can be high, whereby the opening portions can be formed to have minute sizes.

### <Component Materials for Semiconductor Device>

Materials that can be used for the semiconductor device of this embodiment are described below. Note that each layer included in the semiconductor device of this embodiment may have a single-layer structure or a stacked-layer structure.

### [Oxide Semiconductor Layer 230]

As described above, the oxide semiconductor layer 230 includes a channel formation region. The channel formation region is an i-type (intrinsic) or substantially i-type region. The oxide semiconductor layer 230 further includes a source region and a drain region. The source region and the drain region are each an n-type region (low-resistance region) having a higher carrier concentration than the channel formation region.

There is no particular limitation on the crystallinity of a semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used because degradation of the transistor characteristics can be inhibited.

The metal oxide functioning as a semiconductor preferably has a band gap larger than or equal to 2.0 eV, further preferably larger than or equal to 2.5 eV. With the use of a metal oxide having a larger band gap, the off-state current of the transistor can be reduced. The off-state current of the OS transistor is low, so that power consumption of the semiconductor device can be adequately reduced. The OS transistor has excellent frequency characteristics, which enables the semiconductor device to operate at high speed.

Examples of the metal oxide that can be used for the oxide semiconductor layer 230 include indium oxide, gallium oxide, and zinc oxide. The metal oxide preferably contains at least indium (In) or zinc (Zn). The metal oxide preferably contains two or three kinds selected from indium, the element M, and zinc. The metal oxide preferably contains one or both of indium and zinc. The element M is a metal element or a metalloid element that has a high binding energy with oxygen, such as a metal element or a metalloid element whose binding energy with oxygen is higher than that of indium, for example. Specific examples of the element Minclude aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably any one or more of the above elements, further preferably one or more selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For example, the oxide semiconductor layer 230 can be formed using an indium oxide (In oxide), an IZO (registered trademark), an ITO, an indium titanium oxide (an In—Ti oxide), an indium gallium oxide (an In—Ga oxide), an indium gallium aluminum oxide (an In—Ga—Al oxide), an indium gallium tin oxide (an In—Ga—Sn oxide, also referred to as an IGTO), a gallium zinc oxide (also referred to as a Ga—Zn oxide or a GZO), an aluminum zinc oxide (also referred to as an Al—Zn oxide or an AZO), an indium aluminum zinc oxide (also referred to as an In—Al—Zn oxide or an IAZO), an indium tin zinc oxide (also referred to as an In—Sn—Zn oxide or an ITZO (registered trademark)), an indium titanium zinc oxide (an In—Ti—Zn oxide), an indium gallium zinc oxide (also referred to as an In—Ga—Zn oxide or an IGZO), an indium gallium tin zinc oxide (also referred to as an In—Ga—Sn—Zn oxide or an IGZTO), or an indium gallium aluminum zinc oxide (also referred to as an In—Ga—Al—Zn oxide, an IGAZO, an IGZAO, or an IAGZO). Alternatively, it is possible to use an ITSO, a gallium tin oxide (a Ga—Sn oxide), an aluminum tin oxide (an Al—Sn oxide), or the like.

By increasing the proportion of the number of indium atoms in the total number of atoms of all the metal elements contained in the metal oxide, the field-effect mobility of the transistor can be increased. In addition, the transistor can have high on-state current.

Note that the metal oxide may contain, instead of indium or in addition to indium, one or more kinds of metal elements with large period numbers in the periodic table. The larger the overlap between orbits of metal elements is, the more likely it is that the metal oxide will have high carrier conductivity. Thus, a transistor including a metal element with a large period number can have high field-effect mobility in some cases. Examples of the metal element with a large period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a nonmetallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of the element M atoms in the total number of atoms of all the metal elements contained in the metal oxide, the metal oxide can have a large band gap. This can inhibit formation of oxygen vacancies in the metal oxide. Accordingly, generation of carriers due to oxygen vacancies is inhibited, which makes the off-state current of the transistor low. In addition, a shift in the threshold voltage of the transistor can be inhibited. Furthermore, a change in electrical characteristics of the transistor is inhibited, and the reliability of the transistor can be increased.

Electrical characteristics and reliability of a transistor depend on the composition of the metal oxide used for the oxide semiconductor layer 230. Thus, by varying the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=5:2:5, and a composition in the neighborhood of any of these atomic ratios. Note that a composition in the neighborhood includes the range of ±30% of an intended atomic ratio. By increasing the atomic proportion of indium in the metal oxide, the on-state current, field-effect mobility, or the like of the transistor can be increased.

The proportion of the number of In atoms may be less than that of the number ofMatoms in the In-M-Zn oxide. Examples of the atomic ratio of the metal elements in such an In-M-Zn oxide include In:M:Zn=1:3:2, In:M:Zn=1:3:3, In:M:Zn=1:3:4, and a composition in the neighborhood of any of these atomic ratios. By increasing the proportion of the number of M atoms in the metal oxide, generation of oxygen vacancies can be inhibited.

In the case where a plurality of metal elements are contained as the element M, the sum of the proportions of the numbers of atoms of the metal elements can be the proportion of the number of the element M atoms.

In this specification and the like, the proportion of the number of indium atoms in the total number of atoms of all the metal elements contained is sometimes referred to as the content percentage of indium. The same applies to other metal elements.

In the case where the metal oxide is an In—Zn oxide, examples of the atomic ratio of metal elements in the In—Zn oxide include In:Zn=1:1, In:Zn=2:1, In:Zn=4:1, and a composition in the neighborhood of any of these atomic ratios. In addition, the In—Zn oxide may contain a slight amount of the element M. For example, in the case where Sn is contained as the element M, examples of the atomic ratio of metal elements in the metal oxide include In:Sn:Zn=2:0.1:1, In:Sn:Zn=4:0.1:1, and a composition in the neighborhood thereof.

For analysis of the composition of the metal oxide used for the oxide semiconductor layer 230, for example, energy dispersive X-ray spectroscopy (EDX), XPS, inductively coupled plasma-mass spectrometry (ICP-MS), or inductively coupled plasma-atomic emission spectrometry (ICP-AES) can be used. Alternatively, these methods may be combined for the analysis. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage. In some cases, the element M is difficult to quantify or the element Mis not detected.

A sputtering method or an ALD method can be suitably used for forming the metal oxide. Note that in the case where the metal oxide is formed by a sputtering method, the composition of the formed metal oxide film may be different from the composition of a target. In particular, the content percentage of zinc in the formed metal oxide film may be reduced to approximately 50% of that of the target. The metal oxide film may be formed by a CVD method, an MBE method, a PLD method, or the like.

The oxide semiconductor layer 230 may have a stacked-layer structure including two or more metal oxide layers. The two or more metal oxide layers included in the oxide semiconductor layer 230 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the oxide semiconductor layer 230 may have different compositions.

A specific example of the case where the oxide semiconductor layer 230 has a two-layer structure of a first metal oxide layer and a second metal oxide layer over the first metal oxide layer will be described below.

For example, a material having higher conductivity than a material for the second metal oxide layer can be used for the first metal oxide layer. The use of the material having high conductivity for the first metal oxide layer in contact with the source electrode and the drain electrode (the conductive layer 120 and the conductive layer 240) can reduce the contact resistance between the oxide semiconductor layer 230 and the conductive layer 120 and the contact resistance between the oxide semiconductor layer 230 and the conductive layer 240, and thus the transistor can have high on-state current.

Here, in the case where a material having high conductivity is used for the second metal oxide layer provided on the conductive layer 260 side functioning as the gate electrode, the threshold voltage of the transistor 200A is shifted and a drain current flowing when the gate voltage is 0 V (hereinafter also referred to as a cut-off current) becomes large in some cases. Specifically, the threshold voltage may be low when the transistor 200A is an n-channel transistor. Thus, a material having lower conductivity than a material for the first metal oxide layer is preferably used for the second metal oxide layer. Accordingly, the transistor 200A can have high threshold voltage in the case where the transistor 200A is an n-channel transistor, in which case the transistor 200A can have a low cut-off current. Note that characteristics with a low cut-off current are sometimes referred to as normally-off characteristics.

When the oxide semiconductor layer 230 has a stacked-layer structure and the material having higher conductivity than the material for the second metal oxide layer is used for the first metal oxide layer as described above, the transistor can have normally-off characteristics and a high on-state current. Consequently, the semiconductor device can have both low power consumption and high performance.

Furthermore, the carrier concentration of the first metal oxide layer is preferably higher than the carrier concentration of the second metal oxide layer. Increasing the carrier concentration of the first metal oxide layer results in higher conductivity thereof, which can reduce the contact resistance between the oxide semiconductor layer 230 and the conductive layer 120 and the contact resistance between the oxide semiconductor layer 230 and the conductive layer 240, and thus the transistor can have a high on-state current. Reducing the carrier concentration of the second metal oxide layer reduces the conductivity, which enables the transistor to be normally off.

Note that the structure of the oxide semiconductor layer 230 is not limited to the above structure, and a material having lower conductivity than the material for the second metal oxide layer may be used for the first metal oxide layer. In addition, the first metal oxide layer may have a lower carrier concentration than the second metal oxide layer.

The band gap of a first metal oxide used for the first metal oxide layer and the band gap of a second metal oxide used for the second metal oxide layer are preferably different from each other. For example, the difference between the band gap of the first metal oxide and the band gap of the second metal oxide is preferably larger than or equal to 0.1 eV, further preferably larger than or equal to 0.2 eV, still further preferably larger than or equal to 0.3 eV.

The band gap of the first metal oxide used for the first metal oxide layer is preferably smaller than the band gap of the second metal oxide used for the second metal oxide layer. Thus, the contact resistance between the oxide semiconductor layer 230 and the conductive layer 120 and the contact resistance between the oxide semiconductor layer 230 and the conductive layer 240 can be reduced, and thus the transistor can have a high on-state current. Also, the transistor 200A can have high threshold voltage in the case where the transistor is an n-channel transistor; accordingly, the transistor 200A can be a normally-off transistor. Furthermore, when the second metal oxide has a large band gap, carriers can be inhibited from being generated and induced in the second metal oxide layer and at the interface between the second metal oxide layer and the insulating layer 250. Thus, the transistor can have higher reliability.

For example, the content percentage of the element M in the first metal oxide is preferably lower than that of the element Min the second metal oxide. Specifically, for example, it is preferable to use a metal oxide with a composition of In:M:Zn=1:1:1 [atomic ratio] or in the neighborhood thereof for the first metal oxide layer and a metal oxide with a composition of In:M:Zn=1:3:2 [atomic ratio] or in the neighborhood thereof for the second metal oxide layer. At this time, it is particularly preferable to use one or more of gallium, aluminum, and tin as the element M.

Note that the oxide semiconductor layer 230 is not limited to having the above structure, and the band gap of the first metal oxide may be larger than that of the second metal oxide.

In addition, the content percentage of the element Min the first metal oxide is preferably lower than that of the element M in the second metal oxide. The first metal oxide may contain no or a slight amount of the element M. For example, it is preferable that the first metal oxide used for the first metal oxide layer be an In—Zn oxide, and the second metal oxide used for the second metal oxide layer be an In-M-Zn oxide. Specifically, the first metal oxide can be an In—Zn oxide, and the second metal oxide can be an In—Ga—Zn oxide.

For example, for the first metal oxide layer, it is preferable to use a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide. For the second metal oxide layer, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. Thus, the on-state current of the transistor 200A can be increased, and the transistor can have high reliability with small variations.

For example, in the case where a metal oxide is used for the conductive layer 120 or the conductive layer 240 (in the case of a stacked-layer structure, a layer closest to the channel formation region of the oxide semiconductor layer 230), an In—Zn oxide or an In—Sn—Zn oxide is preferably used for the oxide semiconductor layer 230 (or the first metal oxide layer) because the contact resistance can be reduced as compared with the case where an In—Ga—Zn oxide is used for the oxide semiconductor layer 230 (or the first metal oxide layer). Specifically, in FIG. 9B and FIG. 9C, ITO or ITSO is preferably used for the conductive layer 120b and the conductive layer 240a, an In—Zn oxide or an In—Sn—Zn oxide is preferably used for the first metal oxide layer, and an In—Ga—Zn oxide is preferably used for the second metal oxide layer.

Note that the structure of the oxide semiconductor layer 230 is not limited to the above structure, and the content percentage of the element Min the first metal oxide may be higher than that of the element Min the second metal oxide.

The oxide semiconductor layer 230 preferably includes a metal oxide layer having crystallinity. Examples of the structure of a metal oxide having crystallinity include a CAAC (c-axis aligned crystalline) structure, a polycrystalline (Poly-crystalline) structure, and a nano-crystalline (nc) structure. By using a metal oxide layer having crystallinity as the oxide semiconductor layer 230, the density of defect states in the oxide semiconductor layer 230 can be reduced, which enables the semiconductor device to have high reliability. Note that the CAAC structure is a crystal structure in which a plurality of microcrystals (typically, a plurality of IGZO microcrystals) have c-axis alignment and the plurality of microcrystals are connected in an a-b plane without alignment. When the cross section of an OS film having the CAAC structure is observed with use of a high-resolution TEM image, it can be confirmed that metal atoms are arranged in a layered manner in the crystal parts. Thus, the CAAC structure of the OS film can also be referred to as a structure including the layered crystal parts.

The polycrystalline structure includes a crystal grain boundary. When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. A CAAC structure has a fewer crystal grain boundaries in the a-b plane than the polycrystalline structure; thus, a highly reliable semiconductor device can be achieved.

The higher the crystallinity of the metal oxide layer used for the oxide semiconductor layer 230 is, the lower the density of defect states in the oxide semiconductor layer 230 can be. By contrast, the use of a metal oxide layer having low crystallinity achieves a transistor through which a large amount of current can flow.

The higher the substrate temperature (the stage temperature) in the formation of the metal oxide layer is, the higher the crystallinity of the metal oxide layer can be. The metal oxide layer with higher crystallinity can be formed as the proportion of a flow rate of an oxygen gas to the whole film formation gas (also referred to as oxygen flow rate ratio) used in formation is increased.

The crystallinity of the oxide semiconductor layer 230 can be analyzed by XRD, TEM, or ED, for example. Alternatively, these methods may be combined for the analysis.

The oxide semiconductor layer 230 may have a stacked-layer structure of two or more metal oxide layers having different crystallinities. For example, a stacked-layer structure of a first metal oxide layer and a second metal oxide layer provided over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

For example, it is preferable that the first metal oxide layer be formed using a metal oxide with a composition of In:M:Zn=1:3:2 [atomic ratio] or in the neighborhood thereof or a metal oxide with a composition of In:M:Zn=1:3:4 [atomic ratio] or in the neighborhood thereof, and that the second metal oxide layer be formed using a metal oxide with a composition of In:M:Zn=1:1:1 [atomic ratio] or in the neighborhood thereof. The use of a metal oxide in which the ratio of Zn to In is high for the first metal oxide layer can increase the crystallinity of the first metal oxide layer. Furthermore, forming the second metal oxide layer over the first metal oxide layer with high crystallinity facilitates increasing the crystallinity of the second metal oxide layer. This is preferable because the crystallinity of the whole oxide semiconductor layer 230 can be increased. At this time, gallium, aluminum, or tin is particularly preferably used as the element M. For example, two IGZO layers having different compositions may be stacked. For another example, a stacked-layer structure of one selected from indium oxide, indium gallium oxide, and IGZO, and one selected from IAZO, IAGZO, and ITZO (registered trademark) may be employed.

Furthermore, the oxide semiconductor layer 230 may have a stacked-layer structure of three or more layers. The oxide semiconductor layer 230 can have a three-layer structure including a third metal oxide layer, the first metal oxide layer over the third metal oxide layer, and the second metal oxide layer over the first metal oxide layer, for example.

The above-described structure can be applied to each of the first metal oxide layer and the second metal oxide layer. The structure of the third metal oxide layer can be similar to the structure that can be applied to the second metal oxide layer. Hereinafter, the second metal oxide layer and the third metal oxide layer are collectively described as a pair of metal oxide layers between which the first metal oxide layer is interposed.

For example, for the first metal oxide layer, it is preferable to use a metal oxide with a composition of In:Zn=1:1 [atomic ratio] or in the neighborhood thereof, a metal oxide with a composition of In:Zn=2:1 [atomic ratio] or in the neighborhood thereof, a metal oxide with a composition of In:Sn:Zn=2:0.1:1 [atomic ratio] or in the neighborhood thereof, a metal oxide with a composition of In:Zn=4:1 [atomic ratio] or in the neighborhood thereof, a metal oxide with a composition of In:Sn:Zn=4:0.1:1 [atomic ratio] or in the neighborhood thereof, or an indium oxide. For the pair of metal oxide layers between which the first metal oxide layer is interposed, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof, for example.

The pair of metal oxide layers between which the first metal oxide layer is interposed preferably have a larger band gap than the first metal oxide layer. Thus, the first metal oxide layer is interposed between the pair of metal oxide layers having a large band gap, and the first metal oxide layer mainly functions as a current path (channel). When the first metal oxide layer is interposed between the pair of metal oxide layers, the trap states at the interfaces with the first metal oxide layer and the vicinity thereof can be reduced. Accordingly, a buried-channel transistor where a channel is distanced from the interface with an insulating layer can be achieved, whereby the field-effect mobility can be increased. Furthermore, the influence of interface states that can be formed on the back channel side is reduced, so that light deterioration (e.g., light negative bias deterioration) of the transistor can be inhibited and the reliability of the transistor can be increased.

The thickness of the oxide semiconductor layer 230 is preferably larger than or equal to 3 nm and smaller than or equal to 200 nm, further preferably larger than or equal to 3 nm and smaller than or equal to 100 nm, still further preferably larger than or equal to 5 nm and smaller than or equal to 100 nm, yet still further preferably larger than or equal to 10 nm and smaller than or equal to 100 nm, yet still further preferably larger than or equal to 10 nm and smaller than or equal to 70 nm, yet still further preferably larger than or equal to 15 nm and smaller than or equal to 70 nm, yet still further preferably larger than or equal to 15 nm and smaller than or equal to 50 nm, yet still further preferably larger than or equal to 20 nm and smaller than or equal to 50 nm. In a transistor used for a miniaturized semiconductor device, the thickness of the oxide semiconductor layer 230 is preferably larger than or equal to 1 nm, larger than or equal to 3 nm, or larger than or equal to 5 nm and smaller than or equal to 20 nm, smaller than or equal to 15 nm, smaller than or equal to 12 nm, or smaller than or equal to 10 nm.

At the time of forming the oxide semiconductor layer, two kinds of film formation methods, which are a sputtering method and an ALD method, are preferably used. For example, after a first oxide semiconductor layer having a CAAC structure is formed by a sputtering method, a second oxide semiconductor layer having lower crystallinity than the CAAC structure is formed by an ALD method, in which case, an atomic layer of the second oxide semiconductor layer is expected to fill or repair an atomic-level gap between crystal parts included in the CAAC structure of the first oxide semiconductor layer. After the second oxide semiconductor layer is formed by an ALD method, heat treatment (e.g., at higher than or equal to 100° C. and lower than or equal to 500° C., preferably higher than or equal to 200° C. and lower than or equal to 450° C., further preferably higher than or equal to 300° C. and lower than or equal to 400° C.) is preferably performed. By the heat treatment, the atomic-level gap between crystal parts included in the CAAC structure of the first oxide semiconductor layer is expected to be repaired by the second oxide semiconductor layer (in other words, crystal molecules formed by an ALD method). The oxide semiconductor layer formed by the two kinds of film formation methods may be referred to as a Hybrid OS.

Even in the case where a minute gap or a minute space is included in the first oxide semiconductor layer, forming the second oxide semiconductor layer over the first oxide semiconductor layer or forming the second oxide semiconductor layer and performing heat treatment can fill the minute gap or the minute space in the first oxide semiconductor layer. When an oxide semiconductor layer having a CAAC structure is used as the first oxide semiconductor layer and an oxide semiconductor layer having a microcrystalline structure or an amorphous structure is used as the second oxide semiconductor layer in this manner, a dense oxide semiconductor layer with increased crystallinity density can be provided. When the dense oxide semiconductor layer with increased crystallinity density is used in a channel formation region of a transistor, an increase in electric resistance of the oxide semiconductor layer can be inhibited or initial characteristics (particularly on-state current) of the transistor can be improved; thus, the transistor suitable for high-speed operation can be expected.

In the case where an oxide semiconductor layer is formed by both a sputtering method and an ALD method and an oxide semiconductor layer formed by an ALD method is thin, the oxide semiconductor layer can be regarded as not having a stacked-layer structure of an oxide semiconductor layer formed by a sputtering method and the oxide semiconductor layer formed by an ALD method, but having a single-layer structure. For example, when the thickness of the oxide semiconductor layer formed by an ALD method is greater than 0 nm and less than or equal to 3 nm, preferably greater than 0 nm and less than or equal to 2 nm, further preferably greater than 0 nm and less than or equal to 1 nm, the oxide semiconductor layer formed by two kinds of film formation methods, which are a sputtering method and an ALD method, can be regarded as having a single-layer structure. In such a case, for example, a boundary between the oxide semiconductor layer formed by a sputtering method and the oxide semiconductor layer formed by an ALD method is not observed in a cross-sectional TEM image, a cross-sectional STEM image, or the like. On the other hand, when the thickness of the oxide semiconductor layer formed by an ALD method exceeds 3 nm, the oxide semiconductor layer can be sometimes regarded as having a stacked-layer structure, a multilayer structure, or a multi-structure of the oxide semiconductor layer formed by a sputtering method and the oxide semiconductor layer formed by an ALD method.

In the case where the oxide semiconductor layer is formed by both a sputtering method and an ALD method, different compositions are preferably employed. Typically, a metal oxide with a composition of In:Ga:Zn=1:1:1 [atomic ratio] or in the neighborhood thereof can be formed by a sputtering method, and then a metal oxide with a composition of In:Ga:Zn=4:0.1:1 [atomic ratio] or in the neighborhood thereof can be formed by an ALD method. The oxide semiconductor layer having the above composition can have high reliability owing to the metal oxide layer with In:Ga:Zn=1:1:1 [atomic ratio] and have high on-state current or high field-effect mobility owing to the metal oxide with a composition of In:Ga:Zn=4:0.1:1 [atomic ratio] or in the neighborhood thereof. Instead of the metal oxide with a composition of In:Ga:Zn=4:0.1:1 [atomic ratio] or in the neighborhood thereof, a metal oxide with In:Ga:Zn=1:0:0 [atomic ratio], that is, indium oxide or a metal oxide with a high In proportion can be used.

The oxide semiconductor layer formed by the two kinds of film formation methods can be regarded as having a structure where a gap between crystal parts included in the CAAC structure is filled with an atomic layer formed by an ALD method. Note that the structure can be analyzed by an analysis method such as a cross-sectional SEM, a cross-sectional STEM, a cross-sectional TEM, secondary ion mass spectrometry (SIMS), or EDX.

The oxide semiconductor layer having a CAAC structure formed by the two kinds of film formation methods sometimes has one or more of a higher relative permittivity, higher film density, and higher film hardness than the oxide semiconductor layer having a CAAC structure formed by one kind of film formation method. With the use of the oxide semiconductor layer having the CAAC structure formed by two kinds of film formation methods in a channel formation region of a transistor as described above, a transistor with excellent characteristics (e.g., a transistor with high on-state current, a transistor with high field-effect mobility, a transistor with a small S value, a transistor with high frequency characteristics (also referred to as f characteristics), or a transistor with high reliability) can be achieved.

Hydrogen contained in the oxide semiconductor reacts with oxygen bonded to a metal atom to be water, and thus sometimes forms an oxygen vacancy (Vo) in the oxide semiconductor. In some cases, a defect that is an oxygen vacancy into which hydrogen has entered (hereinafter, referred to as VoH) functions as a donor and generates an electron serving as a carrier. In some cases, bonding of part of hydrogen to oxygen bonded to a metal atom generates electrons serving as carriers. Thus, a transistor including an oxide semiconductor that contains a large amount of hydrogen is likely to become normally-on characteristics (i.e., a negative threshold voltage value). Moreover, hydrogen in the oxide semiconductor is easily transferred by a stress such as heat or an electric field; thus, a large amount of hydrogen in the oxide semiconductor might reduce the reliability of the transistor.

The amount of VoH in the oxide semiconductor layer 230 is preferably reduced as much as possible so that the oxide semiconductor layer 230 becomes a highly purified intrinsic or substantially highly purified intrinsic oxide. In order to obtain such an oxide semiconductor with sufficiently reduced VoH, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as VoH is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of an oxide semiconductor in the region functioning as a channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm⁻³.

Here, the influence of each impurity in the metal oxide (oxide semiconductor) is described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor using the oxide semiconductor containing nitrogen as a semiconductor is likely to become normally-on characteristics. When nitrogen is contained in the oxide semiconductor, trap states are sometimes formed. This might make the electrical characteristics of the transistor unstable. Thus, the concentration of nitrogen in the channel formation region in the oxide semiconductor, which is obtained by SIMS, is set lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor including the oxide semiconductor that contains hydrogen is likely to become normally-on characteristics. For this reason, hydrogen in the channel formation region of the oxide semiconductor is preferably reduced as much as possible. Specifically, the hydrogen concentration in the channel formation region of the oxide semiconductor, which is obtained by SIMS, is set lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to become normally-on characteristics. Thus, the concentration of an alkali metal or an alkaline earth metal in the channel formation region of the oxide semiconductor, which is obtained by SIMS, is set lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

Note that for the semiconductor device of this embodiment, a transistor using a different semiconductor material in its channel formation region may be used. Examples of the different semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also a kind of compound semiconductor. These semiconductor materials may contain an impurity as a dopant.

As examples of silicon that can be used for the semiconductor material for the transistor, single crystal silicon, polycrystalline silicon, microcrystalline silicon, and amorphous silicon can be given. An example of polycrystalline silicon is low-temperature polysilicon (LTPS).

The semiconductor layer of the transistor may contain a layered substance that functions as a semiconductor. The layered substance is a general term of a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for the channel formation region, the transistor can have a high on-state current.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer]

For the insulating layers (the insulating layer 140, the insulating layer 250, the insulating layer 280, the insulating layer 283, the insulating layer 285, and the like) included in the semiconductor device, the insulating material described in [Insulating layer] in Embodiment 1 can be used.

As miniaturization and high integration of transistors progress, for example, a problem such as a leakage current may arise because of a thinner gate insulating layer. When a high-k material is used for a gate insulating layer, the voltage at the time of the operation of the transistor can be reduced while the physical thickness is maintained. In addition, the equivalent oxide thickness (EOT) of the gate insulating layer can be reduced. In contrast, when a material with a low relative permittivity is used for the insulating layer functioning as an interlayer film, parasitic capacitance generated between wirings can be reduced. Thus, a material can be selected depending on the function of an insulating layer. Note that the material with a low relative permittivity is a material with high dielectric strength.

A material that can have ferroelectricity can be used for the insulating layer included in the semiconductor device. The description in Embodiment 1 can be referred to for the material that can have ferroelectricity; thus, the detailed description thereof is omitted.

When a transistor using a metal oxide is surrounded by an insulating layer having a function of inhibiting transmission of impurities and oxygen, the transistor can have stable electrical characteristics. As the insulating layer having a function of inhibiting transmission of impurities and oxygen, a single layer or stacked layers including an insulating layer containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used, for example. Specifically, as a material of the insulating layer having a function of inhibiting transmission of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

Specific examples of the insulating layer having a function of inhibiting transmission of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulating layer having a function of inhibiting transmission of oxygen and impurities such as water and hydrogen include oxides containing aluminum and hafnium (hafnium aluminate). Other examples of the insulating layer having a function of inhibiting transmission of oxygen and impurities such as water and hydrogen include metal nitrides such as aluminum nitride, aluminum titanium nitride, titanium nitride, silicon nitride oxide, and silicon nitride.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies in the oxide semiconductor layer can be reduced. Examples of an insulating layer in which a region containing excess oxygen is easily formed include silicon oxide, silicon oxynitride, and porous silicon oxide.

The insulating layer 280 preferably includes a barrier insulating layer against hydrogen. The insulating layer 280 is provided to surround the oxide semiconductor layer 230. When the insulating layer 280 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow transmission of a target substance, a property with low permeability to a target substance, or a function of inhibiting diffusion of a target substance). In addition, hydrogen described as a target substance refers to at least one of a hydrogen atom, a hydrogen molecule, and a substance bonded to hydrogen, such as a water molecule or OH—, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

For example, the insulating layer 280 preferably includes one or both of an aluminum oxide film and a silicon nitride film.

Note that silicon nitride also has a barrier property against oxygen. Thus, using silicon nitride for the insulating layer 280 can inhibit extraction of oxygen from the oxide semiconductor layer 230, and accordingly can inhibit formation of an excess amount of oxygen vacancies in the oxide semiconductor layer 230.

Furthermore, when silicon nitride is used for the insulating layer 280, excess oxygen can be prevented from being supplied to the oxide semiconductor layer 230. Thus, the channel formation region of the oxide semiconductor layer 230 can be prevented from containing excess oxygen, whereby the reliability of the transistor 200A can be improved.

The insulating layer 280 preferably includes any of an oxide insulating film, an oxynitride insulating film, and an insulating layer including a region containing excess oxygen, which are described above.

For example, the insulating layer including a region containing excess oxygen can be formed by a sputtering method in an oxygen-containing atmosphere. With the use of a sputtering method, which does not need to use a molecule containing hydrogen in a deposition gas, the hydrogen concentration in the insulating layer 280 can be reduced. When at least part of the insulating layer 280 is formed in this manner, oxygen can be supplied from the insulating layer 280 to the channel formation region of the oxide semiconductor layer 230, so that oxygen vacancies and VoH can be reduced.

The concentration of impurities such as water and hydrogen in the insulating layer 280 is preferably reduced. This can inhibit entry of impurities such as water and hydrogen into the channel formation region of the oxide semiconductor layer 230.

Note that since the thickness of the insulating layer 280 over the conductive layer 120 corresponds to the channel length of the transistor 200A, the thickness of the insulating layer 280 can be set as appropriate depending on the design value of the channel length of the transistor 200A.

For example, a single-layer structure of a silicon nitride film, a silicon nitride oxide film, or an aluminum oxide film is preferably used for the insulating layer 280. Alternatively, for example, a three-layer structure where a silicon nitride film, a silicon oxide film, and a silicon nitride film are stacked in this order is preferably used for the insulating layer 280. For example, a three-layer structure where an aluminum oxide film, a silicon oxide film, and an aluminum oxide film are stacked in this order is preferably used for the insulating layer 280.

The insulating layer 250 preferably has a function of capturing hydrogen and fixing hydrogen. In this case, the hydrogen concentration in the oxide semiconductor layer 230 (in particular, the hydrogen concentration in the channel formation region of the transistor) can be reduced. Accordingly, VoH in the channel formation region can be reduced, so that the channel formation region can be an i-type or substantially i-type region.

Examples of a material for the insulating layer having a function of capturing or fixing hydrogen include metal oxides such as an oxide containing hafnium, an oxide containing magnesium, an oxide containing aluminum, and an oxide containing aluminum and hafnium (hafnium aluminate). These metal oxides may further contain zirconium, and an example of such a metal oxide is an oxide containing hafnium and zirconium. In a metal oxide having an amorphous structure, some oxygen atoms have a dangling bond, which allows the metal oxide to have a high capability of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide includes one or both of a crystal region and a crystal grain boundary in some cases.

Note that a function of capturing or fixing a target substance can also be referred to as a property that does not easily allow diffusion of a target substance. Thus, a function of capturing or fixing a target substance can be rephrased as a barrier property.

In the case where the gate insulating layer has a stacked-layer structure, a layer in contact with the oxide semiconductor layer 230 preferably has a function of capturing or fixing hydrogen. Thus, hydrogen contained in the oxide semiconductor layer 230 can be captured or fixed more effectively. Thus, the hydrogen concentration in the oxide semiconductor layer 230 can be reduced. For a layer of the insulating layer 250 which is in contact with the oxide semiconductor layer 230, hafnium silicate or the like is preferably used, for example. The layer preferably has an amorphous structure.

The layer having an amorphous structure can inhibit formation of a crystal grain boundary. Inhibiting the formation of a crystal grain boundary can increase the planarity of the layer. This makes the thickness distribution of the insulating layer 250 uniform and the number of extremely thin portions to be reduced, so that the breakdown voltage of the insulating layer 250 can be improved. In addition, the thickness distribution of a film provided over the insulating layer 250 can be uniform.

Moreover, inhibiting the formation of a crystal grain boundary in the layer can reduce leakage current due to the defect states in the crystal grain boundary. Thus, the insulating layer 250 can function as an insulating film with a low leakage current.

Since hafnium oxide is a high permittivity (high-k) material, hafnium silicate is a high permittivity (high-k) material depending on the silicon content. Accordingly, in the case where hafnium oxide or hafnium silicate is used for the gate insulating layer, a gate potential applied during operation of the transistor can be reduced while the physical thickness of the gate insulating layer is maintained. In addition, the equivalent oxide thickness (EOT) of the gate insulating layer can be reduced.

As described above, for the insulating layer 250, an oxide containing one or both of aluminum and hafnium is preferably used, an oxide that has an amorphous structure and contains one or both of aluminum and hafnium is further preferably used, and aluminum oxide having an amorphous structure is still further preferably used.

As the insulating layer 250, the above-described barrier insulating layer against hydrogen is preferably used. When a barrier insulating layer against hydrogen is used as the insulating layer 250, diffusion of impurities contained in the conductive layer 260 into the oxide semiconductor layer 230 can be inhibited. For example, silicon nitride is suitably used for the insulating layer 250 because of its high barrier property against hydrogen. Furthermore, the insulating layer 250 may include an insulating layer with a thermally stable structure, such as silicon oxide or silicon oxynitride.

With such a structure, a semiconductor device having favorable electrical characteristics can be provided. A highly reliable semiconductor device can be provided. A semiconductor device with a small variation in electrical characteristics can be provided. A semiconductor device with a high on-state current can be provided.

Furthermore, the insulating layer 250 may include an insulating layer with a thermally stable structure, such as silicon oxide or silicon oxynitride.

The insulating layer 250 may include, between a pair of insulating layers having a function of capturing hydrogen and fixing hydrogen, an insulating layer with a thermally stable structure.

The insulating layer 250 preferably includes a barrier insulating layer against oxygen. This can inhibit oxidation of the conductive layer 240, the conductive layer 260, and the like. In the case where the insulating layer 250 has a stacked-layer structure, a layer in contact with the conductive layer 240 is preferably a barrier insulating layer against oxygen. In particular, among layers included in the insulating layer 250, a layer in contact with the conductive layer 240 and a layer in contact with the conductive layer 260 are each preferably a barrier insulating layer against oxygen.

When a barrier insulating layer against hydrogen and oxygen is used as the layer of the insulating layer 250 which is in contact with the conductive layer 260, oxidation of the conductive layer 260 can be inhibited. Moreover, diffusion of oxygen contained in the oxide semiconductor layer 230 into the conductive layer 260 and formation of oxygen vacancies in the oxide semiconductor layer 230 can be inhibited.

Examples of the barrier insulating layer against oxygen include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The layer that is included in the insulating layer 250 and is in contact with the conductive layer 240 is preferably less likely to transmit oxygen than at least the insulating layer 280. When the layer has a barrier property against oxygen, oxidation of the side surface of the conductive layer 240 and formation of an oxide film on the side surface can be inhibited. Accordingly, a decrease in on-state current or field-effect mobility of the transistor 200A can be inhibited.

Each layer included in the insulating layer 250 is preferably a thin film. For example, when each layer included in the insulating layer 250 is greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in the subthreshold region when the drain voltage is constant and the drain current is changed by one order of magnitude.

The thickness of each of the layers included in the insulating layer 250 is preferably larger than or equal to 0.1 nm and smaller than or equal to 10 nm, further preferably larger than or equal to 0.1 nm and smaller than or equal to 5 nm, still further preferably larger than or equal to 0.5 nm and smaller than or equal to 5 nm, yet further preferably larger than or equal to 1 nm and smaller than 5 nm, yet still further preferably larger than or equal to 1 nm and smaller than or equal to 3 nm. Each of the layers included in the insulating layer 250 at least partly includes a region with the above-described thickness.

The insulating layer 250 preferably has a three-layer structure where a first insulating layer containing a material with a low relative permittivity, a second insulating layer having a function of capturing or fixing hydrogen, and a third insulating layer having a barrier property against hydrogen and oxygen are stacked in this order from the oxide semiconductor layer 230 side. As a material with low relative permittivity contained in the first insulating layer, silicon oxide or silicon oxynitride is preferably used. The first insulating layer is in contact with the oxide semiconductor layer 230. When an oxide is used for the first insulating layer, oxygen can be supplied to the oxide semiconductor layer 230. Providing the third insulating layer can inhibit diffusion of oxygen contained in the first insulating layer into the conductive layer 260 so that the oxidation of the conductive layer 260 can be inhibited. In addition, a reduction in the amount of oxygen supplied to the oxide semiconductor layer 230 from the first insulating layer can be inhibited.

The insulating layer 250 preferably has a four-layer structure where a fourth insulating layer having a barrier property against oxygen, the first insulating layer containing a material with a low relative permittivity, the second insulating layer having a function of capturing or fixing hydrogen, and the third insulating layer having a barrier property against hydrogen and oxygen are stacked in this order from the oxide semiconductor layer 230 side. The first insulating layer to the third insulating layer can have a structure similar to that of the layers used in the above three-layer structure. The fourth insulating layer is in contact with the oxide semiconductor layer 230. When the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen and is thus suitable for the fourth insulating layer in contact with the oxide semiconductor layer 230.

Typically, the fourth insulating layer, the first insulating layer, the second insulating layer, and the third insulating layer are preferably aluminum oxide, silicon oxide, hafnium oxide, and silicon nitride, respectively. Furthermore, typically, the thicknesses of the fourth insulating layer, the first insulating layer, the second insulating layer, and the third insulating layer are 1 nm, 2 nm, 2 nm, and 1 nm, respectively. This structure enables the transistor to have favorable electrical characteristics even when the transistor is miniaturized or highly integrated.

The insulating layer 250 preferably has a three-layer structure where the fourth insulating layer having a barrier property against oxygen, the first insulating layer containing a material with a low relative permittivity, and the second insulating layer having a function of capturing or fixing hydrogen are stacked in this order from the oxide semiconductor layer 230 side. That is, the third insulating layer is not necessarily provided.

As the insulating layer 283, a barrier insulating layer against hydrogen is preferably used. In that case, diffusion of hydrogen from above the insulating layer 283 into the oxide semiconductor layer 230 can be inhibited. A silicon nitride film and a silicon nitride oxide film can be suitably used for the insulating layer 283 because the silicon nitride film and the silicon nitride oxide film release fewer impurities (e.g., water and hydrogen) and are less likely to transmit oxygen and hydrogen.

Silicon nitride deposited by a sputtering method is particularly preferably used as the insulating layer 283. Since a sputtering method does not need to use a molecule containing hydrogen as a deposition gas, the hydrogen concentration in the insulating layer 283 can be reduced. When the insulating layer 283 is deposited by a sputtering method, high-density silicon nitride can be formed.

As the insulating layer 283, an insulating layer having a function of capturing or fixing hydrogen may be used. With such a structure, diffusion of hydrogen from above the insulating layer 283 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 283, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 285 functions as an interlayer film and thus is preferably formed using the above-described material having low relative permittivity. For example, the insulating layer 285 preferably includes a silicon oxide film.

The concentration of impurities such as water and hydrogen in the insulating layer 140 is preferably reduced. This can inhibit entry of impurities such as water and hydrogen into the channel formation region of the oxide semiconductor layer 230.

As the insulating layer 140, a barrier insulating layer against hydrogen is preferably used. This can inhibit diffusion of hydrogen into the oxide semiconductor layer 230.

For example, a silicon nitride film is preferably used as the insulating layer 140.

### [Conductive Layer]

For the conductive layers (the conductive layer 120, the conductive layer 240, the conductive layer 260, the conductive layer 265, and the like) included in the semiconductor device, the conductive material described in [Conductive layer] in Embodiment 1 can be used.

In the case where a metal oxide is used for the channel formation region of the transistor, the conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

Each of the conductive layer 120 and the conductive layer 240 are in contact with the oxide semiconductor layer 230, and is thus preferably formed using a conductive material that is not easily oxidized, a conductive material that maintains its low electrical resistance even after being oxidized, a metal oxide having conductivity (also referred to as an oxide conductor), or a conductive material that has a function of inhibiting diffusion of oxygen. Examples of the conductive material include a conductive material containing nitrogen and a conductive material containing oxygen. In that case, a decrease in conductivity of the conductive layer 120 and the conductive layer 240 can be inhibited.

When a conductive material containing oxygen is used for the conductive layer 120 or the conductive layer 240, the conductive layer 120 or the conductive layer 240 can maintain its conductivity even after absorbing oxygen. For each of the conductive layer 120 and the conductive layer 240, ITO, ITSO, IZO (registered trademark), or the like is preferably used, for example.

FIG. 9B and FIG. 9C each illustrate an example where the conductive layer 120 has a stacked-layer structure of the conductive layer 120a and the conductive layer 120b over the conductive layer 120a. Each of the conductive layer 120a and the conductive layer 120b may have a single-layer structure or a stacked-layer structure. For example, in the case where the conductive layer 120a has a two-layer structure of the first conductive layer and the second conductive layer over the first conductive layer, a conductive material that is less likely to be oxidized or a conductive material having a function of inhibiting diffusion of oxygen is preferably used for the first conductive layer, a material with high conductivity is preferably used for the second conductive layer, and a conductive material containing oxygen (further preferably an oxide conductor) is preferably used for the conductive layer 120b. Specifically, titanium nitride is preferably used for the first conductive layer, tungsten is preferably used for the second conductive layer, and an oxide conductor (e.g., ITO, ITSO, or IZO (registered trademark)) is preferably used for the conductive layer 120b. In that case, titanium nitride is in contact with the insulating layer 180 and the oxide conductor is in contact with the oxide semiconductor layer 230. Since the oxide conductor has a lower contact resistance with the oxide semiconductor layer 230 than tungsten, the current path between the source and the drain can be shortened and the on-state current of the transistor can be increased. Such a structure enables the conductive layer 120 to maintain its conductivity even when the conductive layer 120 is in contact with the oxide semiconductor layer 230. In the case where an oxide insulating layer is used as the insulating layer 180, excessive oxidation of the conductive layer 120 due to the insulating layer 180 can be inhibited. When a metal material (here, tungsten) having higher conductivity than the oxide conductor and titanium nitride is used for the second conductive layer, the conductivity of the conductive layer 120 can be increased.

FIG. 9B and FIG. 9C each illustrate an example where the conductive layer 240 has a two-layer structure of the conductive layer 240a and the conductive layer 240b over the conductive layer 240a.

There is no particular limitation on the material used for the conductive layer 240a and the conductive layer 240b. A material having higher conductivity than a material for the conductive layer 240b may be used for the conductive layer 240a, and a material having higher conductivity than a material for the conductive layer 240a may be used for the conductive layer 240b. An oxide conductor is preferably used for the conductive layer 240a or the conductive layer 240b.

For example, a conductive material containing oxygen is preferably used for the conductive layer 240a, and a material having higher conductivity than the material for the conductive layer 240a is preferably used for the conductive layer 240b. Specifically, for example, an oxide conductor (e.g., ITO, ITSO, or IZO (registered trademark)) is preferably used for the conductive layer 240a, and ruthenium, tungsten, titanium nitride, or tantalum nitride is preferably used for the conductive layer 240b. Among layers included in the conductive layer 240, the use of a conductive material containing oxygen for the layer closest to the channel formation region can reduce the contact resistance with the oxide semiconductor layer 230, which allows a short current path between the source and the drain and thus can increase the on-state current of the transistor.

Alternatively, a conductive material containing oxygen may be used for the conductive layer 240b, and a material having higher conductivity than the material for the conductive layer 240b may be used for the conductive layer 240a. In the transistor 200A, the oxide semiconductor layer 230 is in contact with the side surface of the conductive layer 240a and the top and side surfaces of the conductive layer 240b, and is not in contact with the top surface of the conductive layer 240a. In that case, the oxide semiconductor layer 230 is in contact with the conductive layer 240b in a larger area than with the conductive layer 240a. For example, when an oxide conductor is used for the conductive layer 240b and a material having higher conductivity than the oxide conductor, such as tungsten, is used for the conductive layer 240a, the oxide conductor is mainly in contact with the oxide semiconductor layer 230. Such a structure enables the conductive layer 240 to maintain its conductivity even when being in contact with the oxide semiconductive layer 230. When a material having higher conductivity than a material for the conductive layer 240b is used for the conductive layer 240a, the conductivity of the conductive layer 240 can be increased. Furthermore, the contact resistance between the oxide semiconductor layer 230 and the conductive layer 240b can be reduced, so that a decrease in on-state current of the transistor 200A due to the contact resistance can be inhibited.

The conductive layer 260 is preferably formed using a material with high conductivity such as tungsten. In addition, a conductive material that is not easily oxidized, a conductive material having a function of inhibiting diffusion of oxygen, or the like is preferably used for the conductive layer 260. Examples of the conductive material include a conductive material containing nitrogen (e.g., titanium nitride or tantalum nitride) and a conductive material containing oxygen (e.g., ruthenium oxide), as described above. This can inhibit a decrease in the conductivity of the conductive layer 260.

It is preferable to use, for the conductive layer 260, a conductive material containing oxygen and a metal element contained in the metal oxide where the channel is formed. Alternatively, a conductive material containing the above metal element and nitrogen (e.g., titanium nitride or tantalum nitride) may be used. One or more of ITO, indium oxide containing tungsten oxide, indium zinc oxide containing tungsten oxide, indium oxide containing titanium oxide, indium tin oxide containing titanium oxide, IZO (registered trademark), and ITSO may be used. Indium gallium zinc oxide containing nitrogen may be used. With the use of such a material, hydrogen contained in the metal oxide where the channel is formed can be captured in some cases. Alternatively, hydrogen entering from an external insulating layer or the like can be captured in some cases.

The conductive layer 260 preferably has a stacked-layer structure of titanium nitride and tungsten over the titanium nitride, for example. Alternatively, a stacked-layer structure of tantalum nitride and copper over the tantalum nitride is preferably used. Such a structure can increase the conductivity of the conductive layer 260.

Alternatively, the conductive layer 260 may have a stacked-layer structure of three or more layers. The conductive layer 260 may have a three-layer structure of tantalum nitride, titanium nitride over the tantalum nitride, and tungsten over the titanium nitride, for example.

The conductive layer 265 functions as the gate wiring and thus preferably has high conductivity. For the conductive layer 265, tungsten is preferably used. The conductive layer 265 may have a structure similar to that of the conductive layer 260. For example, a two-layer structure of titanium nitride and tungsten may be employed.

### <Structure Example of Semiconductor Device>

The memory cell 150 including the transistor 200A and the capacitor 100 described in this embodiment can be used as a memory cell of the storage device. The transistor 200A is a transistor in which a channel is formed in a semiconductor layer including an oxide semiconductor. Since the transistor 200A has a low off-state current, a storage device that uses the transistor 200A can retain stored contents for a long time. In other words, such a storage device does not require refresh operation or has an extremely low frequency of refresh operation, which leads to a sufficient reduction in power consumption of the storage device. The transistor 200A also has high frequency characteristics and thus enables high-speed reading and writing of the storage device.

The memory cells 150 can be arranged in a matrix three-dimensionally to form a memory cell array.

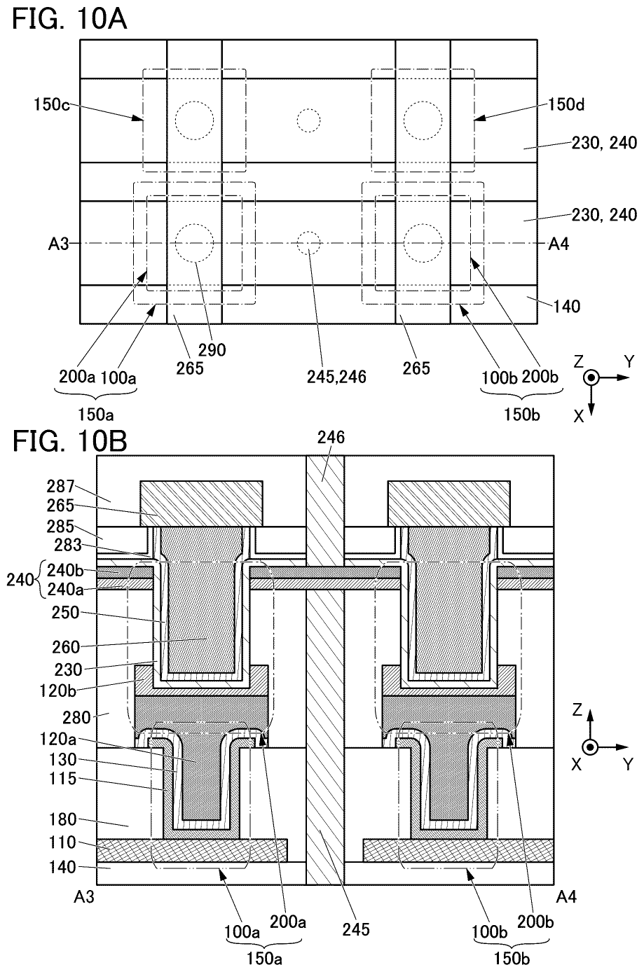

FIG. 10A is a plan view of the semiconductor device of one embodiment of the present invention. FIG. 10A illustrates an example in which 2×2 memory cells (a memory cell 150a to a memory cell 150d) are placed in the X direction and the Y direction.

FIG. 10B is a cross-sectional view along the dashed-dotted line A3-A4 in FIG. 10A. In FIG. 10A and FIG. 10B, two memory cells (the memory cell 150a and the memory cell 150b in FIG. 10B) are connected to a common wiring (a conductive layer 246).

Here, the memory cell 150a and the memory cell 150b illustrated in FIG. 10A and FIG. 10B each have a structure similar to that of the memory cell 150. The memory cell 150a includes a capacitor 100a and a transistor 200a, and the memory cell 150b includes a capacitor 100b and a transistor 200b. The memory cell 150c and the memory cell 150d illustrated in FIG. 10A each have a structure similar to that of the memory cell 150. Thus, in the semiconductor device illustrated in FIG. 10A and FIG. 10B, components having the same functions as the components of the semiconductor device illustrated in FIG. 9A to FIG. 9C are denoted by the same reference numerals. The description of the memory cell 150 in <Structure example of memory cell> can be referred to for the details of the memory cell 150a to the memory cell 150d.

As illustrated in FIG. 10A and FIG. 10B, the conductive layer 265 functioning as a wiring WL is provided in each of the memory cell 150a and the memory cell 150b. As illustrated in FIG. 10A, one conductive layer 265 is provided to be shared by the memory cell 150a and the memory cell 150c, and another conductive layer 265 is provided to be shared by the memory cell 150b and the memory cell 150d. One conductive layer 240 functioning as part of a wiring BL is provided to be shared by the memory cell 150a and the memory cell 150b. That is, the conductive layer 240 is in contact with the oxide semiconductor layer 230 of the memory cell 150a and the oxide semiconductor layer 230 of the memory cell 150b. Another conductive layer 240 is provided to be shared by the memory cell 150c and the memory cell 150d. The wiring WL and the wiring BL will be described later.

FIG. 10B illustrates an example where the conductive layer 240 has a two-layer structure of the conductive layer 240a and the conductive layer 240b over the conductive layer 240a.

Here, the semiconductor device illustrated in FIG. 10A and FIG. 10B includes a conductive layer 245 and the conductive layer 246 functioning as plugs (which can also be referred to as connection electrodes) electrically connected to the memory cell 150a and the memory cell 150b. The conductive layer 245 is placed in an opening portion formed in the insulating layer 140, the insulating layer 180, and the insulating layer 280 and is in contact with the bottom surface of the conductive layer 240a. The conductive layer 246 is placed in an opening portion formed in an insulating layer 287, the insulating layer 285, the insulating layer 283, and the oxide semiconductor layer 230 and is in contact with the top surface of the conductive layer 240b. Note that the conductive material or the like that can be used for the conductive layer 240 can be used for the conductive layer 245 and the conductive layer 246.

The conductive layer 246 can be in contact with the top surface of the conductive layer 240a. That is, the conductive layer 240b may include an opening portion in a position overlapping with the conductive layer 246. Alternatively, the conductive layer 246 can be in contact with the top surface of the oxide semiconductor layer 230. That is, the oxide semiconductor layer 230 does not necessarily have an opening portion in a position overlapping with the conductive layer 246. As a connection portion between the memory cell and the plug, a layer having a low contact resistance with the conductive layer 246 among the layers included in the conductive layer 240 and the oxide semiconductor layer 230 is preferably in contact with the conductive layer 246.

Similarly, the conductive layer 245 can be in contact with the bottom surface of the conductive layer 240b or the bottom surface of the oxide semiconductor layer 230. That is, the conductive layer 240a may include an opening portion in a position overlapping with the conductive layer 246. Among the layers included in the conductive layer 240 and the oxide semiconductor layer 230, a layer having a low contact resistance with the conductive layer 245 is preferably in contact with the conductive layer 245.

Among the layers included in the conductive layer 240 and the oxide semiconductor layer 230, a layer with a low wiring resistance is preferably in contact with the conductive layer 245 and the conductive layer 246.

The insulating layer 287 functions as an interlayer film and thus preferably has a low relative permittivity. When a material with a low relative permittivity is used for an interlayer film, the parasitic capacitance generated between wirings can be reduced.

The concentration of impurities such as water and hydrogen in the insulating layer 287 is preferably reduced. This can inhibit entry of impurities such as water and hydrogen into the channel formation region of the oxide semiconductor layer 230.

The conductive layer 245 and the conductive layer 246 function as plugs or wirings for electrically connecting the memory cell 150a and the memory cell 150b to a circuit element such as a switch, a transistor, a capacitor, an inductor, a resistor, or a diode, a wiring, an electrode, or a terminal. For example, the conductive layer 245 can be electrically connected to a sense amplifier (not illustrated) provided below the semiconductor device illustrated in FIG. 10B, and the conductive layer 246 can be electrically connected to a similar semiconductor device (not illustrated) provided above the semiconductor device illustrated in FIG. 10B. In that case, the conductive layer 245 and the conductive layer 246 function as part of the wiring BL. When a similar semiconductor device or the like is provided above or below the semiconductor device illustrated in FIG. 10B in this manner, the storage capacity per unit area can be increased.

The memory cell 150a and the memory cell 150b are line-symmetrical to each other with a perpendicular bisector of the dashed-dotted line A3-A4 as the symmetric axis. Thus, the transistor 200a and the transistor 200b are also placed line-symmetrically with the conductive layer 245 and the conductive layer 246 therebetween. Here, the conductive layer 240 has a function of the other of a source electrode and a drain electrode of the transistor 200a and a function of one of a source electrode and a drain electrode of the transistor 200b. The transistor 200a and the transistor 200b share the conductive layer 245 and the conductive layer 246 functioning as plugs. Accordingly, when the two transistors and the plug are connected as described above, a semiconductor device that can be miniaturized or highly integrated can be provided.

Note that the conductive layer 110 functioning as a wiring PL may be provided in each of the memory cell 150a and the memory cell 150b or may be provided to be shared by the memory cell 150a and the memory cell 150b. However, as illustrated in FIG. 10B, the conductive layer 110 is provided to be apart from the conductive layer 245 so that the conductive layer 110 and the conductive layer 245 are not short-circuited. The wiring PL will be described later.

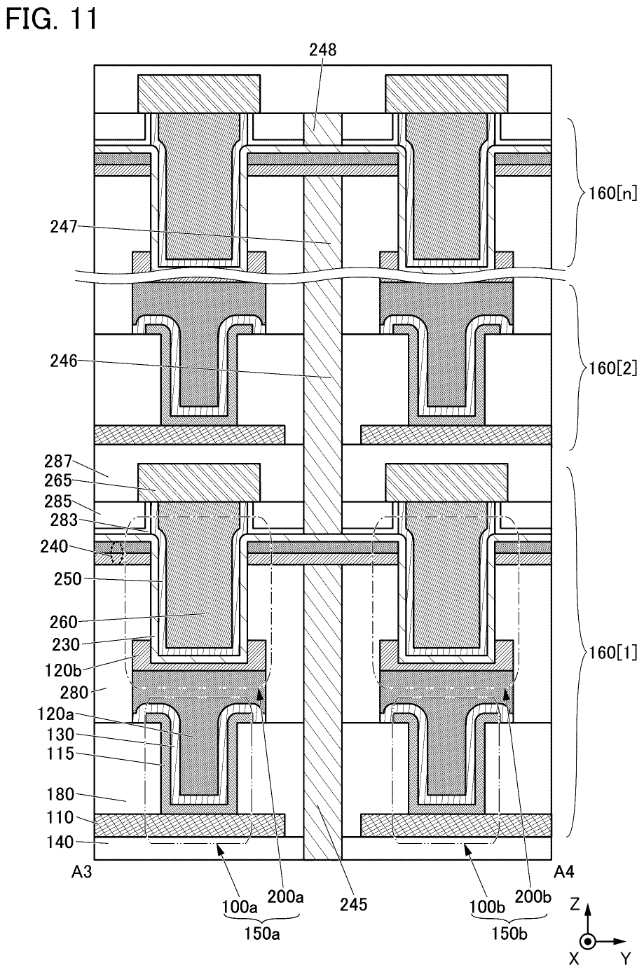

FIG. 11 illustrates an example where four memory cells illustrated in FIG. 10A are stacked in n layers (n is an integer greater than or equal to 3) in the Z direction. FIG. 11 is a cross-sectional view along the dashed-dotted line A3-A4 in FIG. 10A.

The semiconductor device illustrated in FIG. 11 includes n memory layers 160. Specifically, a memory layer 160[2] is provided over a memory layer 160[1], (n-2) memory layers are provided over the memory layer 160[2], and a memory layer 160[n] is provided at the uppermost level. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

FIG. 11 illustrates an example where the conductive layer 245 is in contact with the bottom surface of the conductive layer 240 and the conductive layer 246 is in contact with the top surface of the oxide semiconductor layer 230. As described above, a connection portion between the plug such as the conductive layer 245 or the conductive layer 246 and each memory cell can have any of a variety of modes and is not limited to the structure in FIG. 11.

When a plurality of cell arrays are stacked as illustrated in FIG. 11, cells can be integrated without increasing the area occupied by the cell arrays. In other words, a 3D memory cell array can be formed.

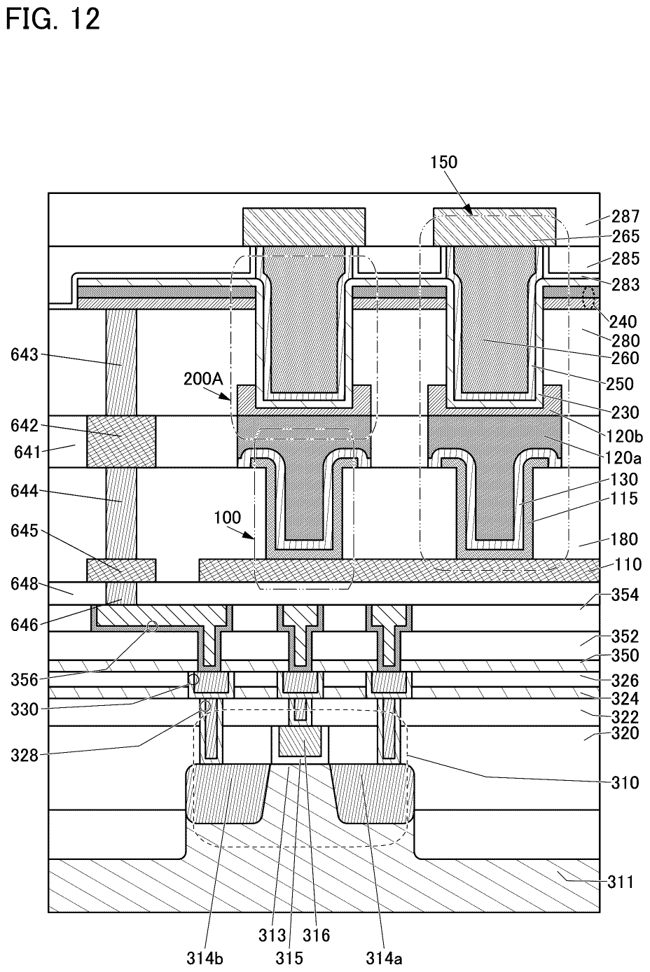

FIG. 12 illustrates a cross-sectional structure example of a semiconductor device in which a layer including a memory cell is stacked over a layer where a driver circuit including a sense amplifier is provided.

In FIG. 12, the memory cell 150 (the transistor 200A and the capacitor 100) is provided above a transistor 310.

The transistor 310 is one of the transistors included in the sense amplifier.

The description of the memory cell 150 in <Structure example of memory cell> can be referred to for the memory cell 150 illustrated in FIG. 12.

With the structure in which the sense amplifier is provided to overlap with the memory cell 150 as illustrated in FIG. 12, the bit line can be shortened. Accordingly, the bit line capacitance can be reduced and the storage device can be driven at high speed.

The semiconductor device illustrated in FIG. 12 can correspond to a storage device 300 described in Embodiment 3. Specifically, the transistor 310 corresponds to a transistor included in a sense amplifier 46 in the storage device 300. The memory cell 150 corresponds to a semiconductor device 10.

The transistor 310 is provided on a substrate 311 and includes a conductive layer 316 functioning as a gate, an insulating layer 315 functioning as a gate insulating layer, a semiconductor region 313 formed of part of the substrate 311, and a low-resistance region 314a and a low-resistance region 314b functioning as a source region and a drain region. The transistor 310 may be a p-channel transistor or an n-channel transistor.

Here, in the transistor 310 illustrated in FIG. 12, the semiconductor region 313 (part of the substrate 311) in which a channel is formed has a protruding shape. In addition, the conductive layer 316 is provided to cover the side surface and the top surface of the semiconductor region 313 with the insulating layer 315 therebetween. Note that a material adjusting the work function may be used for the conductive layer 316. The transistor 310 is also referred to as a FIN-type transistor because it utilizes a protruding portion of the semiconductor substrate. Note that an insulating layer functioning as a mask for forming the projecting portion may be provided in contact with an upper portion of the projecting portion. Although the case where the projecting portion is formed by processing part of the semiconductor substrate is described here, a semiconductor film having a projecting shape may be formed by processing an SOI substrate.

Note that the transistor 310 illustrated in FIG. 12 is an example and the structure is not limited thereto; an appropriate transistor can be used in accordance with a circuit configuration or a driving method.

A wiring layer provided with an interlayer film, a wiring, a plug, and the like may be provided between the components. A plurality of wiring layers can be provided in accordance with the design. Here, a plurality of conductive layers functioning as a plug or a wiring are collectively denoted by the same reference numeral in some cases. Furthermore, in this specification and the like, a wiring and a plug electrically connected to the wiring may be a single component. That is, part of a conductive layer serves as a wiring in some cases and part of the conductive layer serves as a plug in other cases.

For example, an insulating layer 320, an insulating layer 322, an insulating layer 324, and an insulating layer 326 are stacked in this order over the transistor 310 as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 function as a plug or a wiring.

The insulating layers functioning as interlayer films may also function as planarization films that cover uneven shapes therebelow. For example, the top surface of the insulating layer 322 may be planarized by planarization treatment using a CMP method or the like to increase the planarity.

A wiring layer may be provided over the insulating layer 326 and the conductive layer 330. For example, in FIG. 12, an insulating layer 350, an insulating layer 352, and an insulating layer 354 are stacked sequentially. Furthermore, a conductive layer 356 is formed in the insulating layer 350, the insulating layer 352, and the insulating layer 354. The conductive layer 356 functions as a plug or a wiring.

As the insulating layer 352, the insulating layer 354, and the like functioning as interlayer films, any of the above-described insulating layers that can be used for the semiconductor device or the storage device can be used.

As each of the conductive layers functioning as plugs or wirings, such as the conductive layer 328, the conductive layer 330, and the conductive layer 356, the conductive material that can be used for the conductive layer 240 can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

The conductive layer 240 included in the transistor 200A is electrically connected to the low-resistance region 314b functioning as the source region or the drain region of the transistor 310 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 180 and is embedded in an insulating layer 641. The conductive layer 644 is embedded in the insulating layer 180. The conductive layer 645 is covered with the insulating layer 180. The conductive layer 645 and the conductive layer 110 can be formed using the same material in the same step. The conductive layer 646 is embedded in an insulating layer 648. The transistor 310 and the conductive layer 110 are electrically insulated from each other by the insulating layer 648.

As described above, the semiconductor device of this embodiment includes a transistor with reduced parasitic capacitance, and thus can have higher operation speed. In addition, since the semiconductor device of this embodiment includes a capacitor and a transistor that overlap with each other, the area occupied by the memory cell in a plan view can be reduced and a semiconductor device with a high integration degree can be obtained.

### <Operation Example of Memory Cell>

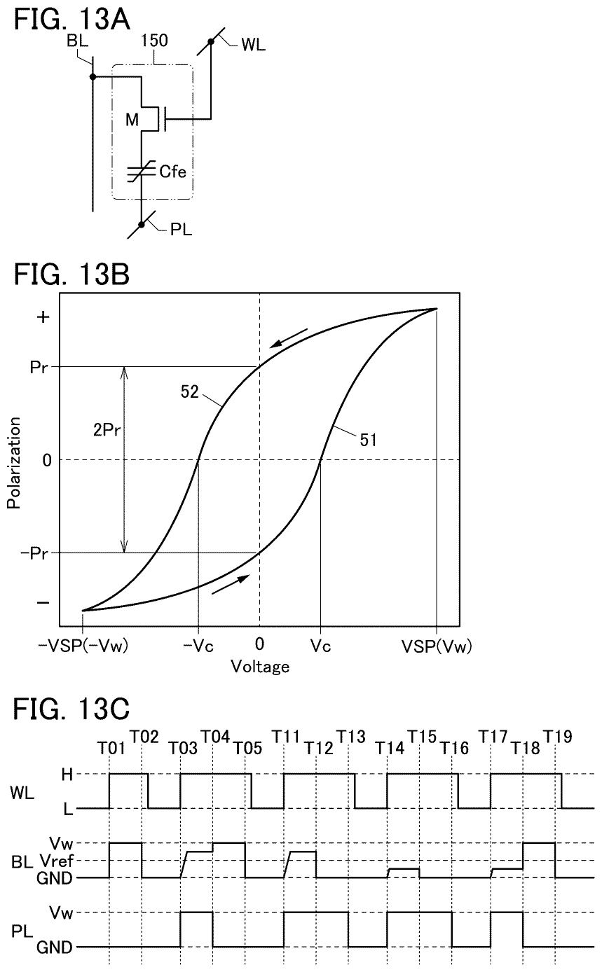

Next, an operation example of the memory cell 150 will be described. FIG. 13A is an equivalent circuit diagram of the memory cell 150. The memory cell 150 illustrated in FIG. 13A functions as a DRAM (1Tr1C-type) storage element including one transistor M and one capacitor Cfe.

The capacitor Cfe is a ferroelectric capacitor including a material that can have ferroelectricity as a ferroelectric layer between two electrodes. Thus, the memory cell 150 functions as an FeRAM. The transistor M illustrated in FIG. 13A corresponds to the transistor 200A, and the capacitor Cfe corresponds to the capacitor 100.

One of a source and a drain of the transistor M is electrically connected to one of a pair of electrodes of the capacitor Cfe. The other of the source and the drain of the transistor M is connected to the wiring BL. A gate of the transistor M is connected to the wiring WL. The other of the pair of electrodes of the capacitor Cfe is connected to the wiring PL.

Here, the wiring BL corresponds to the conductive layer 240, the wiring WL corresponds to the conductive layer 265, and the wiring PL corresponds to the conductive layer 110. As illustrated in FIG. 9A to FIG. 9C, it is preferable that the conductive layer 265 be provided to extend in the X direction and the conductive layer 240 be provided to extend in the Y direction. In this structure, the wiring BL and the wiring WL are provided to intersect with each other. Although the wiring PL (the conductive layer 110) is provided in a plane shape in FIG. 9A, the present invention is not limited thereto. For example, the wiring PL may be provided parallel to the wiring WL (the conductive layer 265) or may be provided parallel to the wiring BL (the conductive layer 240).

A variety of semiconductor materials can be used for a semiconductor layer in which the channel of the transistor M is formed. For example, as the semiconductor layer in which the channel of the transistor M is formed, a single crystal semiconductor, a polycrystalline semiconductor, a microcrystalline semiconductor, an amorphous semiconductor, or the like can be used alone or in combination. As a semiconductor material, silicon or germanium can be used, for example. Alternatively, a compound semiconductor such as silicon germanium, silicon carbide, gallium arsenide, an oxide semiconductor, or a nitride semiconductor may be used.

In particular, an OS transistor is preferably used as the transistor M. The OS transistor has a characteristic of a high withstand voltage between its source and drain. Thus, with use of an OS transistor as the transistor M, a high voltage can be applied to the transistor M even when the transistor M is miniaturized. The miniaturization of the transistor M can reduce the area occupied by the memory cell 150. For example, the area occupied by one memory cell 150 illustrated in FIG. 13A can be ⅓ to ⅙ of the area occupied by one cell of an SRAM (Static Random Access Memory). This enables the memory cells 150 to be arranged at high density. Thus, a storage device having high storage capacity can be achieved.

In the case where an OS transistor is used as a transistor included in a memory cell, the memory cell can be referred to as an “OS memory”. In particular, the DRAM OS memory is referred to as a DOSRAM (registered trademark) in some cases. In addition, an FeRAM using an OS transistor as a transistor included in a memory cell is referred to as an FeDOSRAM in some cases.

The wiring WL has a function of a word line, and the on state and off state of the transistor M can be controlled by controlling the potential of the wiring WL. For example, in the case where the transistor M is an n-channel transistor, the potential of the wiring WL is set to a high potential so that the transistor M can be turned on, while the potential of the wiring WL is set to a low potential so that the transistor M can be turned off.

The wiring BL has a function of a bit line, and the potential of the wiring BL is supplied to one electrode of the capacitor Cfe when the transistor M is in an on state.

The wiring PL functions as a plate line. A potential is supplied to the other electrode of the capacitor Cfe through the wiring PL.

### <Hysteresis Characteristics of Ferroelectric Layer>

A ferroelectric layer included in the capacitor Cfe has hysteresis characteristics. FIG. 13B is a graph showing an example of the hysteresis characteristics. The horizontal axis in FIG. 13B represents the voltage applied to the ferroelectric layer. The voltage can be a difference between the potential of one electrode of the capacitor Cfe and the potential of the other electrode of the capacitor Cfe, for example.

In FIG. 13B, the vertical axis represents polarization of the ferroelectric layer; a positive value indicates that positive charges are concentrated on one electrode side of the capacitor Cfe and negative charges are concentrated on the other electrode side of the capacitor Cfe. On the other hand, a negative value of the polarization indicates that positive charges are concentrated on the other electrode side of the capacitor Cfe and negative charges are concentrated on the one electrode side of the capacitor Cfe.

Note that the voltage represented by the horizontal axis of the graph in FIG. 13B may be a difference between the potential of the other electrode of the capacitor Cfe and the potential of the one electrode of the capacitor Cfe. Furthermore, the polarization represented by the vertical axis of the graph in FIG. 13B may be a positive value in the case where positive charges are concentrated on the other electrode side of the capacitor Cfe and negative charges are concentrated on the one electrode side of the capacitor Cfe, and may be a negative value in the case where positive charges are concentrated on the one electrode side of the capacitor Cfe and negative charges are concentrated on the other electrode side of the capacitor Cfe.

As shown in FIG. 13B, the hysteresis characteristics of the ferroelectric layer can be represented by a curve 51 and a curve 52. The voltages at the intersecting points between the curve 51 and the curve 52 are VSP and VSP. The polarities of VSP and −VSP can be said to be different.

When the voltage applied to the ferroelectric layer is increased after a voltage lower than or equal to −VSP is applied to the ferroelectric layer, the polarization of the ferroelectric layer is increased along the curve 51. On the other hand, when the voltage applied to the ferroelectric layer is decreased after a voltage higher than or equal to VSP is applied to the ferroelectric layer, the polarization of the ferroelectric layer is decreased along the curve 52. Thus, VSP and −VSP can each be referred to as a saturation polarization voltage. Note that VSP is referred to as a first saturation polarization voltage and −VSP is referred to as a second saturation polarization voltage in some cases. In addition, the absolute values of the first saturation polarization voltage and the second saturation polarization voltage are equal to each other in FIG. 13B, but may be different from each other.

Here, Vc represents a voltage applied to the ferroelectric layer in the case where the polarization of the ferroelectric layer is 0 in the change of the polarization of the ferroelectric layer along the curve 51. In addition, −Vc represents a voltage applied to the ferroelectric layer in the case where the polarization of the ferroelectric layer is 0 in the change of the polarization of the ferroelectric layer along the curve 52. Vc and −Vc can each be referred to as coercive voltages. The value of Vc and the value of Vc can be said to be values between −VSP and VSP. For example, Vc is referred to as a first coercive voltage and −Vc is referred to as a second coercive voltage in some cases. Although the absolute values of the first coercive voltage and the second coercive voltage are equal to each other in FIG. 13B, they may be different from each other.

The maximum value and the minimum value of polarization when a voltage is not applied to the ferroelectric layer are referred to as “remanent polarization Pr” and “remanent polarization −Pr”, respectively. A difference between the remanent polarization Pr and the remanent polarization −Pr is referred to as “remanent polarization 2Pr”.

As described above, a voltage applied to the ferroelectric layer included in the capacitor Cfe can be expressed by a difference between the potential of one electrode of the capacitor Cfe and the potential of the other electrode of the capacitor Cfe. As described above, the other electrode of the capacitor Cfe is electrically connected to the wiring PL. Thus, by controlling the potential of the wiring PL, the voltage applied to the ferroelectric layer included in the capacitor Cfe can be controlled.

An example of a method of driving the memory cell 150 is described. In the following description, the voltage applied to the ferroelectric layer of the capacitor Cfe indicates a potential difference between the potential of one electrode of the capacitor Cfe and the potential of the other electrode of the capacitor Cfe (the wiring PL). In addition, the transistor M is an n-channel transistor.

FIG. 13C is a timing chart showing an example of a driving method of the memory cell 150. FIG. 13C shows an example of writing and reading 2-bit digital data in and out of the memory cell 150. Specifically, in FIG. 13C, data “1” is written in the memory cell 150 from Time T01 to Time T02; the data “1” is read out and rewritten from Time T03 to Time T05; the data “1” is read out, and data “0” is written in the memory cell 150 from Time T11 to Time T13; the data “0” is read out and rewritten from Time T14 to Time T16; and the data “0” is read out and data “1” is written in the memory cell 150 from Time T17 to Time T19.

A sense amplifier electrically connected to the wiring BL is supplied with Vref as a reference potential. In the readout operation shown in FIG. 13C or the like, when the potential of the wiring BL is higher than Vref, data “1” is read out by a bit line driver circuit. In contrast, when the potential of the wiring BL is lower than Vref, data “0” is read out by the bit line driver circuit.

From Time T01 to Time T02, the potential of the wiring WL is set to a high potential (H). Thus, the transistor M is turned on. In addition, the potential of the wiring BL is set to Vw. Since the transistor M is in an on state, the potential of one electrode of the capacitor Cfe becomes Vw. In addition, the potential of the wiring PL is set to GND. Accordingly, the voltage applied to the ferroelectric layer of the capacitor Cfe becomes “Vw-GND”. This allows data “1” to be written in the memory cell 150. Thus, the period from Time T01 to Time T02 can be referred to as a write operation period.

Here, Vw is preferably higher than or equal to VSP, and is preferably equal to VSP, for example. In this specification and the like, GND can be set to a ground potential, but is not necessarily a ground potential as long as the memory cell 150 can be driven so as to achieve an object of one embodiment of the present invention. For example, when the absolute value of the first saturation polarization voltage is different from the absolute value of the second saturation polarization voltage, and the absolute value of the first coercive voltage is different from the absolute value of the second coercive voltage, GND can be a potential other than a ground.

From Time T02 to Time T03, the potential of the wiring BL and the potential of the wiring PL are set to GND. Accordingly, the voltage applied to the ferroelectric layer of the capacitor Cfe becomes 0 V. The voltage “Vw-GND” applied to the ferroelectric layer of the capacitor Cfe from Time T01 to Time T02 can be higher than or equal to VSP, and thus the polarization quantity of the ferroelectric layer of the capacitor Cfe is changed along the curve 52 in FIG. 13B from Time T02 to Time T03. From the above, from Time T02 to Time T03, polarization inversion does not occur in the ferroelectric layer of the capacitor Cfe.

After the potential of the wiring BL and the potential of the wiring PL are set to GND, the potential of the wiring WL is set to a low potential (L). Thus, the transistor M is turned off. Through the above steps, the write operation is completed and data “1” is held in the memory cell 150. Note that the potentials of the wiring BL and the wiring PL can be any potentials as long as polarization inversion does not occur in the ferroelectric layer of the capacitor Cfe, i.e., the voltage applied to the ferroelectric layer of the capacitor Cfe is higher than or equal to −Vc as the second coercive voltage.

From Time T03 to Time T04, the potential of the wiring WL is set to a high potential. Thus, the transistor M is turned on. The potential of the wiring PL is set to Vw. By setting the potential of the wiring PL to Vw, the voltage applied to the ferroelectric layer of the capacitor Cfe becomes “GND-Vw”. As described above, from Time T01 to Time T02, the voltage applied to the ferroelectric layer of the capacitor Cfe is “Vw-GND”. Thus, polarization inversion occurs in the ferroelectric layer of the capacitor Cfe. At the time of the polarization inversion, a current flows through the wiring BL, and the potential of the wiring BL becomes higher than Vref. Thus, the bit line driver circuit can read out the data “1” held in the memory cell 150. Accordingly, the period from Time T03 to Time T04 can be referred to as a readout operation period. Note that Vref is higher than GND and lower than Vw but may be higher than Vw, for example.

Since the above readout is destructive readout, the data “1” held in the memory cell 150 is lost. Thus, from Time T04 to Time T05, the potential of the wiring BL is set to Vw and the potential of the wiring PL is set to GND. Thus, data “1” is rewritten in the memory cell 150. Consequently, the period from Time T04 to Time T05 can be referred to as a rewrite operation period.

From Time T05 to Time T11, the potential of the wiring BL and the potential of the wiring PL are set to GND. After that, the potential of the wiring WL is set to a low potential. Through the above steps, the rewrite operation is completed, and the data “1” is held in the memory cell 150.

From Time T11 to Time T12, the potential of the wiring WL is set to a high potential and the potential of the wiring PL is set to Vw. Since the data “1” is held in the memory cell 150, the potential of the wiring BL is higher than Vref and the data “1” held in the memory cell 150 is read out. Thus, the period from Time T11 to Time T12 can be referred to as a readout operation period.

From Time T12 to Time T13, the potential of the wiring BL is set to GND. Since the transistor M is in an on state, the potential of one electrode of the capacitor Cfe becomes GND. The potential of the wiring PL is set to Vw. In the above manner, the voltage applied to the ferroelectric layer of the capacitor Cfe becomes to be “GND-Vw”. As a result, data “0” can be written in the memory cell 150. Thus, the period from Time T12 to Time T13 can be referred to as a write operation period.

From Time T13 to Time T14, the potential of the wiring BL and the potential of the wiring PL are set to GND. Accordingly, the voltage applied to the ferroelectric layer of the capacitor Cfe becomes 0 V. The voltage “GND-Vw” applied to the ferroelectric layer of the capacitor Cfe from Time T12 to Time T13 can be set to be −VSP or lower; thus, the polarization quantity of the ferroelectric layer of the capacitor Cfe is changed along the curve 51 in FIG. 13B from Time T13 to Time T14. From the above, from Time T13 to Time T14, polarization inversion does not occur in the ferroelectric layer of the capacitor Cfe.

After the potential of the wiring BL and the potential of the wiring PL are set to GND, the potential of the wiring WL is set to a low potential. Thus, the transistor M is turned off. Through the above steps, the write operation is completed and data “0” is held in the memory cell 150. Note that the potentials of the wiring BL and the wiring PL can be any potentials as long as polarization inversion does not occur in the ferroelectric layer of the capacitor Cfe, i.e., the voltage applied to the ferroelectric layer of the capacitor Cfe is lower than or equal to Vc as the first coercive voltage.

From Time T14 to Time T15, the potential of the wiring WL is set to a high potential. Thus, the transistor M is turned on. The potential of the wiring PL is set to Vw. By setting the potential of the wiring PL to Vw, the voltage applied to the ferroelectric layer of the capacitor Cfe becomes “GND-Vw”. As described above, the voltage applied to the capacitor layer of the capacitor Cfe from Time T12 to Time T13 is “GND-Vw”. Thus, polarization inversion does not occur in the ferroelectric layer of the capacitor Cfe. Consequently, the amount of current flowing through the wiring BL is smaller than that in the case where the polarization inversion occurs in the ferroelectric layer of the capacitor Cfe. Accordingly, the increase amount in the potential of the wiring BL is smaller than that in the case where the polarization inversion occurs in the ferroelectric layer of the capacitor Cfe; specifically, the potential of the wiring BL becomes lower than or equal to Vref. Thus, the bit line driver circuit can read out the data “0” held in the memory cell 150. Accordingly, the period from Time T14 to Time T15 can be referred to as a readout operation period.

From Time T15 to Time T16, the potential of the wiring BL is set to GND and the potential of the wiring PL is set to Vw. Thus, data “0” is rewritten in the memory cell 150. Accordingly, the period from Time T15 to Time T16 can be referred to as a rewrite operation period.

From Time T16 to Time T17, the potential of the wiring BL and the potential of the wiring PL are set to GND. After that, the potential of the wiring WL is set to a low potential. Through the above steps, the rewrite operation is completed, and the data “0” is held in the memory cell 150.

From Time T17 to Time T18, the potential of the wiring WL is set to a high potential and the potential of the wiring PL is set to Vw. Since the data “0” is held in the memory cell 150, the potential of the wiring BL becomes lower than Vref and the data “0” held in the memory cell 150 is read out. Thus, the period from Time T17 to Time T18 can be referred to as a readout operation period.

The potential of the wiring BL is set to Vw from Time T18 to Time T19. Since the transistor M is in an on state, the potential of one electrode of the capacitor Cfe becomes Vw. The potential of the wiring PL is set to GND. Accordingly, the voltage applied to the ferroelectric layer of the capacitor Cfe becomes “Vw-GND”. As a result, data “1” can be written in the memory cell 150. Thus, the period from Time T18 to Time T19 can be referred to as a write operation period.

After Time T19, the potential of the wiring BL and the potential of the wiring PL are set to GND. After that, the potential of the wiring WL is set to a low potential. Through the above steps, the write operation is completed and the data “1” is held in the memory cell 150.

The memory cell 150 including the ferroelectric layer in the capacitor Cfe functions as a nonvolatile storage element that can hold information written therein even when power supply is stopped.

A DRAM requires regular refresh operation and thus increases power consumption. The memory cell 150 that includes the capacitor Cfe including a ferroelectric layer does not require refresh operation and thus can have low power consumption.

In this specification and the like, a storage element including a ferroelectric layer or a storage circuit including a ferroelectric layer is referred to as a “ferroelectric memory” or an “FE memory” in some cases. Thus, the memory cell 150 is a ferroelectric memory and is also an FE memory. The FE memory can be expected to achieve the number of rewrite cycles of 1×10¹⁰ or more, preferably 1×10¹² or more, further preferably 1×10¹⁵ or more. The FE memory can be expected to achieve an operation frequency of greater than or equal to 10 MHz, preferably greater than or equal to 1 GHz.

In the FE memory, the remanent polarization 2Pr and data holding capability have a correlation: as the remanent polarization 2Pr becomes smaller, the data holding capability declines. In this specification and the like, a period over which the remanent polarization 2Pr is reduced by 5% (the data holding capability declines by 5%) is referred to as a “memory holding period”. The FE memory can be expected to have a memory holding period of ten days or longer, preferably one year or longer, further preferably ten years or longer at a temperature environment of 150° C. or 200° C.

The FE memory can also be applied to a cache memory and a register in a CPU, a GPU (Graphics Processing Unit), and the like. An Noff-CPU (Normally off CPU) can be obtained by a combination of the FE memory with a cache memory and a register in a CPU. An Noff-GPU (Normally off GPU) can be obtained by a combination of the FE memory with a cache memory and a register in a GPU.

This embodiment can be combined as appropriate with any of the other embodiments and the like described in this specification.

### Embodiment 3

In this embodiment, a structure example of the storage device 300 using the semiconductor device of one embodiment of the present invention will be described.

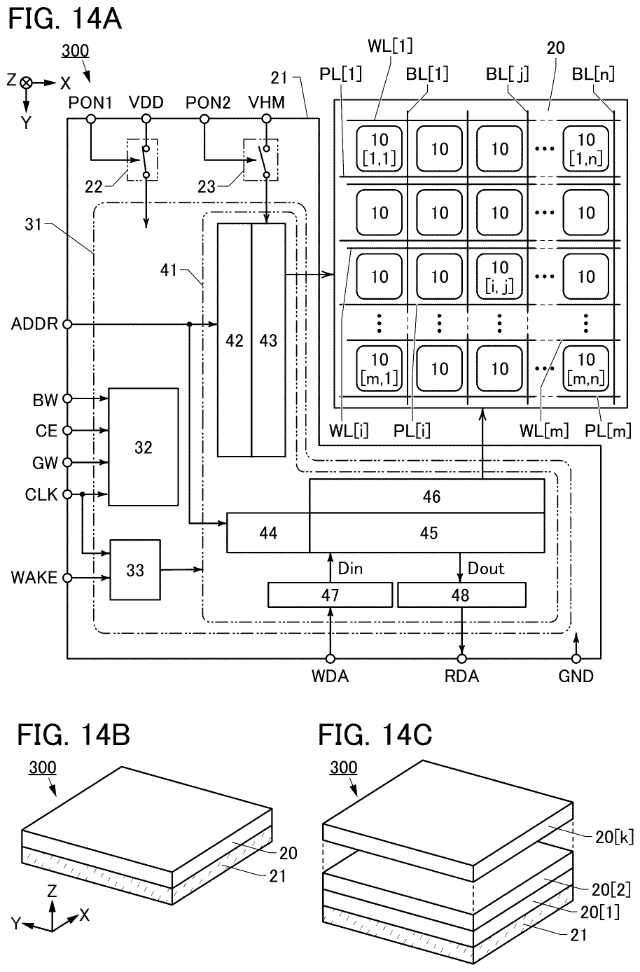

FIG. 14A is a block diagram illustrating a structure example of the storage device 300 of one embodiment of the present invention. The storage device 300 illustrated in FIG. 14A includes a driver circuit 21 and a memory array 20. The memory array 20 includes a plurality of semiconductor devices 10. FIG. 14A illustrates an example in which the memory array 20 includes the plurality of semiconductor devices 10 arranged in a matrix of m rows and n columns (m and n each independently represent an integer greater than or equal to 2). The semiconductor device 10 can correspond to the memory cell 150 described in Embodiment 2.

Note that the rows and the columns extend in directions orthogonal to each other. In this embodiment, the X direction is referred to as a “row” and the Y direction is referred to as a “column”, but the X direction may be referred to as a “column” and the Y direction may be referred to as a “row”.

In FIG. 14A, the semiconductor device 10 in the first row and the first column is denoted as a semiconductor device 10[1, 1] and the semiconductor device 10 in the m-th row and the n-th column is denoted as a semiconductor device 10[m, n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the semiconductor device 10 in the i-th row and the j-th column is denoted as a semiconductor device 10[i, j]. Note that in this embodiment and the like, “i+α” (α is a positive or negative integer) is not below 1 and does not exceed m. Similarly, “j+α” is not below 1 and does not exceed n.

The memory array 20 includes m wirings WL extending in the row direction (X direction), m wirings PL extending in the row direction (X direction), and n wirings BL extending in the Z direction. Note that although the n wirings BL extend in the Z direction, FIG. 14A illustrates the n wirings BL extending in the column direction (Y direction) so as to clearly show the relationship between the wirings WL, the wirings PL, and the wirings BL.

In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[l] and an n-th (n-th column) wiring BL is referred to as a wiring BL[n].

The plurality of semiconductor devices 10 provided in the i-th row are electrically connected to the wiring WL in the i-th row (wiring WL[i]) and the wiring PL in the i-th row (wiring PL[i]). The plurality of semiconductor devices 10 provided in the j-th column are electrically connected to the wiring BL in the j-th column (wiring BL[j]).

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the storage device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the storage device 300. For example, the control circuit performs a logical operation on the signal CE, the signal GW, and the signal BW to determine an operation mode (e.g., a writing operation or a reading operation) of the storage device 300. Alternatively, the control circuit 32 generates a control signal for the peripheral circuit 41 so that the operation mode is executed.

The voltage generation circuit 33 has a function of generating a voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a voltage.

The peripheral circuit 41 is a circuit for writing and reading data to/from the semiconductor devices 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the semiconductor devices 10, a function of reading data from the semiconductor devices 10, a function of retaining the read data, and the like.

The input circuit 47 has a function of retaining the signal WDA. Data retained by the input circuit 47 is output to the column driver 45. Data output from the input circuit 47 is data (Din) to be written to the semiconductor devices 10. Data (Dout) read from the semiconductor devices 10 by the column driver 45 is output to the output circuit 48. The output circuit 48 has a function of retaining Dout. In addition, the output circuit 48 has a function of outputting Dout to the outside of the storage device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the storage device 300, a high power supply potential is VDD and a low power supply potential is GND (a ground potential). In addition, VHM is a high power supply potential used to set a word line at a high level and is higher than VDD. The on/off of the PSW 22 is controlled by the signal PON1, and the on/off of the PSW 23 is controlled by the signal PON2. The number of power domains to which VDD is supplied is one in the peripheral circuit 31 in FIG. 14A but can be more than one. In this case, a power switch is provided for each power domain.

The driver circuit 21 and the memory array 20 may be provided on the same plane. As illustrated in FIG. 14B, a layer including the memory array 20 may be provided directly over a layer including the driver circuit 21. When the driver circuit 21 and the memory array 20 are provided to overlap with each other, the signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the storage device 300 can be downsized.

In FIG. 14B, one layer of the memory array 20 is provided to overlap with the driver circuit 21; however, two or more layers of the memory arrays 20 may be provided to overlap with the driver circuit 21. FIG. 14C illustrates an example in which k layers (k is an integer greater than or equal to 2) of the memory arrays 20 are provided to overlap with the driver circuit 21. In FIG. 14C and the like, the memory array 20 provided in the first layer is denoted as a memory array 20[1], the memory array 20 provided in the second layer is denoted as a memory array 20[2], and the memory array 20 provided in the k-th layer is denoted as a memory array 20[k].

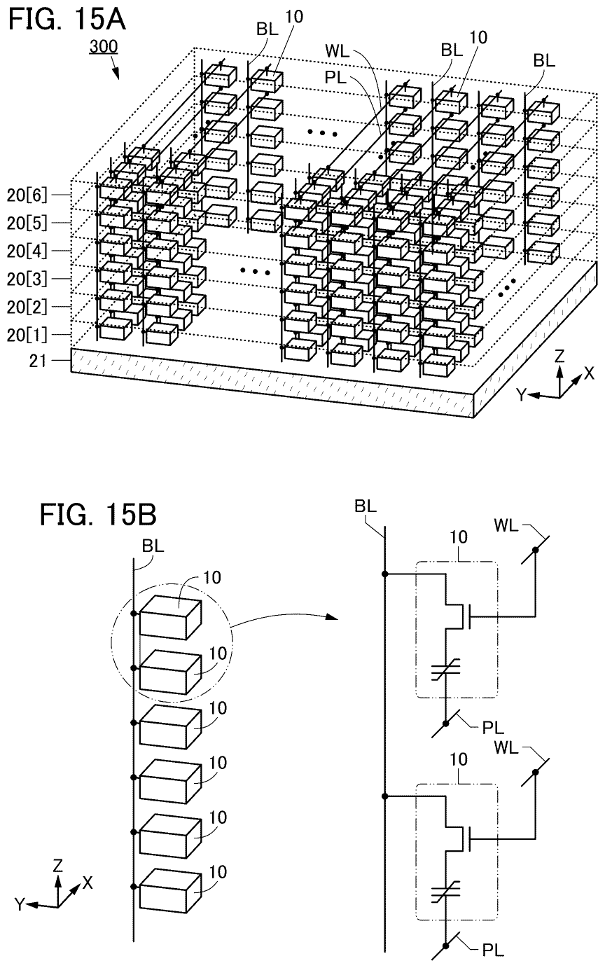

FIG. 15A is a schematic diagram illustrating a structure example of the storage device 300. The storage device 300 illustrated in FIG. 15A includes six layers of the memory arrays 20 provided over the driver circuit 21. As described above, in FIG. 15A and the like, the memory array 20 provided in the third layer is denoted as a memory array 20[3], the memory array 20 provided in the fourth layer is denoted as a memory array 20[4], the memory array 20 provided in the fifth layer is denoted as a memory array 20[5], and the memory array 20 provided in the sixth layer is denoted as a memory array 20[6].

Each layer of the memory array 20 includes a plurality of semiconductor devices 10 arranged in a matrix, and the wiring WL and the wiring PL extending in the X direction. For easy viewing of the drawing, the wirings WL and the wirings PL included in the memory arrays in the first to fifth layers are not illustrated.

The storage device 300 illustrated in FIG. 15A includes a plurality of wirings BL extending in the Z direction. The wiring BL is formed to pass through the six layers of the memory arrays 20 and is electrically connected to the driver circuit 21. When seen from the Z direction, the plurality of wirings BL are arranged in a matrix.

When the wiring BL is extended in the Z direction to be electrically connected to the driver circuit 21, the connection distance between the semiconductor devices 10 and the driver circuit 21 can be shorter than that in the case where the wiring BL is extended in the X direction or the Y direction. Consequently, the signal transmission distance between the semiconductor devices 10 and the driver circuit 21 can be shortened, which can increase the operation speed of the storage device. Moreover, parasitic capacitance due to the wiring BL is reduced, leading to lower power consumption.

In each layer of the memory array 20, one of the plurality of semiconductor devices 10 included in the memory array 20 is electrically connected to one of the plurality of wirings BL. Thus, in the storage device 300 illustrated in FIG. 15A, each wiring BL is electrically connected to one semiconductor device 10 of each layer of the memory array 20, i.e., six semiconductor devices 10 in total.

A configuration in which a plurality of memory cells (semiconductor devices 10) are electrically connected to one wiring BL is also referred to as “memory string”. Thus, it can be said that the storage device 300 illustrated in FIG. 15A includes a plurality of memory strings.

FIG. 15B is a schematic diagram of a memory string included in the storage device 300 illustrated in FIG. 15A. For easy viewing of the drawing, the wirings WL and the wirings PL electrically connected to the semiconductor devices 10 are not illustrated in the schematic diagram of a memory string in FIG. 15B. In addition, part of an equivalent circuit of the memory string is illustrated in FIG. 15B.

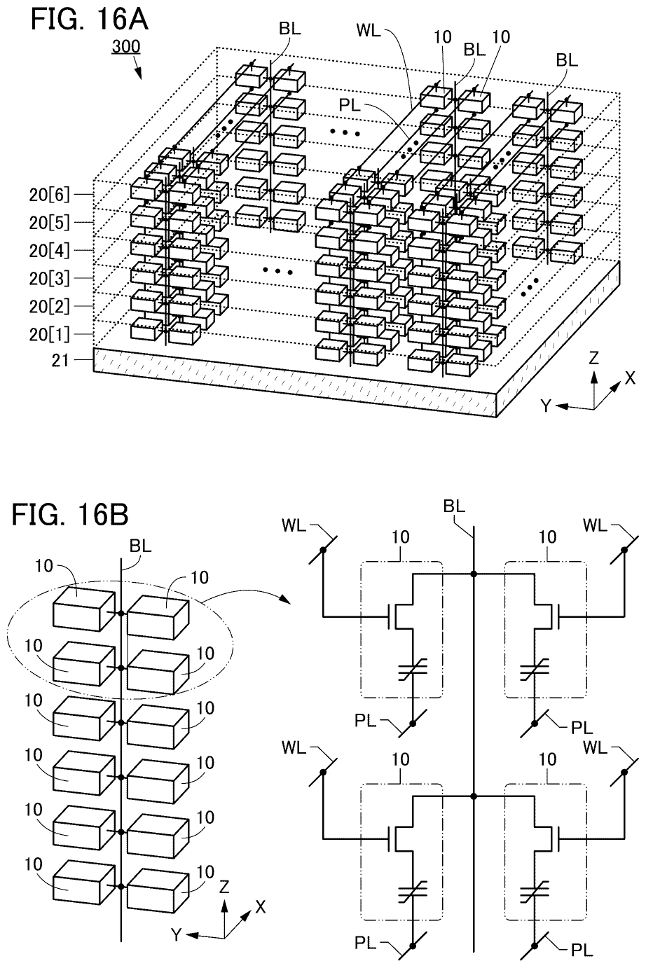

FIG. 16A is a schematic diagram illustrating a structure example of the storage device 300. The storage device 300 illustrated in FIG. 16A is a modification example of the storage device 300 illustrated in FIG. 15A. Thus, differences from the storage device 300 illustrated in FIG. 15A are mainly described in order to reduce repeated description.

The storage device 300 illustrated in FIG. 16A is different from the storage device 300 illustrated in FIG. 15A in that two of the plurality of semiconductor devices 10 included in each layer of the memory array 20 are electrically connected to one of the plurality of wirings BL. That is, 12 semiconductor devices 10 in total are electrically connected to one wiring BL.

FIG. 16B is a schematic diagram of a memory string included in the storage device 300 illustrated in FIG. 16A. In addition, part of an equivalent circuit of the memory string is illustrated in FIG. 16B.

In the storage device 300 illustrated in FIG. 16A, the number of wirings BL can be smaller than that in the storage device 300 illustrated in FIG. 15A. Thus, the area occupied by the storage device 300 is reduced.

The semiconductor device 10 of one embodiment of the present invention is an FE memory, and can retain written information for a long time even when power supply is stopped. Since refresh operation required by a DRAM is unnecessary, the storage device 300 with low power consumption can be achieved.

This embodiment can be combined as appropriate with any of the other embodiments and the like described in this specification.

### Embodiment 4

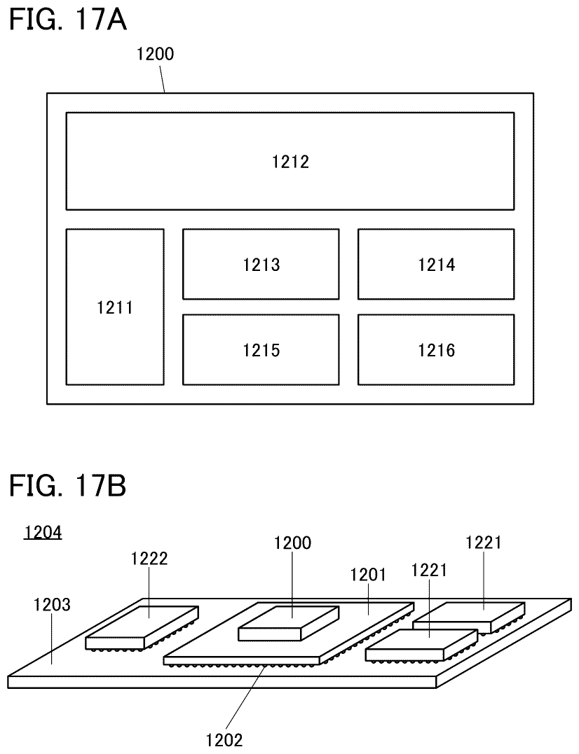

In this embodiment, an example of a chip 1200 on which the semiconductor device of one embodiment of the present invention is mounted is described with reference to FIG. 17A and FIG. 17B. A plurality of circuits (systems) are mounted on the chip 1200. A technique for integrating a plurality of circuits (systems) into one chip is referred to as system on chip (SoC) in some cases.

As illustrated in FIG. 17A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 17B, the chip 1200 is connected to a first surface of a package board 1201. In addition, a plurality of bumps 1202 are provided on a rear surface of a first surface of the package board 1201, and the package board 1201 is connected to a motherboard 1203.

Storage devices such as a storage device 1221 and a flash memory 1222 may be provided over the motherboard 1203. For example, the semiconductor device 10 can be used as the storage device 1221. Alternatively, the semiconductor device 10 may be used instead of the flash memory 1222, for example.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The semiconductor device can be used as the memory. Moreover, the GPU 1212 is suitable for parallel computation of a number of data and thus can be used for image processing or product-sum operation. When an image processing circuit or a product-sum operation circuit including an oxide semiconductor is provided in the GPU 1212, image processing or product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the storage device 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be fabricated at low cost.

The motherboard 1203 provided with the package board 1201 on which the chip 1200 including the GPU 1212 is mounted, the storage devices 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined as appropriate with any of the other embodiments and the like described in this specification.

### Embodiment 5

In this embodiment, examples of electronic components in which the semiconductor device or the like described in the above embodiment is incorporated will be described.

### <Electronic Component>

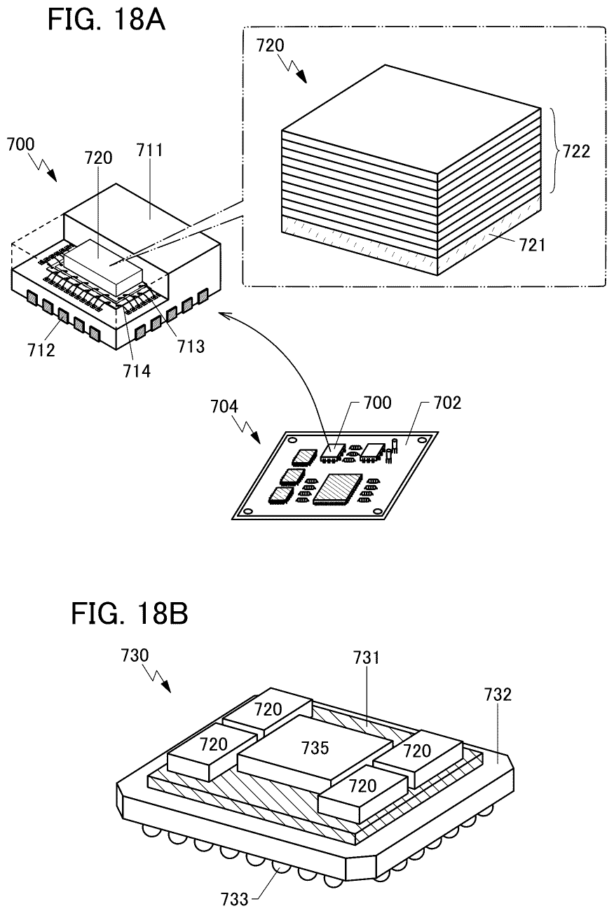

FIG. 18A is a perspective view of an electronic component 700 and a substrate (circuit board 704) on which the electronic component 700 is mounted. The electronic component 700 illustrated in FIG. 18A includes a storage device 720 in a mold 711. FIG. 18A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the circuit board 704.

The storage device 720 includes a driver circuit layer 721 and a storage circuit layer 722. The storage device 300 of one embodiment of the present invention can be used as the storage device 720. Thus, the driver circuit layer 721 can be referred to as a layer including the driver circuit 21. In addition, a single layer or a plurality of layers of the memory array 20 can be used as the storage circuit layer 722. Thus, the driver circuit layer 721 can be referred to as a layer including the memory array 20.

FIG. 18B is a perspective view of an electronic component 730. The electronic component 730 is an example of a SiP (System in package) or an MCM (Multi Chip Module). In the electronic component 730, an interposer 731 is provided over a package board 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA (Field Programmable Gate Array) can be used as the semiconductor device 735.

As the package board 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package board 732. Accordingly, the interposer is sometimes referred to as a “redistribution substrate” or an “intermediate substrate”. A through electrode may be provided in the interposer 731 to be used for electrically connecting the integrated circuit and the package board 732. In the case of using a silicon interposer, a TSV (Through Silicon Via) can also be used as the through electrode.

A silicon interposer is preferably used as the interposer 731. The silicon interposer can be fabricated at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, integrated circuits provided on the interposer 731 are preferably level with each other. In the electronic component 730 of this embodiment, the storage device 720 and the semiconductor device 735 are preferably level with each other, for example.

An electrode 733 may be provided on the bottom portion of the package board 732 to mount the electronic component 730 on another substrate. FIG. 18B illustrates an example in which the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

This embodiment can be combined as appropriate with any of the other embodiments and the like described in this specification.

### Embodiment 6

In this embodiment, application examples of the semiconductor device of one embodiment of the present invention will be described.

The semiconductor device of one embodiment of the present invention can be applied to, for example, storage devices of a variety of electronic devices (e.g., information terminals, computers, smartphones, e-book readers, digital still cameras, video cameras, video recording/reproducing devices, navigation systems, game machines, and the like). In addition, the semiconductor device can also be used for image sensors, IoT (Internet of Things), healthcare-related devices, and the like. Note that here, the computers refer not only to tablet computers, laptop computers, and desktop computers, but also to large computers such as server systems.

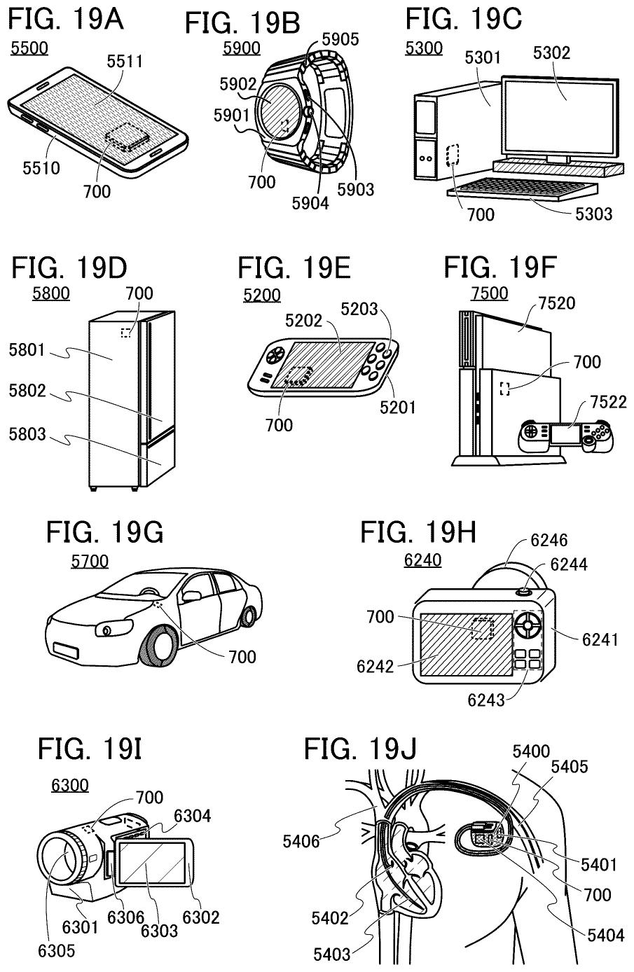

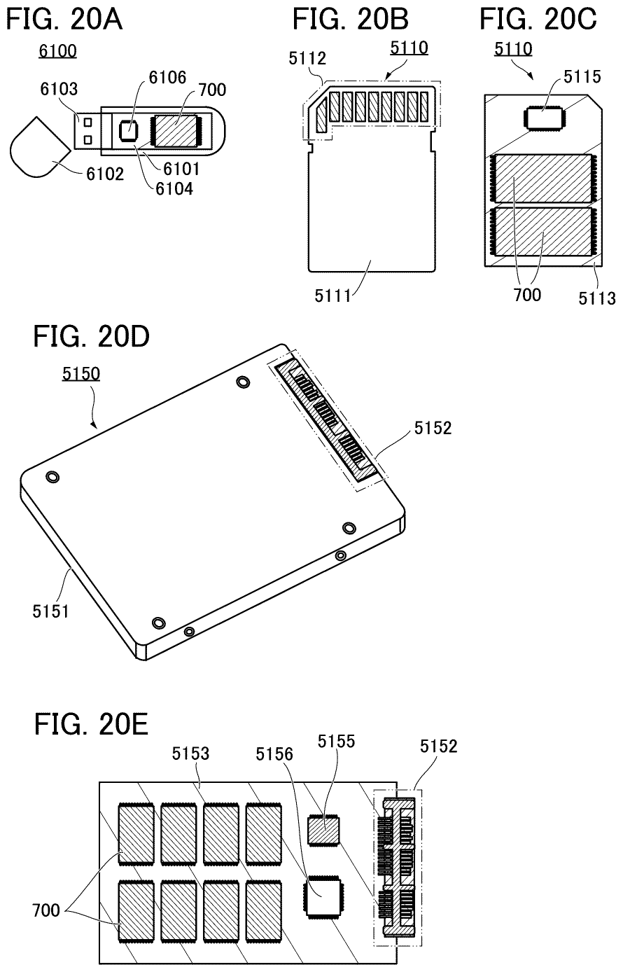

An example of an electronic device including the semiconductor device of one embodiment of the present invention is described. Note that FIG. 19A to FIG. 19J and FIG. 20A to FIG. 20E each illustrate a state where the electronic component 700 or the electronic component 730, each of which includes the semiconductor device, is included in an electronic device.

### [Cellular Phone]

An information terminal 5500 illustrated in FIG. 19A is a cellular phone (smartphone), which is a type of information terminal. The information terminal 5500 includes a housing 5510 and a display portion 5511, and as input interfaces, a touch panel is provided in the display portion 5511 and a button is provided in the housing 5510.

By applying the semiconductor device of one embodiment of the present invention to the information terminal 5500, the information terminal 5500 can retain a temporary file generated at the time of executing an application (e.g., a web browser's cache or the like).

### [Wearable Terminal]

FIG. 19B illustrates an information terminal 5900 that is an example of a wearable terminal. The information terminal 5900 includes a housing 5901, a display portion 5902, an operation switch 5903, an operation switch 5904, a band 5905, and the like.

Like the information terminal 5500 described above, the wearable terminal can retain a temporary file generated at the time of executing an application by applying the semiconductor device of one embodiment of the present invention to the wearable terminal.

### [Information Terminal]

FIG. 19C illustrates a desktop information terminal 5300. The desktop information terminal 5300 includes a main body 5301 of the information terminal, a display portion 5302, and a keyboard 5303.

Like the information terminal 5500 described above, the desktop information terminal 5300 can retain a temporary file generated at the time of executing an application by applying the semiconductor device of one embodiment of the present invention to the desktop information terminal 5300.

Note that although the smartphone, the wearable terminal, and the desktop information terminal are respectively illustrated in FIG. 19A to FIG. 19C as examples of the electronic device, one embodiment of the present invention can be applied to an information terminal other than a smartphone, a wearable terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 19D illustrates an electric refrigerator-freezer 5800 as an example of a household appliance. The electric refrigerator-freezer 5800 includes a housing 5801, a refrigerator door 5802, a freezer door 5803, and the like. For example, the electric refrigerator-freezer 5800 is an electric refrigerator-freezer that is compatible with IoT (Internet of Things).

The semiconductor device of one embodiment of the present invention can be applied to the electric refrigerator-freezer 5800. The electric refrigerator-freezer 5800 can transmit and receive information on food stored in the electric refrigerator-freezer 5800 and food expiration dates, for example, to and from an information terminal or the like via the Internet or the like. In the electric refrigerator-freezer 5800, the semiconductor device can retain a temporary file generated at the time of transmitting the information.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 19E illustrates a portable game machine 5200 as an example of a game machine. The portable game machine 5200 includes a housing 5201, a display portion 5202, a button 5203, and the like.

FIG. 19F illustrates a stationary game machine 7500 as another example of a game machine. The stationary game machine 7500 includes a main body 7520 and a controller 7522. Note that the controller 7522 can be connected to the main body 7520 with or without a wire. Although not illustrated in FIG. 19F, the controller 7522 can include a display portion that displays a game image, and an input interface besides a button, such as a touch panel, a stick, a rotating knob, and a sliding knob, for example. Moreover, the shape of the controller 7522 is not limited to that illustrated in FIG. 19F, and the shape of the controller 7522 may be changed in various ways in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using a gesture or a voice instead of a controller.

In addition, videos displayed on the game machine can be output with a display device such as a television device, a computer display, a game display, or a head-mounted display.

The semiconductor device described in the above embodiment is employed for the portable game machine 5200 or the stationary game machine 7500, so that the portable game machine 5200 with low power consumption or the stationary game machine 7500 with low power consumption can be achieved. Moreover, heat generation from a circuit can be reduced owing to low power consumption; thus, the influence of heat generation on the circuit itself, a peripheral circuit, and a module can be reduced.

Moreover, the semiconductor device described in the above embodiment is employed for the portable game machine 5200 or the stationary game machine 7500, so that it is possible to retain a temporary file necessary for arithmetic operation that occurs during game play.

As an example of a game machine, FIG. 19E illustrates a portable game machine. In addition, FIG. 19F illustrates a home-use stationary game machine. Note that an electronic device of one embodiment of the present invention is not limited thereto. Examples of the electronic device of one embodiment of the present invention include an arcade game machine installed in entertainment facilities (a game center, an amusement park, and the like), a throwing machine for batting practice installed in sports facilities, and the like.

### [Moving Vehicle]

The semiconductor device described in the above embodiment can be used for a motor vehicle, which is a moving vehicle, and around the driver's seat in a motor vehicle.

FIG. 19G illustrates a motor vehicle 5700 as an example of a moving vehicle.

An instrument panel that provides various kinds of information by displaying a speedometer, a tachometer, a mileage, a fuel meter, a gearshift state, air-conditioning settings, and the like is provided around the driver's seat in the motor vehicle 5700. In addition, a display device showing the above information may be provided around the driver's seat.

In particular, the display device can compensate for the view obstructed by a pillar or the like, blind areas for the driver's seat, and the like by displaying a video from an imaging device (not illustrated) provided for the motor vehicle 5700, which can increase safety. That is, display of an image from an imaging device provided on the outside of the motor vehicle 5700 can fill in blind areas and increase safety.

The semiconductor device described in the above embodiment can temporarily retain information; thus, the semiconductor device can be used to retain temporary information necessary in a system conducting automatic driving, navigation, and risk prediction for the motor vehicle 5700, for example. The display device may be configured to display temporary information regarding navigation, risk prediction, or the like. Moreover, the semiconductor device may be configured to retain a video of a driving recorder provided in the motor vehicle 5700.

Note that although a motor vehicle is described above as an example of a moving vehicle, the moving vehicle is not limited to a motor vehicle. Examples of moving vehicles include a train, a monorail train, a ship, and a flying object (a helicopter, an unmanned aircraft (a drone), an airplane, and a rocket).

### [Camera]

The semiconductor device described in the above embodiment can be employed for a camera.

FIG. 19H illustrates a digital camera 6240 as an example of an imaging device. The digital camera 6240 includes a housing 6241, a display portion 6242, operation switches 6243, a shutter button 6244, and the like, and a detachable lens 6246 is attached to the digital camera 6240. Note that here, although the digital camera 6240 is configured such that the lens 6246 is detachable from the housing 6241 for replacement, the lens 6246 may be integrated with the housing 6241. In addition, the digital camera 6240 can be additionally equipped with a stroboscope, a viewfinder, or the like.

When the semiconductor device described in the above embodiment is employed for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The semiconductor device described in the above embodiment can be employed for a video camera.

FIG. 19I illustrates a video camera 6300 as an example of an imaging device. The video camera 6300 includes a first housing 6301, a second housing 6302, a display portion 6303, operation switches 6304, a lens 6305, a joint 6306, and the like. The operation switches 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. With the use of the above semiconductor device, the video camera 6300 can retain a temporary file generated in encoding.

### [ICD]

The semiconductor device described in the above embodiment can be employed for an implantable cardioverter-defibrillator (ICD).

FIG. 19J is a schematic cross-sectional view illustrating an example of an ICD. An ICD main unit 5400 includes at least a battery 5401, the electronic component 700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In addition, in the ICD main unit 5400, data on the heart rate obtained by the sensor or the like, the number of times the treatment with pacing is performed, and the time taken for the treatment, for example, can be stored in the electronic component 700.

The antenna 5404 can receive electric power, and the battery 5401 is charged with the electric power. Furthermore, when the ICD main unit 5400 includes a plurality of batteries, safety can be increased. Specifically, even when some of the batteries in the ICD main unit 5400 are dead, the other batteries can work properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Expansion Device for PC]

The semiconductor device described in the above embodiment can be employed for a calculator such as a PC (Personal Computer) and an expansion device for an information terminal.

FIG. 20A illustrates, as an example of the expansion device, a portable expansion device 6100 that includes a chip capable of storing information and is externally provided on a PC. The expansion device 6100 can store information using the chip when connected to a PC with a USB or the like, for example. Note that FIG. 20A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the semiconductor device or the like described in the above embodiment. For example, the substrate 6104 is provided with the electronic component 700 and a controller chip 6106. The USB connector 6103 functions as an interface for connection to an external device.

### [SD Card]

The semiconductor device described in the above embodiment can be employed for an SD card that can be attached to an electronic device such as an information terminal or a digital camera.

FIG. 20B is a schematic external view of an SD card, and FIG. 20C is a schematic view of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a semiconductor device and a circuit for driving the semiconductor device. For example, the electronic components 700 and a controller chip 5115 are attached to the substrate 5113. Note that the circuit configurations of the electronic components 700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic components 700.

When the electronic components 700 are provided also on a rear surface side of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 700.

### [SSD]

The semiconductor device described in the above embodiment can be employed for an SSD (Solid State Drive) that can be attached to an electronic device such as an information terminal.

FIG. 20D is a schematic external view of an SSD, and FIG. 20E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a storage device and a circuit for driving the storage device. For example, the electronic components 700, a memory chip 5155, and a controller chip 5156 are attached to the substrate 5153. When the electronic components 700 are also provided on a rear surface side of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit configurations of the electronic components 700, the memory chip 5155, and the controller chip 5115 are not limited to those described above, and the circuit configurations can be changed as appropriate according to circumstances. For example, a memory functioning as a work memory may also be provided in the controller chip 5156.

### [Computer]

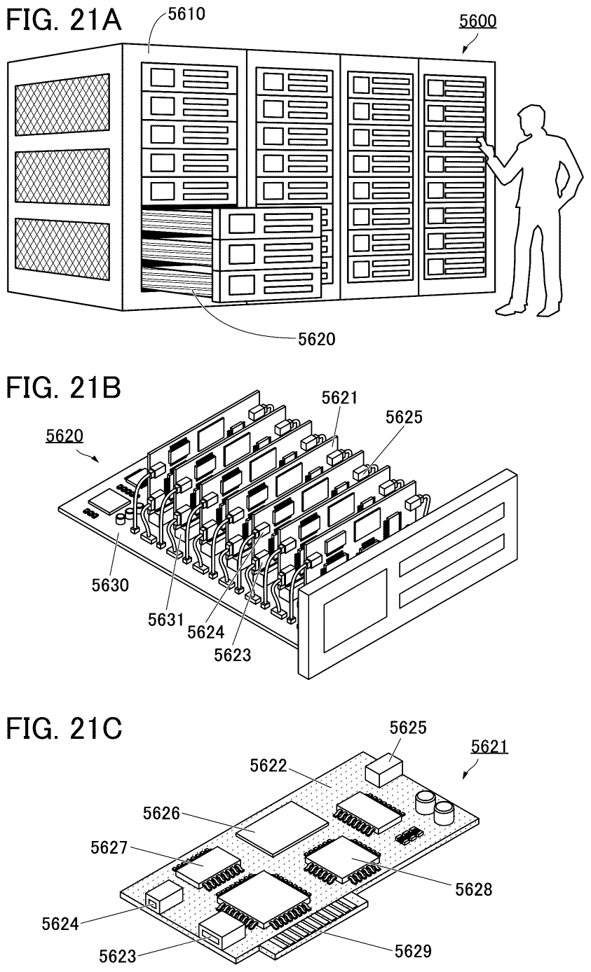

A computer 5600 illustrated in FIG. 21A is an example of a large computer (a supercomputer) mainly used for scientific computation. In scientific computation, an enormous amount of arithmetic operation needs to be processed at high speed; hence, power consumption is high and chips generate a large amount of heat. For example, a data center including a plurality of computers 5600 uses an enormous amount of digital data. Specifically, the amount of digital data in the world is expected to exceed 10²⁴ (yota) bytes or 10³⁰ (quetta) bytes.

When the semiconductor device of one embodiment of the present invention is employed for the computer 5600, a supercomputer with low power consumption can be achieved. Moreover, heat generation from a circuit can be reduced owing to low power consumption; thus, the influence of heat generation on the circuit itself, a peripheral circuit, and a module can be reduced. When the semiconductor device of one embodiment of the present invention is employed, a supercomputer with low power consumption can be achieved. This can be expected to reduce the amount of digital data in the world to make a significant contribution to the fight against global warming.

In the computer 5600, a plurality of rack mount computers 5620 are stored in a rack 5610. The computer 5620 can have a structure in a perspective view illustrated in FIG. 21B, for example. In FIG. 21B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 21C is an example of a processing board provided with a CPU, a GPU, a storage device, and the like. The PC card 5621 includes a board 5622. In addition, the board 5622 includes a connection terminal 5623, a connection terminal 5624, a connection terminal 5625, a semiconductor device 5626, a semiconductor device 5627, a semiconductor device 5628, and a connection terminal 5629. Note that FIG. 21C also illustrates semiconductor devices other than the semiconductor device 5626, the semiconductor device 5627, and the semiconductor device 5628, the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a storage device. As the semiconductor device 5628, the electronic component 700 can be used, for example.

The computer 5600 can also function as a parallel computer. When the computer 5600 is used as a parallel computer, large-scale computation necessary for artificial intelligence learning and inference can be performed, for example.

The semiconductor device of one embodiment of the present invention is used in a variety of electronic devices or the like described above, so that a reduction in size and a reduction in power consumption of the electronic device can be achieved. In addition, since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve an electronic device that operates stably even in a high temperature environment. Thus, the reliability of the electronic device can be increased.

This embodiment can be combined as appropriate with any of the other embodiments and the like described in this specification.

### Embodiment 7

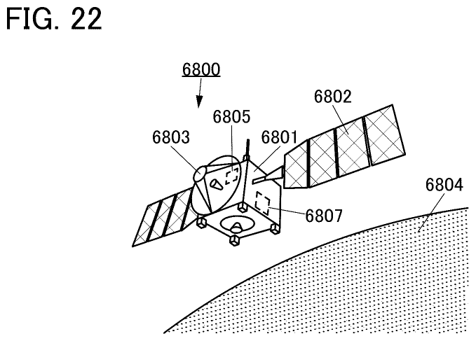

The semiconductor device of one embodiment of the present invention includes an OS transistor. A change in electrical characteristics of the OS transistor due to radiation irradiation is small. That is, the OS transistor is highly resistant to radiation, and thus can be suitably used in an environment where radiation can enter. For example, OS transistors can be suitably used in outer space. In this embodiment, a specific example of using the semiconductor device of one embodiment of the present invention in a device for space will be described with reference to FIG. 22.

FIG. 22 illustrates an artificial satellite 6800 as an example of a device for space. The artificial satellite 6800 includes a body 6801, a solar panel 6802, an antenna 6803, a secondary battery 6805, and a control device 6807. In FIG. 22, a planet 6804 in outer space is illustrated as an example. Note that outer space refers to, for example, space at an altitude greater than or equal to 100 km, and outer space described in this specification can include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device that is one embodiment of the present invention and includes an OS transistor is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, when configured to include a visible light sensor, the artificial satellite 6800 can have a function of sensing sunlight reflected by a ground-based object. Alternatively, when configured to include a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

This embodiment can be combined as appropriate with any of the other embodiments and the like described in this specification.

### Example

In this example, samples including insulating layers were fabricated and the results of evaluating the crystallinity of the insulating layers are described. For the insulating layer, hafnium zirconium oxide (HfZrO_{X} (X is a real number greater than 0)) was used. As described in Embodiment 1, HfZrO_{X} is a material that can have ferroelectricity.

### <Structures and Fabrication Methods of Samples>

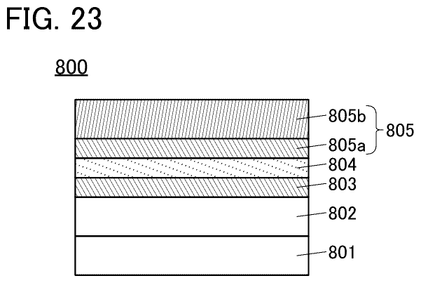

FIG. 23 is a schematic cross-sectional view of Sample 800. Sample 800 includes a substrate 801, an insulating layer 802 over the substrate 801, a conductive layer 803 over the insulating layer 802, an insulating layer 804 over the conductive layer 803, and a conductive layer 805 over the insulating layer 804. The conductive layer 805 has a two-layer structure of a conductive layer 805a and a conductive layer 805b over the conductive layer 805a.

A method for fabricating Sample 800 is described here. As Sample 800, four samples (Sample 800A, Sample 800B, Sample 800C, and Sample 800D) which are different in the formation conditions of the conductive layer 805 and the heat treatment conditions after the formation of the conductive layer 805 were fabricated.

A silicon substrate was prepared as the substrate 801. A 100-nm-thick silicon oxide film was formed by thermal oxidation treatment as the insulating layer 802.

A 20-nm-thick first titanium nitride film was formed by a metal CVD method as the conductive layer 803. In the first titanium nitride film, 50 sccm of titanium chloride (TiCl₄) and 2700 sccm of ammonia (NH₃) were supplied to a reaction chamber of a CVD apparatus, the pressure in the reaction chamber was controlled to be 667 Pa, the distance between the substrate stage and the gas emission stage was 3 mm, and the substrate temperature was 400° C.

As the insulating layer 804, an HfZrO_{X} film with an atomic ratio of Hf:Zr=1:1 was deposited by an ALD method. Note that the thickness of the HfZrO_{X} film was set to 12 nm. Tetrakis(ethylmethylamide)hafnium (TEMAHf) and tetrakis(ethylmethylamide)zirconium (TEMAZr) were used as precursors, and ozone (03) was used as an oxidizer. The deposition temperature was 250° C.

A 5-nm-thick second titanium nitride film was formed by a metal CVD method as the conductive layer 805a. For all of Sample 800A to Sample 800D, the formation conditions of the second titanium nitride film were the same as those of the first titanium nitride film except for the substrate temperature. The substrate temperatures in formation of the second titanium nitride film were 400° C., 340° C., 300° C., and 300° C. in Sample 800A, Sample 800B, Sample 800C, and Sample 800D, respectively.

A 30-nm-thick tungsten film was formed by a metal CVD method as the conductive layer 805b. For all of Sample 800A to Sample 800D, the tungsten film was formed in three steps.

In the first step, part of the tungsten film was formed in such a manner that the deposition gas flow rates of tungsten hexafluoride, silane, argon, and nitrogen were 160 sccm, 400 sccm, 6000 sccm, and 2000 sccm, respectively, and the pressure in the chamber at the time of deposition was 1000 Pa.

In the second step, another part of the tungsten film was formed in such a manner that the deposition gas flow rates of tungsten hexafluoride, hydrogen, argon, and nitrogen were 250 sccm, 4000 sccm, 2000 sccm, and 200 sccm, respectively, and the pressure in the chamber at the time of deposition was 10666 Pa.

In the third step, another part of the tungsten film was formed in such a manner that the deposition gas flow rates of tungsten hexafluoride, hydrogen, argon, and nitrogen were 250 sccm, 2200 sccm, 2000 sccm, and 200 sccm, respectively, and the pressure in the chamber at the time of deposition was 10666 Pa.

The substrate temperatures in the first step, the second step, and the third step were 400° C., 345° C., 300° C., and 300° C. in Sample 800A, Sample 800B, Sample 800C, and Sample 800D, respectively.

After the second titanium nitride film was deposited, heat treatment was performed on Sample 800D. As the heat treatment, an RTA apparatus was used and treatment was performed at 450° C. in a nitrogen (N₂) atmosphere for 1 minute. Note that the heat treatment was not performed on Sample 800A to Sample 800C.

Through the above steps, Samples 800 (Sample 800A to Sample 800D) were fabricated.

In this example, Sample 810 was fabricated as a comparative example. Sample 810 has a structure in which the conductive layer 805 in Sample 800 is not provided, and the other components and the fabrication conditions are similar to those of Sample 800C.

Table 1 shows heat treatment conditions and deposition conditions of the conductive layer 805a and the conductive layer 805b included in each of Sample 810 and Sample 800A to Sample 800D. Note that in Table 1, the conductive layers 805 are denoted by hyphens (-) indicating that the conductive layers 805 were not provided in Sample 810. Furthermore, in Table 1, the heat treatment conditions of Sample 800A to Sample 800C are denoted by hyphens (-) indicating that the heat treatment was not performed.

TABLE 1

| Sample name | 810 | 800A | 800B | 800C | 800D |
|---|---|---|---|---|---|
| Heat treatment condition | — | — | — | — | N₂ 450 °C |
| Conductive layer 805b | — | 400 °C | 345 °C | 300 °C | 300 °C |
| Conductive layer 805a | — | 400 °C | 340 °C | 300 °C | 300 °C |

### <GIXRD>

The crystal state of the HfZrO_{X} film corresponding to the insulating layer 804 in each of Sample 810 and Sample 800A to Sample 800D was examined by GIXRD measurement, which is a kind of XRD analysis method.

In order to perform GIXRD measurement on the insulating layer 804, the conductive layer 805a and the conductive layer 805b were removed by wet etching in each of Sample 800A to Sample 800D.

The GIXRD measurement was performed using a multifunction thin film material evaluation X-ray diffractometer D8 DISCOVER Hybrid/TXS (produced by Bruker Corporation). Note that as measurement conditions in the case of using this apparatus, the X-ray output was set to 50 kV and 100 mA, the incident angle θ was set to 0.5°, and the scan range 2θ was set to 20° to 50°.

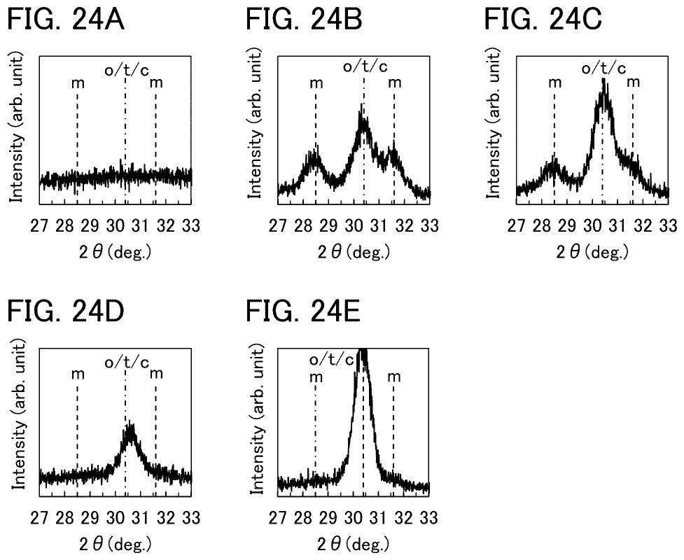

FIG. 24A to FIG. 24E show GIXRD measurement results. FIG. 24A to FIG. 24E each show the relationship between the X-ray diffraction angle (20) and the detected signal intensity. In each of FIG. 24A to FIG. 24E, the vertical axis represents the intensity, and the horizontal axis represents the diffraction angle (20). In FIG. 24A to FIG. 24E, the dashed-dotted line at 2θ of around 30.4° represents the peak position of a peak (o/t/c) derived from an orthorhombic crystal (o), a tetragonal crystal (t), or a cubic crystal (c). In FIG. 24A to FIG. 24E, each of the dashed line at 2θ of around 28.5° and the dashed line at 2θ of around 31.6° represents a peak position of a peak (m) derived from a monoclinic crystal (m). In this example, 2θ of around 30.4° is referred to as a first peak position, 2θ of around 28.5° is referred to as a second peak position, and 20 of around 31.6° is referred to as a third peak position.

FIG. 24A, FIG. 24B, FIG. 24C, FIG. 24D, and FIG. 24E show GIXRD measurement results of Sample 810, Sample 800A, Sample 800B, Sample 800C, and Sample 800D, respectively.

As shown in FIG. 24A, no peak was detected at the first peak position, the second peak position, and the third peak position in Sample 810. Thus, it was found that the insulating layer 804 does not have crystallinity immediately after the formation of the insulating layer 804.

As shown in FIG. 24B and FIG. 24C, peaks were detected at the first peak position, the second peak position, and the third peak position in each of Sample 800A and Sample 800B. The peak detected at the first peak position, the peak detected at the second peak position, and the peak detected at the third peak position correspond to the first peak, the second peak, and the third peak described in Embodiment 1, respectively. That is, the first peak, the second peak, and the third peak were detected in each of Sample 800A and Sample 800B.

Here, the ratio of the peak intensity of the second peak to the peak intensity of the first peak is referred to as a second peak intensity ratio, and the ratio of the peak intensity of the third peak to the peak intensity of the first peak is referred to as a third peak intensity ratio. As shown in FIG. 24B and FIG. 24C, the second peak intensity ratio of Sample 800B was lower than the second peak intensity ratio of Sample 800A. Furthermore, the third peak intensity ratio of Sample 800B was lower than the third peak intensity ratio of Sample 800A.

As shown in FIG. 24D, in Sample 800C, a peak was detected at the first peak position, and a peak was detected at neither the second peak position nor the third peak position. That is, the first peak was detected and neither the second peak nor the third peak was detected in Sample 800C.

From the above, it was found that when the substrate temperature in formation of the conductive layer 805 is lowered, the peak intensities of the peak detected at the second peak position and the peak detected at the third peak position become lowered. Thus, it was suggested that lowering the substrate temperature in formation of the conductive layer 805 can increase the ferroelectricity of the insulating layer 804.

As shown in FIG. 24E, in Sample 800D, a peak was detected at the first peak position, and a peak was detected at neither the second peak position nor the third peak position. That is, the first peak was detected and neither the second peak nor the third peak was detected in Sample 800C. Thus, it was found that the ferroelectricity of the insulating layer 804 can be maintained by performing the heat treatment after the formation of the conductive layer 805. Furthermore, it was suggested that the ferroelectricity of the insulating layer 804 can be improved.

### REFERENCE NUMERALS

BL: wiring, Cfe: capacitor, PL: wiring, WL: wiring, 10: semiconductor device, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 51: curve, 52: curve, 100a: capacitor, 100b: capacitor, 100: capacitor, 110: conductive layer, 115a: conductive layer, 115b: conductive layer, 115F: conductive film, 115: conductive layer, 118: layer, 120a: conductive layer, 120b: conductive layer, 120F: conductive film, 120: conductive layer, 128: layer, 130F: insulating film, 130: insulating layer, 140: insulating layer, 150a: memory cell, 150b: memory cell, 150c: memory cell, 150d: memory cell, 150: memory cell, 160: memory layer, 180: insulating layer, 190: opening portion, 200A: transistor, 200a: transistor, 200b: transistor, 230: oxide semiconductor layer, 240a: conductive layer, 240b: conductive layer, 240: conductive layer, 245: conductive layer, 246: conductive layer, 247: conductive layer, 248: conductive layer, 250: insulating layer, 260: conductive layer, 265: conductive layer, 270: opening portion, 280: insulating layer, 283: insulating layer, 285: insulating layer, 287: insulating layer, 290: opening portion, 300: storage device, 310: transistor, 311: substrate, 313: semiconductor region, 314a: low-resistance region, 314b: low-resistance region, 315: insulating layer, 316: conductive layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 641: insulating layer, 642: conductive layer, 643: conductive layer, 644: conductive layer, 645: conductive layer, 646: conductive layer, 648: insulating layer, 700: electronic component, 702: printed circuit board, 704: circuit board, 711: mold, 712: land, 713: electrode pad, 714: wire, 720: storage device, 721: driver circuit layer, 722: storage circuit layer, 730: electronic component, 731: interposer, 732: package board, 733: electrode, 735: semiconductor device, 800A: sample, 800B: sample, 800C: sample, 800D: sample, 800: sample, 801: substrate, 802: insulating layer, 803: conductive layer, 804: insulating layer, 805a: conductive layer, 805b: conductive layer, 805: conductive layer, 810: sample, 1200: chip, 1201: package board, 1202: bump, 1203: motherboard, 1204: GPU module, 1211: CPU, 1212: GPU, 1213: analog arithmetic unit, 1214: memory controller, 1215: interface, 1216: network circuit, 1221: storage device, 1222: flash memory, 5110: SD card, 5111: housing, 5112: connector, 5113: substrate, 5115: controller chip, 5150: SSD, 5151: housing, 5152: connector, 5153: substrate, 5155: memory chip, 5156: controller chip, 5200: portable game machine, 5201: housing, 5202: display portion, 5203: button, 5300: desktop information terminal, 5301: main body, 5302: display portion, 5303: keyboard, 5400: ICD main unit, 5401: battery, 5402: wire, 5403: wire, 5404: antenna, 5405: subclavian vein, 5406: superior vena cava, 5500: information terminal, 5510: housing, 5511: display portion, 5600: computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 5700: motor vehicle, 5800: electric refrigerator-freezer, 5801: housing, 5802: refrigerator door, 5803: freezer door, 5900: information terminal, 5901: housing, 5902: display portion, 5903: operation switch, 5904: operation switch, 5905: band, 6100: expansion device, 6101: housing, 6102: cap, 6103: USB connector, 6104: substrate, 6106: controller chip, 6240: digital camera, 6241: housing, 6242: display portion, 6243: operation switch, 6244: shutter button, 6246: lens, 6300: video camera, 6301: first housing, 6302: second housing, 6303: display portion, 6304: operation switch, 6305: lens, 6306: joint, 6800: artificial satellite, 6801: body, 6802: solar panel, 6803: antenna, 6804: planet, 6805: secondary battery, 6807: control device, 7500: stationary game machine, 7520: main body, 7522: controller

1. A semiconductor device comprising:
a first conductive layer;
a ferroelectric layer over the first conductive layer; and
a second conductive layer over the ferroelectric layer,
wherein the first conductive layer comprises a first depressed portion,
wherein the ferroelectric layer comprises a region formed along the first depressed portion,
wherein the region comprises a second depressed portion,
wherein the second conductive layer is provided to fill the second depressed portion,
wherein the ferroelectric layer comprises hafnium, zirconium, and oxygen,
wherein the ferroelectric layer, in an X-ray diffraction analysis, has a peak at 2θ of around 30.4°, and
wherein in the ferroelectric layer, in the X-ray diffraction analysis, an intensity at 20 of 28.5° is less than or equal to 0.1 times a peak intensity of the peak and an intensity at 2 of 31.6° is less than or equal to 0.1 times a peak intensity of the peak.

2. The semiconductor device according to claim 1,
wherein one or both of the first conductive layer and the second conductive layer comprise titanium and nitrogen.

3. The semiconductor device according to claim 1,
wherein one or both of the first conductive layer and the second conductive layer comprise tungsten.

4. A semiconductor device comprising:
a capacitor and a transistor over the capacitor,
wherein the capacitor comprises:
a first conductive layer;
a ferroelectric layer over the first conductive layer; and
a second conductive layer over the ferroelectric layer,
wherein the ferroelectric layer comprises hafnium, zirconium, and oxygen, and
wherein a top surface of the second conductive layer comprises a region in contact with at least part of a bottom surface of an oxide semiconductor layer included in the transistor.

5. The semiconductor device according to claim 4,
wherein the ferroelectric layer, in an X-ray diffraction analysis, has a peak at 2θ of around 30.4°, and
wherein in the ferroelectric layer, in the X-ray diffraction analysis, an intensity at 20 of 28.5° is less than or equal to 0.1 times a peak intensity of the peak and an intensity at 2 of 31.6° is less than or equal to 0.1 times a peak intensity of the peak.

6. The semiconductor device according to claim 4,
wherein one or both of the first conductive layer and the second conductive layer comprise titanium and nitrogen.

7. The semiconductor device according to claim 4,
wherein one or both of the first conductive layer and the second conductive layer comprise tungsten.

8. The semiconductor device according to claim 4,
wherein the first conductive layer comprises a first depressed portion,
wherein the ferroelectric layer comprises a region formed along the first depressed portion,
wherein the region comprises a second depressed portion, and
wherein the second conductive layer is provided to fill the second depressed portion.

9. The semiconductor device according to claim 4,
wherein a channel of the transistor is formed along a side surface of an opening portion of an insulating layer.

10. The semiconductor device according to claim 4,
wherein the oxide semiconductor layer comprises one or both of indium and zinc.

11. A method for fabricating a semiconductor device comprising:
forming a first conductive layer over a substrate;
forming a ferroelectric layer over the first conductive layer; and
forming a second conductive layer over the ferroelectric layer,
wherein the first conductive layer is formed by a metal CVD method in which a temperature of the substrate is a first temperature,
wherein the ferroelectric layer is formed by an ALD method using a precursor comprising hafnium, a precursor comprising zirconium, and an oxidizer,
wherein the second conductive layer is formed by a metal CVD method in which a temperature of the substrate is a second temperature,
wherein the second temperature is higher than or equal to 250° C. and lower than or equal to 325° C., and
wherein the first temperature is higher than the second temperature.

12. The method for fabricating a semiconductor device, according to claim 11,
wherein one or both of the first conductive layer and the second conductive layer are formed using titanium chloride and ammonia.

13. The method for fabricating a semiconductor device, according to claim 11,
wherein one or both of the first conductive layer and the second conductive layer are formed using tungsten hexafluoride.

14. The method for fabricating a semiconductor device, according to claim 11,
wherein after an insulating film to be the ferroelectric layer is formed, a heat treatment at higher than or equal to 400° C. and lower than or equal to 600° C. is performed by an RTA method using a lamp.

15. The method for fabricating a semiconductor device, according to claim 11,
wherein the first conductive layer comprises a first depressed portion,
wherein the ferroelectric layer is formed along the first depressed portion,
wherein the ferroelectric layer comprises a second depressed portion in a region overlapping with the first depressed portion, and
wherein the second conductive layer is formed to fill the second depressed portion.

16. The method for fabricating a semiconductor device, according to claim 12,
wherein the ferroelectric layer, in an X-ray diffraction analysis after the second conductive layer is formed, has a peak at 2θ of around 30.4°, and
wherein in the ferroelectric layer, in the X-ray diffraction analysis after the second conductive layer is formed, an intensity at 2θ of 28.5° is less than or equal to 0.1 times a peak intensity of the peak and an intensity at 2θ of 31.6° is less than or equal to 0.1 times a peak intensity of the peak.
